(19) United States
(12) Patent Application Publication
(10) Pub. No.: US 2024/0381678 A1
(43) Pub. Date: Nov. 14, 2024

(54) DISPLAY APPARATUS, METHOD FOR MANUFACTURING DISPLAY APPARATUS, AND ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tomoya AOYAMA, Atsugi (JP); Ryota HODO, Atsugi (JP)

(21) Appl. No.: 18/577,365

(22) PCT Filed: Jun. 30, 2022
(86) PCT No.: PCT/IB2022/056090

§ 371 Date: Jan. 8, 2024

(30) Foreign Application Priority Data
Jul. 20, 2021 (JP) 2021-119903

(51) Int. Cl. H10K 39/34; H10K 59/12; H10K 59/122; H10K 59/35; H10K 59/40; H10K 59/80; H10K 59/88; H10K 71/40

(52) U.S. Cl. CPC H10K 39/34; H10K 59/1201; H10K 59/122; H10K 59/353; H10K 59/40; H10K 59/80515; H10K 59/875; H10K 59/8791; H10K 59/88; H10K 71/40

(57) ABSTRACT

A display apparatus including first and second light-emitting elements and a light-receiving element can capture an image with high sensitivity. In the first light-emitting element, the second light-emitting element, and the light-receiving element, a first pixel electrode, a first light-emitting layer, and a common electrode; a second pixel electrode, a second light-emitting layer, and the common electrode; and a third pixel electrode, a photoelectric conversion layer, and the common electrode are stacked in this order, respectively. A first insulating layer between the second light-emitting element and the light-receiving element and a second insulating layer between the first light-emitting element and the second light-emitting element each contain a positive photosensitive material having a high visible-light-transmitting property. A transmittance of light having a wavelength that is at least part of a visible light wavelength in the first insulating layer is lower than that in the second insulating layer.

### TECHNICAL FIELD

One embodiment of the present invention relates to a display apparatus. One embodiment of the present invention relates to an image capturing device. One embodiment of the present invention relates to a display apparatus having an image capturing function. One embodiment of the present invention relates to a display module. One embodiment of the present invention relates to an electronic device.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, display apparatuses have been required to have higher resolution in order to display high-definition images. In addition, display apparatuses used in information terminal devices such as smartphones, tablet terminals, and notebook PCs (personal computers) have been required to have lower power consumption as well as higher resolution. Furthermore, display apparatuses have been required to have a variety of functions such as a function of a touch sensor and a function of capturing images of fingerprints for authentication, in addition to a function of displaying images.

Light-emitting apparatuses including light-emitting elements have been developed, for example, as display apparatuses. Light-emitting elements (also referred to as EL elements) utilizing an electroluminescence (hereinafter, referred to as EL) phenomenon have features such as ease of reduction in thickness and weight, high-speed response to an input signal, and driving with a direct-constant voltage source, and have been used in display apparatuses. For example, Patent Document 1 discloses a flexible light-emitting apparatus including an organic EL element (also referred to as an organic EL device).

Non-Patent Document 1 discloses a method for manufacturing an organic optoelectronic device using standard UV photolithography.

### REFERENCES

### Patent Document

[Patent Document 1] Japanese Published Patent Application No. 2014-197522

### Non-Patent Document

[Non-Patent Document 1] B. Lamprecht et al., “Organic optoelectronic device fabrication using standard UV photolithography” phys. stat. sol. (RRL) 2, No. 1, p. 16-18 (2008)

### SUMMARY OF THE INVENTION

### Problems to be Solved by the Invention

By providing not only a light-emitting element but also a light-receiving element for a pixel, for example, a display apparatus having a function of performing image capturing can be achieved. For example, when the light-receiving element detects light emitted from the light-emitting element and reflected by an object to be detected such as a finger, the display apparatus can have a function of a touch sensor, a function of capturing an image of a fingerprint for authentication, and the like. Here, when light emitted from a light-emitting element adjacent to the light-receiving element enters the light-receiving element due to stray light, for example, noise might be generated in image capturing using the light-receiving element, leading to a reduction in image capturing sensitivity.

An object of one embodiment of the present invention is to provide a display apparatus or an image capturing device that is capable of image capturing with high sensitivity. Another object of one embodiment of the present invention is to provide a high-resolution display apparatus or a high-resolution image capturing device. Another object of one embodiment of the present invention is to provide a display apparatus or an image capturing device that has a high aperture ratio. Another object of one embodiment of the present invention is to provide a display apparatus or an image capturing device that can be manufactured in a simple process. Another object of one embodiment of the present invention is to provide an inexpensive display apparatus or an inexpensive image capturing device. Another object of one embodiment of the present invention is to provide a highly reliable display apparatus or a highly reliable image capturing device. Another object of one embodiment of the present invention is to provide a display apparatus with high light extraction efficiency. Another object of one embodiment of the present invention is to provide a display apparatus having high display quality. Another object of one embodiment of the present invention is to provide a display apparatus capable of obtaining biological information such as fingerprints. Another object of one embodiment of the present invention is to provide a display apparatus functioning as a touch sensor. Another object of one embodiment of the present invention is to provide a highly functional display apparatus. Another object of one embodiment of the present invention is to provide a display apparatus or an image capturing device that has a novel structure. Another object of one embodiment of the present invention is to provide an electronic device including the display apparatus or the image capturing device. Another object of one embodiment of the present invention is to provide a method for manufacturing the display apparatus, the image capturing device, or the electronic device.

Note that the description of these objects does not preclude the existence of other objects. One embodiment of the present invention does not have to achieve all of these objects. Note that objects other than these can be derived from the descriptions of the specification, the drawings, the claims, and the like.

### Means for Solving the Problems

One embodiment of the present invention is a display apparatus including a first light-emitting element, a second light-emitting element adjacent to the first light-emitting element, a light-receiving element adjacent to the second light-emitting element, a first insulating layer provided between the second light-emitting element and the light-receiving element, and a second insulating layer provided between the first light-emitting element and the second light-emitting element. The first light-emitting element includes a first pixel electrode, a first EL layer over the first pixel electrode, and a common electrode over the first EL layer. The second light-emitting element includes a second pixel electrode, a second EL layer over the second pixel electrode, and the common electrode over the second EL layer. The light-receiving element includes a third pixel electrode, a PD layer over the third pixel electrode, and the common electrode over the PD layer. The common electrode is provided over the first insulating layer and the second insulating layer. The second insulating layer and the first insulating layer contain the same material. A transmittance of light having a specific wavelength that is at least part of a visible light wavelength in the first insulating layer is lower than the transmittance of the light having the specific wavelength in the second insulating layer.

Alternatively, one embodiment of the present invention is a display apparatus including a first light-emitting element, a second light-emitting element adjacent to the first light-emitting element, a light-receiving element adjacent to the second light-emitting element, a first insulating layer provided between the second light-emitting element and the light-receiving element, and a second insulating layer provided between the first light-emitting element and the second light-emitting element. The first light-emitting element includes a first pixel electrode, a first EL layer over the first pixel electrode, and a common electrode over the first EL layer. The second light-emitting element includes a second pixel electrode, a second EL layer over the second pixel electrode, and the common electrode over the second EL layer. The light-receiving element includes a third pixel electrode, a PD layer over the third pixel electrode, and the common electrode over the PD layer. The common electrode is provided over the first insulating layer and the second insulating layer. The second insulating layer and the first insulating layer contain the same material. A transmittance of light of at least one color among red, green, and blue in the first insulating layer is lower than the transmittance in the second insulating layer.

Alternatively, in the above embodiment, the first insulating layer and the second insulating layer may each contain an organic material.

Alternatively, in the above embodiment, end portions of the first to third pixel electrodes may have tapered shapes; the first EL layer may cover the end portion of the first pixel electrode; the second EL layer may cover the end portion of the second pixel electrode; and the PD layer may cover the end portion of the third pixel electrode.

Alternatively, in the above embodiment, the first EL layer may include a first tapered portion between the end portion of the first pixel electrode and the second insulating layer; the second EL layer may include a second tapered portion between the end portion of the second pixel electrode and the second insulating layer; and the PD layer may include a third tapered portion between the end portion of the third pixel electrode and the first insulating layer.

Alternatively, in the above embodiment, the first EL layer may include a first light-emitting layer and a first carrier-transport layer over the first light-emitting layer; the second EL layer may include a second light-emitting layer and a second carrier-transport layer over the second light-emitting layer; and the PD layer may include a photoelectric conversion layer and a third carrier-transport layer over the photoelectric conversion layer.

Alternatively, in the above embodiment, a common layer over the first carrier-transport layer, over the second carrier-transport layer, over the third carrier-transport layer, over the first insulating layer, and over the second insulating layer and the common electrode over the common layer may be included.

Alternatively, in the above embodiment, the common layer may include a carrier-injection layer.

A display module including the display apparatus of one embodiment of the present invention and at least one of a connector and an integrated circuit is also one embodiment of the present invention.

An electronic device including the display module of one embodiment of the present invention and at least one of a battery, a camera, a speaker, and a microphone is also one embodiment of the present invention.

Alternatively, one embodiment of the present invention is a method for manufacturing a display apparatus, including forming a first pixel electrode, a second pixel electrode, and a third pixel electrode; forming a first EL film over the first to third pixel electrodes; forming a first mask film over the first EL film; processing the first EL film and the first mask film to form a first EL layer and a first mask layer over the first EL layer; forming a second EL film over the second pixel electrode, the third pixel electrode, and the first mask layer; forming a second mask film over the second EL film; processing the second EL film and the second mask film to form a second EL layer adjacent to the first EL layer and a second mask layer over the second EL layer; forming a PD film over the third pixel electrode, the first mask layer, and the second mask layer; forming a third mask film over the PD film; processing the PD film and the third mask film to form a PD layer adjacent to the second EL layer and a third mask layer over the PD layer; forming a first insulating film containing a positive photosensitive material to cover a side surface of the first EL layer, a side surface of the second EL layer, and a side surface of the PD layer; performing irradiation of first light on the first insulating film and then performing development to form a first insulating layer between the second EL layer and the PD layer and a second insulating layer between the first EL layer and the second EL layer; performing irradiation of second light on the second insulating layer to increase a transmittance of light having a wavelength that is at least part of a visible light wavelength in the second insulating layer; removing at least part of the first to third mask layers; and forming a common electrode over the first EL layer, the second EL layer, the PD layer, the first insulating layer, and the second insulating layer.

Alternatively, one embodiment of the present invention is a method for manufacturing a display apparatus, including forming a first pixel electrode, a second pixel electrode, and a third pixel electrode; forming a first EL film over the first to third pixel electrodes; forming a first mask film over the first EL film; processing the first EL film and the first mask film to form a first EL layer and a first mask layer over the first EL layer; forming a second EL film over the second pixel electrode, the third pixel electrode, and the first mask layer; forming a second mask film over the second EL film; processing the second EL film and the second mask film to form a second EL layer adjacent to the first EL layer and a second mask layer over the second EL layer; forming a PD film over the third pixel electrode, the first mask layer, and the second mask layer; forming a third mask film over the PD film; processing the PD film and the third mask film to form a PD layer adjacent to the second EL layer and a third mask layer over the PD layer; forming a first insulating film containing a positive photosensitive material to cover a side surface of the first EL layer, a side surface of the second EL layer, and a side surface of the PD layer; performing irradiation of first light on the first insulating film and then performing development to form a first insulating layer between the second EL layer and the PD layer and a second insulating layer between the first EL layer and the second EL layer; performing irradiation of second light on the second insulating layer to increase a transmittance of light of at least one color among red, green, and blue in the second insulating layer; removing at least part of the first to third mask layers to expose at least part of the first EL layer, the second EL layer, and the PD layer; and forming a common electrode over the first EL layer, the second EL layer, the PD layer, the first insulating layer, and the second insulating layer.

Alternatively, in the above embodiment, by performing heat treatment after the first and second insulating layers are formed but before the first to third mask layers are removed, the first and second insulating layers may be changed in shape to have tapered shapes in side surfaces.

Alternatively, in the above embodiment, a temperature of the heat treatment may be lower than or equal to 130° C.

Alternatively, in the above embodiment, the second light may include light having the same wavelength as the first light.

Alternatively, in the above embodiment, a spectrum of the first light and a spectrum of the second light may each have a peak in an ultraviolet light region.

Alternatively, in the above embodiment, after at least part of the first to third mask layers is removed, a common layer may be formed over the first EL layer, the second EL layer, the PD layer, the first insulating layer, and the second insulating layer and the common electrode may be formed over the common layer.

Alternatively, in the above embodiment, the common layer may include a carrier-injection layer.

Alternatively, in the above embodiment, the first EL film may include a first light-emitting film and a film functioning as a first carrier-transport layer over the first light-emitting film; the second EL film may include a second light-emitting film and a film functioning as a second carrier-transport layer over the second light-emitting film; the PD film may include a photoelectric conversion film and a film functioning as a third carrier-transport layer over the photoelectric conversion film; the first light-emitting film, the film functioning as the first carrier-transport layer, and the first mask film may be processed to form a first light-emitting layer, the first carrier-transport layer over the first light-emitting layer, and the first mask layer over the first carrier-transport layer; the second light-emitting film, the film functioning as the second carrier-transport layer, and the second mask film may be processed to form a second light-emitting layer, the second carrier-transport layer over the second light-emitting layer, and the second mask layer over the second carrier-transport layer; and the photoelectric conversion film, the film functioning as the third carrier-transport layer, and the third mask film may be processed to form a photoelectric conversion layer, the third carrier-transport layer over the photoelectric conversion layer, and the third mask layer over the third carrier-transport layer.

Alternatively, in the above embodiment, the first to third pixel electrodes may be formed to have tapered shapes in end portions; by processing the first EL film, the first EL layer may be formed to cover the end portion of the first pixel electrode; by processing the second EL film, the second EL layer may be formed to cover the end portion of the second pixel electrode; and by processing the PD film, the PD layer may be formed to cover the end portion of the third pixel electrode.

Alternatively, in the above embodiment, by processing the first EL film, the first EL layer may be formed to include a first tapered portion between the end portion of the first pixel electrode and an end portion of the first mask layer; by processing the second EL film, the second EL layer may be formed to include a second tapered portion between the end portion of the second pixel electrode and an end portion of the second mask layer; and by processing the PD film, the PD layer may be formed to include a third tapered portion between the end portion of the third pixel electrode and an end portion of the third mask layer.

### Effect of the Invention

According to one embodiment of the present invention, a display apparatus or an image capturing device that is capable of image capturing with high sensitivity can be provided can be provided. Alternatively, according to one embodiment of the present invention, a high-resolution display apparatus or a high-resolution image capturing device can be provided can be provided. Alternatively, according to one embodiment of the present invention, a display apparatus or an image capturing device that has a high aperture ratio can be provided. Alternatively, according to one embodiment of the present invention, a display apparatus or an image capturing device that can be manufactured in a simple process can be provided. Alternatively, according to one embodiment of the present invention, an inexpensive display apparatus or an inexpensive image capturing device can be provided. Alternatively, according to one embodiment of the present invention, a highly reliable display apparatus or a highly reliable image capturing device can be provided. Alternatively, according to one embodiment of the present invention, a display apparatus with high light extraction efficiency can be provided. Alternatively, according to one embodiment of the present invention, a display apparatus having high display quality can be provided. Alternatively, according to one embodiment of the present invention, a display apparatus capable of obtaining biological information such as fingerprints can be provided.

Alternatively, according to one embodiment of the present invention, a display apparatus functioning as a touch sensor can be provided. Alternatively, according to one embodiment of the present invention, a highly functional display apparatus can be provided. Alternatively, according to one embodiment of the present invention, a display apparatus or an image capturing device that has a novel structure can be provided. Alternatively, according to one embodiment of the present invention, an electronic device including the display apparatus or the image capturing device can be provided. Alternatively, according to one embodiment of the present invention, a method for manufacturing the display apparatus, the image capturing device, or the electronic device can be provided.

Note that the description of these effects does not preclude the existence of other effects. One embodiment of the present invention does not need to have all of these effects. Note that effects other than these can be derived from the descriptions of the specification, the drawings, the claims, and the like.

### BRIEF DESCRIPTION OF THE DRAWINGS

FIG. 1A, FIG. 1B1, and FIG. 1B2 are top views illustrating structure examples of a display apparatus.

FIG. 2A1, FIG. 2A2, FIG. 2B1, and FIG. 2B2 are cross-sectional views illustrating structure examples of a display apparatus.

FIG. 3A and FIG. 3B are cross-sectional views illustrating a structure example of a display apparatus.

FIG. 4A and FIG. 4B are cross-sectional views illustrating a structure example of a display apparatus.

FIG. 5A and FIG. 5B are cross-sectional views illustrating a structure example of a display apparatus.

FIG. 6A to FIG. 6D are cross-sectional views illustrating an example of a manufacturing method of a display apparatus.

FIG. 7A to FIG. 7C are cross-sectional views illustrating an example of a manufacturing method of a display apparatus.

FIG. 8A to FIG. 8C are cross-sectional views illustrating an example of a manufacturing method of a display apparatus.

FIG. 9A to FIG. 9D are cross-sectional views illustrating an example of a manufacturing method of a display apparatus.

FIG. 10A to FIG. 10D are cross-sectional views illustrating an example of a manufacturing method of a display apparatus.

FIG. 11A to FIG. 11C are cross-sectional views illustrating an example of a manufacturing method of a display apparatus.

FIG. 12A and FIG. 12B are cross-sectional views illustrating an example of a manufacturing method of a display apparatus.

FIG. 13A1, FIG. 13A2, FIG. 13B1, and FIG. 13B2 are cross-sectional views illustrating an example of a manufacturing method of a display apparatus.

FIG. 14A, FIG. 14B, FIG. 14C1, and FIG. 14C2 are cross-sectional views illustrating an example of a manufacturing method of a display apparatus.

FIG. 15A1, FIG. 15A2, and FIG. 15B are cross-sectional views illustrating an example of a manufacturing method of a display apparatus.

FIG. 16 is a perspective view illustrating a structure example of a display apparatus.

FIG. 17A is a cross-sectional view illustrating a structure example of a display apparatus. FIG. 17B1 and FIG. 17B2 are cross-sectional views illustrating structure examples of transistors.

FIG. 18 is a cross-sectional view illustrating a structure example of a display apparatus.

FIG. 19 is a cross-sectional view illustrating a structure example of a display apparatus.

FIG. 20A to FIG. 20D are cross-sectional views illustrating structure examples of a display apparatus.

FIG. 21A and FIG. 21B are diagrams illustrating a structure example of a display apparatus.

FIG. 22 is a diagram illustrating a structure example of a display apparatus.

FIG. 23 is a diagram illustrating a structure example of a display apparatus.

FIG. 24 is a diagram illustrating a structure example of a display apparatus.

FIG. 25 is a diagram illustrating a structure example of a display apparatus.

FIG. 26 is a diagram illustrating a structure example of a display apparatus.

FIG. 27 is a diagram illustrating a structure example of a display apparatus.

FIG. 28A, FIG. 28B, and FIG. 28D are cross-sectional views showing an example of a display apparatus. FIG. 28C and FIG. 28E are diagrams illustrating examples of images. FIG. 28F to FIG. 28H are top views illustrating examples of a pixel.

FIG. 29A is a cross-sectional view illustrating a structure example of a display apparatus. FIG. 29B to FIG. 29D are top views illustrating examples of a pixel.

FIG. 30A is a cross-sectional view illustrating a structure example of a display apparatus. FIG. 30B to FIG. 30I are top views illustrating examples of a pixel.

FIG. 31A and FIG. 31B are diagrams illustrating structure examples of a display apparatus.

FIG. 32A to FIG. 32G are diagrams illustrating structure examples of a display apparatus.

FIG. 33A to FIG. 33F are diagrams illustrating examples of a pixel. FIG. 33G and FIG. 33H are diagrams illustrating examples of circuit diagrams of pixels.

FIG. 34A to FIG. 34J are diagrams illustrating structure examples of a display apparatus.

FIG. 35A and FIG. 35B are diagrams illustrating an example of an electronic device.

FIG. 36A to FIG. 36D are diagrams illustrating examples of electronic devices.

FIG. 37A to FIG. 37F are diagrams illustrating examples of electronic devices.

FIG. 38A to FIG. 38F are diagrams illustrating examples of electronic devices.

### MODE FOR CARRYING OUT THE INVENTION

Hereinafter, embodiments are described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatching pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, the ordinal numbers such as “first” and “second” are used in order to avoid confusion among components and do not limit the number.

Hereinafter, the expressions indicating directions such as “over” and “under” are basically used to correspond to the directions of drawings. However, in some cases, the direction indicating “over” or “under” in the specification does not correspond to the direction in the drawings for the purpose of description simplicity, for example. For example, when a stacking order (or formation order) of a stack is described, even in the case where a surface on which the stack is provided (e.g., a formation surface, a support surface, an adhesion surface, or a planar surface) is positioned above the stack in the drawings, the surface on which the stacked body is provided is regarded as being under the stack, and the stack is regarded as being over the surface, for example, in some cases.

In this specification and the like, the term “film” and the term “layer” can be interchanged with each other depending on the case or according to circumstances. For example, in some cases, the term “conductive layer” and the term “insulating layer” can be interchanged with the term “conductive film” and the term “insulating film”, respectively.

Note that in this specification and the like, an EL layer means a layer containing at least a light-emitting substance (also referred to as a light-emitting layer) or a stack including the light-emitting layer provided between a pair of electrodes of a light-emitting element. A PD layer refers to a layer that is provided between a pair of electrodes of a light-receiving element and contains at least a photoelectric conversion material (such a layer is also referred to as an active layer or a photoelectric conversion layer), or a stack including an active layer.

In this specification and the like, a display panel that is one embodiment of a display apparatus has a function of displaying (outputting), for example, an image on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, a structure example of a display apparatus of one embodiment of the present invention and an example of a method for manufacturing the display apparatus will be described.

One embodiment of the present invention is a display apparatus provided with a light-emitting element (also referred to as a light-emitting device) and a light-receiving element (also referred to as a light-receiving device). The light-emitting element includes a pair of electrodes and an EL layer between them. The light-receiving element includes a pair of electrodes and a PD layer between them. Here, the EL layer includes at least a light-emitting layer and preferably includes a plurality of layers. The EL layer preferably includes, for example, a light-emitting layer and a carrier-transport layer (a hole-transport layer or an electron-transport layer) over the light-emitting layer. The PD layer includes at least an active layer (also referred to as a photoelectric conversion layer) and preferably includes a plurality of layers. The PD layer preferably includes, for example, an active layer and a carrier-transport layer (a hole-transport layer or an electron-transport layer) over the active layer.

The light-emitting element is preferably an organic EL element (an organic electroluminescent element). The light-receiving element is preferably an organic photodiode (an organic photoelectric conversion element).

The display apparatus preferably includes two or more light-emitting elements emitting light of different colors. The light-emitting elements emitting different colors include respective EL layers containing different materials. For example, three kinds of light-emitting elements emitting red (R), green (G), and blue (B) light are included, whereby a full-color display apparatus can be obtained.

One embodiment of the present invention is capable of image capturing by a plurality of light-receiving elements and thus functions as an image capturing device. In this case, the light-emitting elements can be used as a light source for image capturing. Moreover, one embodiment of the present invention is capable of displaying an image with the plurality of light-emitting elements and thus functions as a display apparatus. Accordingly, one embodiment of the present invention can be regarded as a display apparatus that has an image capturing function or an image capturing device that has a display function.

For example, in addition to light-emitting elements, light-receiving elements are arranged in a matrix in a display portion of the display apparatus of one embodiment of the present invention. Hence, the display portion has, in addition to a function of displaying an image, a function of a light-receiving portion. An image can be captured by the plurality of light-receiving elements provided in the display portion, so that the display apparatus can function as an image sensor or a touch sensor. That is, in the display apparatus of one embodiment of the present invention, an image can be captured in the display portion, for example. Alternatively, the display apparatus of one embodiment of the present invention can detect an object approaching the display portion or an object touching the display portion. Furthermore, since the light-emitting elements provided in the display portion can be used as a light source at the time of receiving light, a light source does not need to be provided separately from the display apparatus. Thus, a highly functional display apparatus can be provided without increasing the number of electronic components.

In this specification and the like, the term “touch sensor” may refer to a “contactless touch sensor” having a function of detecting an object that is approaching but not touching the sensor.

In one embodiment of the present invention, when an object reflects light emitted by the light-emitting element included in the display portion, the light-receiving element can detect the reflected light; thus, even in a dark environment, image capturing can be performed and touch of an object can be detected.

Furthermore, when a finger, a palm, or the like touches the display portion of the display apparatus of one embodiment of the present invention, an image of the fingerprint or the palm print can be captured. Thus, an electronic device including the display apparatus of one embodiment of the present invention can perform biometric authentication by using the captured image of the fingerprint or the palm print. Accordingly, an image capturing device for the fingerprint authentication or the palm-print authentication does not need to be additionally provided, and the number of components of the electronic device can be reduced. Since the light-receiving elements are arranged in a matrix in the display portion, an image of a fingerprint or an image of a palm print can be captured in any position in the display portion, which can provide a highly convenient electronic device.

Here, as a way of forming EL layers separately between light-emitting elements which emit light of different colors and forming a PD layer, an evaporation method using a shadow mask such as a metal mask is known. However, this method has difficulty in achieving high resolution and a high aperture ratio of a display apparatus because in this method, a deviation from the designed shape and position of each of the island-shaped EL layer and the island-shaped PD layer is caused by various influences such as the accuracy of the metal mask, the positional deviation between the metal mask and a substrate, a warp of the metal mask, and the vapor-scattering-induced expansion of the outline of the deposited film. In addition, the outline of the layer may blur during evaporation, whereby the thickness of an end portion may be reduced. That is, the thicknesses of the island-shaped EL layer and the island-shaped PD layer may vary from area to area. In the case of manufacturing a display apparatus with a large size, high definition, or high resolution, the manufacturing yield might be reduced because of low dimensional accuracy of the metal mask and a change in shape due to heat or the like.

In this specification and the like, the term “island shape” refers to a state where two or more layers formed using the same material in the same step are physically separated from each other. For example, the term “island-shaped EL layer” refers to a state where the EL layer and its adjacent EL layer are physically separated from each other.

In view of the above, in manufacture of the display apparatus of one embodiment of the present invention, pixel electrodes are formed for respective subpixels and then a light-emitting film is deposited across the plurality of pixel electrodes. After that, the light-emitting film is processed by a photolithography method, for example, so that one island-shaped EL layer is formed per pixel electrode. In this manner, the EL layer is divided for each subpixel and island-shaped EL layers can be formed for respective subpixels. The PD layer included in the light-receiving element can also be formed by a method similar to that for the EL layer.

In the case where the EL layer and the PD layer are processed into island shapes, a structure in which processing is performed by a photolithography method directly on the EL layer or the PD layer is considered. In the case of this structure, damage to the EL layer or the PD layer (processing damage or the like) might significantly degrade the reliability. In view of the above, in the manufacture of the display apparatus of one embodiment of the present invention, it is preferable to employ a method in which a mask layer (also referred to as a sacrificial layer, a protective layer, or the like) or the like is formed over a layer positioned above the EL layer or the PD layer (e.g., a carrier-transport layer or a carrier-injection layer, and specifically an electron-transport layer or an electron-injection layer), followed by the processing of the EL layer and the PD layer into island shapes. Such a method can provide a highly reliable display apparatus.

In the case where the EL layer is processed into an island shape, a layer positioned below the light-emitting layer (e.g., a carrier-injection layer or a carrier-transport layer, and specifically a hole-injection layer or a hole-transport layer) is preferably processed into an island shape with the same pattern as the light-emitting layer. When the layer positioned below the light-emitting layer is processed into an island shape with the same pattern as the light-emitting layer, a leakage current that would be generated between adjacent subpixels (sometimes referred to as a horizontal leakage current or a lateral leakage current) can be reduced. For example, in the case where a hole-injection layer is shared by adjacent subpixels, a horizontal leakage current would be generated because of the hole-injection layer. In contrast, in the display apparatus of one embodiment of the present invention, the hole-injection layer can be processed into an island shape with the same pattern as the light-emitting layer; hence, a horizontal leakage current between adjacent subpixels is not substantially generated or a horizontal leakage current can be extremely small.

As described above, the island-shaped EL layer and the island-shaped PD layer formed by the method for manufacturing a display apparatus of one embodiment of the present invention are formed not by using a fine metal mask but by processing a film to be an EL layer and a film to be a PD layer that are deposited over the entire surface. Specifically, the island-shaped EL layer and the island-shaped PD layer are divided and processed into layers with a smaller size by a photolithography method or the like. Thus, its size can be made smaller than the size formed using a fine metal mask. Accordingly, a high-resolution display apparatus or a display apparatus with a high aperture ratio, which has been difficult to achieve, can be manufactured.

The small number of times of processing of the EL layer and the PD layer with a photolithography method is preferable because a reduction in manufacturing cost and an improvement of manufacturing yield become possible.

A formation method using a fine metal mask, for example, does not easily shorten the distance between adjacent light-emitting elements to less than 10 μm; meanwhile, the method employing a photolithography method according to one embodiment of the present invention can shorten the distance between adjacent light-emitting elements to less than 10 μm, 5 μm or less, 3 μm or less, 2 μm or less, 1.5 μm or less, 1 μm or less, or even 0.5 μm or less, for example, in a process over a glass substrate. Using a light exposure apparatus for LSI can further shorten the distance between adjacent light-emitting elements to 500 nm or less, 200 nm or less, 100 nm or less, or even 50 nm or less, for example, in a process over a Si wafer. Accordingly, the area of a non-light-emitting region that may exist between two light-emitting elements can be significantly reduced, and the aperture ratio can be close to 100%. For example, the aperture ratio of the display apparatus of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display apparatus can improve the reliability of the display apparatus. Specifically, with reference to the lifetime of a display apparatus including an organic EL element and having an aperture ratio of 10%, a display apparatus having an aperture ratio of 20% (i.e., having an aperture ratio two times the reference) has a lifetime approximately 3.25 times the reference, and a display apparatus having an aperture ratio of 40% (i.e., having an aperture ratio four times the reference) has a lifetime approximately 10.6 times the reference. Thus, the density of current flowing through the organic EL element can be reduced with the increasing aperture ratio, and accordingly the lifetime of the display apparatus can be increased. The display apparatus of one embodiment of the present invention can have a higher aperture ratio and thus the display apparatus can have higher display quality. Furthermore, the display apparatus has excellent effect that the reliability (especially the lifetime) can be significantly improved with the increasing aperture ratio.

In the display apparatus of one embodiment of the present invention, an insulating layer having a high visible-light-transmitting property is provided in a space between the EL layer and the EL layer and an insulating layer having a high visible-light-blocking property is provided in a space between the EL layer and the PD layer. By providing an insulating layer having a high visible-light-transmitting property in the space between the EL layer and the EL layer, light emitted from the EL layer can be inhibited from being absorbed by, for example, the insulating layer as compared to the case of providing an insulating layer having a low visible-light-transmitting property. Thus, a display apparatus with high light extraction efficiency can be achieved. By providing an insulating layer having a high visible-light-blocking property in the space between the EL layer and the PD layer, part of light emitted from the EL layer can be inhibited from entering the PD layer due to stray light as compared to the case of providing an insulating layer having a low visible-light-blocking property. Thus, a display apparatus capable of image capturing with less noise and high sensitivity can be achieved.

In this specification and the like, for example, the term “high visible-light-transmitting property” means a high light-transmitting property with respect to light having a wavelength that is at least part of a wavelength included in visible light and the term “high visible-light-blocking property” means a high light-blocking property with respect to light having a wavelength that is at least part of a wavelength included in visible light. The same applies to light other than visible light, such as ultraviolet light or infrared light.

Here, in the case where the insulating layer is a layer containing a photosensitive material, an insulating film containing a photosensitive material can be formed as the insulating layer by performing only light exposure and development process after application of a photoresist, for example. In other words, the insulating layer can be formed without employing a dry etching method, for example. Thus, the manufacturing process of the display apparatus can be simplified.

In the method for manufacturing a display apparatus of one embodiment of the present invention, for the insulating film containing a photosensitive material, a material that has a visible-light-blocking property before light exposure and has a visible-light-transmitting property after light exposure is used. That is, for the insulating film containing a photosensitive material, a material whose visible-light-transmitting property is increased by light exposure is used. Moreover, in the method for manufacturing a display apparatus of one embodiment of the present invention, as the insulating film containing a photosensitive material, a positive insulating film, i.e., an insulating film in which the solubility of a portion exposed to light in a developer is increased is used.

Application of the insulating film is performed after the formation of the EL layer and the PD layer. Next, the applied insulating film is processed through light exposure and development process, whereby an insulating layer is formed in the space between the EL layer and the EL layer and the space between the EL layer and the PD layer. Since the applied insulating film is a positive insulating film, the formed insulating layer is not exposed to light. Thus, the insulating layer has a visible-light-blocking property.

Next, light exposure is performed on a region of the insulating layer provided in the space between the EL layer and the EL layer. Here, light exposure is not performed on the insulating layer provided in the space between the EL layer and the PD layer. The visible-light-transmitting property of the insulating layer is increased by light exposure, so that light exposure performed on the insulating layer provided in the space between the EL layer and the EL layer makes the insulating layer have a visible-light-transmitting property. Meanwhile, light exposure is not performed on the insulating layer provided in the space between the EL layer and the PD layer, so that the insulating layer has a visible-light-blocking property.

In the above manner, the insulating layer provided in the space between the EL layer and the EL layer and the insulating layer provided in the space between the EL layer and the PD layer can have different visible light transmittances while containing the same material.

### Structure Example 1

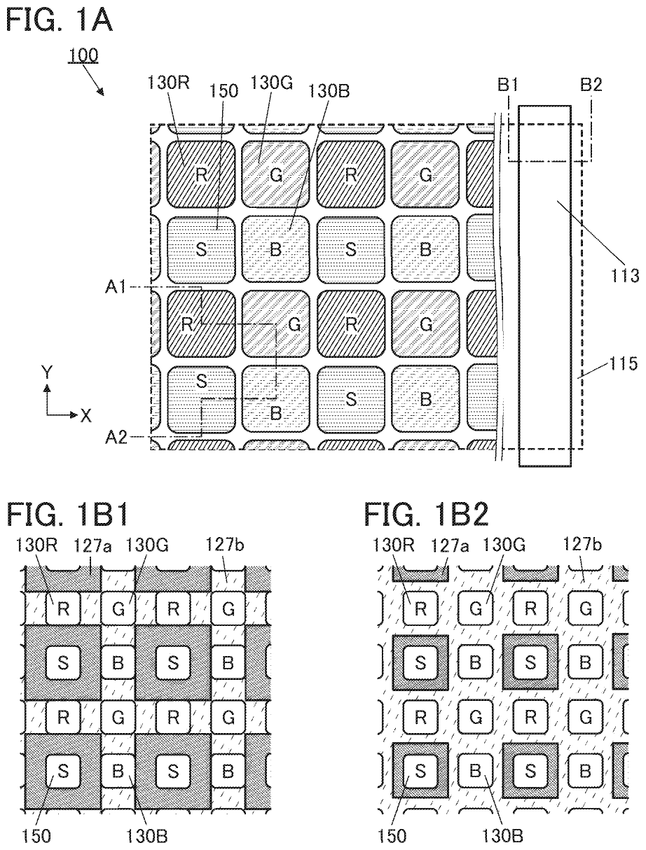

FIG. 1A illustrates a schematic top view of a display apparatus 100. The display apparatus 100 includes a plurality of light-emitting elements 130R exhibiting red, a plurality of light-emitting elements 130G exhibiting green, a plurality of light-emitting elements 130B exhibiting blue, and a plurality of light-receiving elements 150. In FIG. 1A, light-emitting regions of the light-emitting elements are denoted by R, G, and B to easily differentiate the light-emitting elements. Moreover, in FIG. 1A, light-receiving regions of the light-receiving elements are denoted by S.

In this specification and the like, in the description common to the light-emitting element 130R, the light-emitting element 130G, and the light-emitting element 130B, the term “light-emitting element 130” is used in some cases. In the description common to other components that are distinguished by alphabets, reference numerals without alphabets are sometimes used.

The light-emitting elements 130R, the light-emitting elements 130G, the light-emitting elements 130B, and the light-receiving elements 150 are arranged in a matrix. FIG. 1A illustrates a structure in which two elements are alternately arranged in one direction. Note that the arrangement method of the light-emitting elements and the light-receiving elements is not limited thereto; another arrangement method such as a stripe arrangement, an S-stripe arrangement, a delta arrangement, a Bayer arrangement, or a zigzag arrangement may be employed, a PenTile arrangement, a diamond arrangement, or the like may also be used.

As the light-emitting elements 130R, the light-emitting elements 130G, and the light-emitting elements 130B, EL elements such as OLEDs (Organic Light Emitting Diodes) or QLEDs (Quantum-dot Light Emitting Diodes) are preferably used. As a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given.

As the light-receiving element 150, a pn photodiode or a pin photodiode (PhotoDiode, also referred to as PD) can be used, for example. The light-receiving element 150 functions as a photoelectric conversion element that detects light incident on the light-receiving element 150 and generates charge. The amount of generated charge in the photoelectric conversion element is determined depending on the amount of incident light. It is particularly preferable to use an organic photodiode including a layer containing an organic compound as the light-receiving element 150. An organic photodiode, which is easily made thin, lightweight, and large in area and has a high degree of freedom for shape and design, can be used in a variety of devices.

Since the display apparatus 100 includes the light-receiving elements 150, the display apparatus 100 can capture images. Thus, the display apparatus 100 can function as an image sensor or a touch sensor. That is, in the display apparatus 100, an image can be captured in the display portion, for example. Alternatively, the display apparatus 100 can detect an object approaching the display portion or an object touching the display portion. Furthermore, since the light-emitting elements 130 provided in the display portion can be used as a light source at the time of receiving light, a light source does not need to be provided separately from the display apparatus 100. Thus, the display apparatus 100 can be a highly functional display apparatus without increasing the number of electronic components.

In the display apparatus 100, when an object reflects light emitted by the light-emitting element 130, the light-receiving element 150 can detect the reflected light. Thus, even in a dark environment, the display apparatus 100 can perform image capturing and can detect touch (including non-contact touch) of an object.

Furthermore, when a finger, a palm, or the like touches the display portion of the display apparatus 100, an image of the fingerprint or the palm print can be captured. Thus, an electronic device including the display apparatus 100 can perform biometric authentication by using the captured image of the fingerprint or the palm print. Accordingly, an image capturing device for the fingerprint authentication or the palm-print authentication does not need to be additionally provided, and the number of components of the electronic device can be reduced. Since the light-receiving elements 150 are arranged in a matrix in the display portion, an image of a fingerprint or an image of a palm print can be captured in any position in the display portion. Hence, an electronic device including the display apparatus 100 can be a highly convenient electronic device.

FIG. 1A illustrates a common electrode 115 shared by the light-emitting element 130R, the light-emitting element 130G, the light-emitting element 130B, and the light-receiving element 150 and a connection electrode 113 electrically connected to the common electrode 115.

The connection electrode 113 is supplied with a potential to be supplied to the common electrode 115. The connection electrode 113 is provided outside the display portion where the light-emitting elements 130 and the light-receiving elements 150 are arranged.

The connection electrode 113 can be provided along the outer periphery of the display portion. For example, the connection electrode 113 may be provided along one side of the outer periphery of the display portion or two or more sides of the outer periphery of the display portion. That is, in the case where the display portion has a rectangular top surface shape, a top surface shape of the connection electrode 113 can have a band shape, an L shape, a U shape (a square bracket shape), a frame-like shape, or the like.

FIG. 1B1 illustrates an insulating layer 127a and an insulating layer 127b in addition to the light-emitting element 130 and the light receiving element 150 that are illustrated in FIG. 1A. Note that in FIG. 1B1, the light-emitting region and the light-receiving region are not hatched for clarity of the drawing.

As illustrated in FIG. 1B1, the insulating layer 127a is provided around the light-receiving region. In addition, the insulating layer 127b is provided in a region that is neither the light-emitting region nor the light receiving region and not provided with the insulating layer 127a.

The insulating layer 127a is configured to have a high visible-light-blocking property, for example. Accordingly, part of light emitted from the light-emitting element 130 adjacent to the light-receiving element 150 can be inhibited from entering the light-receiving element 150 due to stray light as compared to the case where the insulating layer 127a is configured to have a high visible-light-transmitting property, for example. Thus, the display apparatus 100 can be a display apparatus capable of image capturing with less noise and high image capturing sensitivity.

Meanwhile, the insulating layer 127b is preferably configured to have a high visible-light-transmitting property. For example, the insulating layer 127b is configured to have a higher visible-light-transmitting property than the insulating layer 127a. Accordingly, for example, light emitted from an EL layer 112 can be inhibited from being absorbed by the insulating layer 127b. Thus, the display apparatus 100 can be a display apparatus with high light extraction efficiency.

Although the insulating layer 127a is in contact with the light-emitting region in FIG. 1B1, one embodiment of the present invention is not limited thereto. FIG. 1B2 illustrates an example in which the insulating layer 127a provided in the light-receiving region is not in contact with the light-emitting region.

In the example illustrated in FIG. 1B2, the area of the insulating layer 127b having a high visible-light-transmitting property in a top view can be larger than that in the example illustrated in FIG. 1B1. This can increase the light extraction efficiency of the display apparatus 100.

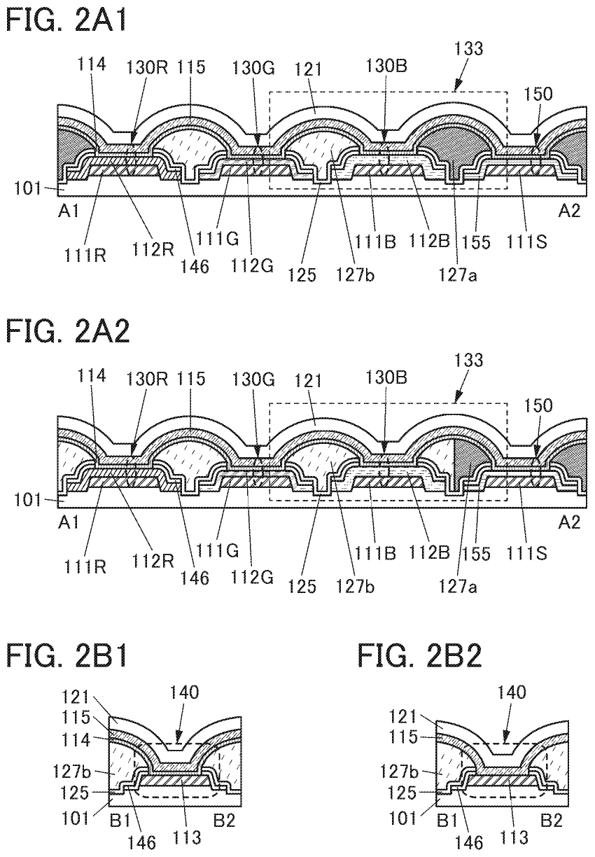

FIG. 2A1 is a schematic cross-sectional view taken along the dashed-dotted line A1-A2 in FIG. 1A and corresponds to the structure illustrated in FIG. 1B1. As illustrated in FIG. 2A1, the display apparatus 100 includes the light-emitting element 130R, the light-emitting element 130G, the light-emitting element 130B, and the light-receiving element 150 over a layer 101 including transistors.

The layer 101 including transistors can employ a stacked-layer structure in which a plurality of transistors are provided over a substrate and an insulating layer is provided to cover these transistors, for example. The layer 101 including transistors may have depressed portions between two adjacent light-emitting elements 130 and between the light-emitting element 130 and the light-receiving element 150 adjacent to each other. For example, an insulating layer positioned on the outermost surface of the layer 101 including transistors may have a depressed portion. Structure examples of the layer 101 including transistors will be described later in the following embodiment.

The light-emitting element 130R includes a pixel electrode 111R, an EL layer 112R over the pixel electrode 111R, a common layer 114 over the EL layer 112R, and the common electrode 115 over the common layer 114. The light-emitting element 130G includes a pixel electrode 111G, an EL layer 112G over the pixel electrode 111G, the common layer 114 over the EL layer 112G, and the common electrode 115 over the common layer 114. The light-emitting element 130B includes a pixel electrode 111B, an EL layer 112B over the pixel electrode 111B, the common layer 114 over the EL layer 112B, and the common electrode 115 over the common layer 114. The light-receiving element 150 includes a pixel electrode 111S, a PD layer 155 over the pixel electrode 111S, the common layer 114 over the PD layer 155, and the common electrode 115 over the common layer 114. Note that the EL layer 112 and the common layer 114 can be collectively referred to as an EL layer. The PD layer 155 and the common layer 114 can be collectively referred to as a PD layer. Moreover, the pixel electrode 111 may be referred to as a lower electrode, and the common electrode 115 may be referred to as an upper electrode.

The EL layer 112R included in the light-emitting element 130R contains at least a light-emitting organic compound that emits light with intensity in a red wavelength range (e.g., a wavelength greater than or equal to 590 nm and less than 830 nm). The EL layer 112G included in the light-emitting element 130G contains at least a light-emitting organic compound that emits light with intensity in a green wavelength range (e.g., a wavelength greater than or equal to 490 nm and less than 590 nm). The EL layer 112B included in the light-emitting element 130B contains at least a light-emitting organic compound that emits light with intensity in a blue wavelength range (e.g., a wavelength greater than or equal to 360 nm and less than 490 nm). A layer that is included in the EL layer 112 and contains a light-emitting organic compound can be referred to as a light-emitting layer. Note that the display apparatus 100 may include the EL layer 112 that emits light with intensity in an infrared wavelength range, e.g., a near infrared light wavelength range (e.g., a wavelength greater than or equal to 830 nm and less than 2500 nm).

The EL layer 112 preferably includes a carrier-transport layer over the light-emitting layer. Accordingly, the light-emitting layer is prevented from being exposed on the outermost surface in the process of manufacturing the display apparatus 100, so that damage to the light-emitting layer can be reduced. This can increase the reliability of the display apparatus 100.

Moreover, the EL layer 112 can include one or more of a hole-injection layer, a hole-transport layer, a hole-blocking layer, an electron-blocking layer, an electron-transport layer, and an electron-injection layer. For example, the EL layer 112 can have a structure in which a hole-injection layer, a hole-transport layer, a light-emitting layer, and an electron-transport layer are stacked in this order from the pixel electrode 111 side. Alternatively, the EL layer 112 can have a structure in which an electron-injection layer, an electron-transport layer, a light-emitting layer, and a hole-transport layer are stacked in this order from the pixel electrode 111 side.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that in some cases, the above-described carrier-injection layer, carrier-transport layer, and carrier-blocking layer cannot be clearly distinguished from each other depending on the cross-sectional shape, properties, or the like. One layer may have two or three functions of the carrier-injection layer, the carrier-transport layer, and the carrier-blocking layer in some cases.

The EL layer 112R, the EL layer 112G, and the EL layer 112B can be configured to have different thicknesses. Specifically, the thicknesses can be set such that optical path lengths that intensify light emitted from the EL layer 112R, the EL layer 112G, and the EL layer 112B are obtained. Accordingly, a microcavity structure can be achieved and the color purity of light emitted from the light-emitting element 130R, the light-emitting element 130G, and the light-emitting element 130B can be improved.

The PD layer 155 included in the light-receiving element 150 contains a photoelectric conversion material having sensitivity with respect to visible light or infrared light. A wavelength range to which the photoelectric conversion material contained in the PD layer 155 is sensitive preferably includes one or more of the wavelength range of light emitted from the light-emitting element 130R, the wavelength range of light emitted from the light-emitting element 130G, and the wavelength range of light emitted from the light-emitting element 130B. Alternatively, a photoelectric conversion material having sensitivity with respect to infrared light, which has a longer wavelength than light emitted from the light-emitting element 130R, may be used. A layer that is included in the PD layer 155 and contains a photoelectric conversion material can be referred to as an active layer or a photoelectric conversion layer.

In this specification and the like, visible light refers to light having a wavelength greater than or equal to 360 nm and less than 830 nm, and infrared light refers to light having a wavelength greater than or equal to 830 nm.

The PD layer 155 preferably includes a carrier-transport layer over the active layer. Accordingly, the active layer is prevented from being exposed on the outermost surface in the process of manufacturing the display apparatus 100, so that damage to the active layer can be reduced. This can increase the reliability of the display apparatus 100.

Moreover, the PD layer 155 can include one or more of a hole-transport layer, a hole-blocking layer, an electron-blocking layer, and an electron-transport layer. For example, the PD layer 155 can have a structure in which a hole-transport layer, an active layer, and an electron-transport layer are stacked in this order from the pixel electrode 111 side. Alternatively, the PD layer 155 can have a structure in which an electron-transport layer, an active layer, and a hole-transport layer are stacked in this order from the pixel electrode 111 side.

The common layer 114 can be an electron-injection layer or a hole-injection layer. In the case where the common layer 114 includes an electron-injection layer, the EL layer 112 does not need to include an electron-injection layer; in the case where the common layer 114 includes a hole-injection layer, the EL layer 112 does not need to include a hole-injection layer. Here, for the common layer 114, a material with as low electric resistance as possible is preferably used. Alternatively, it is preferable to form the common layer 114 as thin as possible, in which case the electric resistance of the common layer 114 in the thickness direction can be reduced. For example, the thickness of the common layer 114 is preferably greater than or equal to 1 nm and less than or equal to 5 nm, further preferably greater than or equal to 1 nm and less than or equal to 3 nm.

Note that the common layer 114 may include a hole-transport layer, a hole-blocking layer, an electron-blocking layer, or an electron-transport layer. In other words, the common layer 114 can include at least one of a hole-injection layer, a hole-transport layer, a hole-blocking layer, an electron-blocking layer, an electron-transport layer, and an electron-injection layer. A structure can be obtained in which the layer included in the common layer 114 is not included in the EL layer 112 and the PD layer 155.

Here, the function of the common layer 114 in the light-emitting element 130 may be different from the function of the common layer 114 in the light-receiving element 150. For example, the common layer 114 can have a function of an electron-injection layer or a hole-injection layer in the light-emitting element 130, and can have a function of an electron-transport layer or a hole-transport layer in the light-receiving element 150.

The pixel electrode 111 can be a conductive layer having a visible-light-reflecting property, and for example, a metal material can be used. For example, for the pixel electrode 111, a metal material such as gold, silver, platinum, magnesium, nickel, tungsten, chromium, molybdenum, iron, cobalt, copper, palladium, or titanium, or an alloy material containing the metal material (e.g., an alloy of silver and magnesium) can be used. Alternatively, a nitride of the metal material (e.g., titanium nitride) or the like may be used for the pixel electrode 111.

The common electrode 115 can be a conductive layer having a visible-light-transmitting property. For example, a conductive oxide such as indium oxide, indium tin oxide, indium zinc oxide, zinc oxide, or zinc oxide containing gallium, or graphene can be used for the common electrode 115. Alternatively, a metal material such as gold, silver, platinum, magnesium, nickel, tungsten, chromium, molybdenum, iron, cobalt, copper, palladium, or titanium, or an alloy material containing the metal material can be used for the common electrode 115. Further alternatively, a nitride of the metal material (e.g., titanium nitride) or the like may be used for the common electrode 115. Note that in the case of using the metal material or the alloy material (or the nitride thereof), the thickness is preferably set small enough to be able to transmit light. A stacked film of any of the above materials can be used as a conductive layer. For example, a stacked film of indium tin oxide and an alloy of silver and magnesium is preferably used for the common electrode 115, in which case the conductivity of the common electrode 115 can be increased.

A protective layer 146 is provided over the EL layer 112 and the PD layer 155. For example, the protective layer 146 is provided in regions of the EL layer 112 and the PD layer 155 that are not in contact with the common layer 114.

An insulating layer 125 and the insulating layer 127a are provided between the light-emitting element 130 and the light-receiving element 150 adjacent to each other. For example, the insulating layer 125 and the insulating layer 127a are provided between the EL layer 112 and the PD layer 155 adjacent to each other. The insulating layer 125 and the insulating layer 127b are provided between two adjacent light-emitting elements 130. For example, the insulating layer 125 and the insulating layer 127b are provided between two adjacent EL layers 112.

Specifically, the insulating layer 125 is provided on the side surface of the EL layer 112, the side surface of the PD layer 155, the side surface of the protective layer 146, the top surface of the protective layer 146, and the top surface of the layer 101 including transistors, for example. By providing the insulating layer 125, entry of impurities such as water from the side surfaces of the EL layer 112 and the PD layer 155 to the inside thereof can be inhibited.

The insulating layer 127a is provided over the insulating layer 125 and can fill a space positioned between the EL layer 112 and the PD layer 155 adjacent to each other. Moreover, the insulating layer 127b is provided over the insulating layer 125 and can fill a space positioned between two adjacent EL layers 112. Provision of the insulating layer 127a and the insulating layer 127b can inhibit generation of disconnection in the common electrode 115 over the space positioned between the EL layer 112 and the PD layer 155 adjacent to each other and the space positioned between the two adjacent EL layers 112, and can inhibit generation of a connection defect. In addition, it is possible to inhibit an increase in electric resistance due to local thinning of the common electrode 115 by the step. Consequently, the display apparatus 100 can be a highly reliable display apparatus.

In this specification and the like, disconnection refers to a phenomenon in which a layer, a film, or an electrode is split because of the shape of the formation surface (e.g., a level difference).

Note that in the display apparatus of one embodiment of the present invention, the insulating layer 127a and the insulating layer 127b are provided over the insulating layer 125 to fill depressed portions formed in the insulating layer 125. The insulating layer 127a is provided between the EL layer 112 and the PD layer 155 adjacent to each other, and the insulating layer 127b is provided between two adjacent EL layers 112. In other words, the display apparatus 100 employs a process in which the EL layer 112 and the PD layer 155 are formed and then the insulating layer 127a and the insulating layer 127b are provided to overlap with an end portion of the EL layer 112 and an end portion of the PD layer 155 (hereinafter, referred to as a process 1). Meanwhile, as a process different from the process 1, there is a process in which the pixel electrode 111 is formed in an island shape, an insulating layer (also referred to as a bank or a structure body) that covers an end portion of the top surface of the pixel electrode 111 is formed, and then the EL layer 112 is formed over the pixel electrode 111 and the insulating layer (hereinafter, referred to as a process 2).

The process 1 has a wider margin with respect to alignment accuracy between different patterning steps than the process 2 and can provide a display apparatus with few variations in characteristics. Since the method for manufacturing a display apparatus of one embodiment of the present invention is a process based on the process 1, a display apparatus with few variations and high display quality can be provided.

The protective layer 146 and the insulating layer 125 can each contain an inorganic material. As the protective layer 146 and the insulating layer 125, an inorganic insulating film such as an oxide insulating film, a nitride insulating film, an oxynitride insulating film, or a nitride oxide insulating film can be used, for example. The protective layer 146 and the insulating layer 125 may each have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, an inorganic insulating film such as an aluminum oxide film, a hafnium oxide film, or a silicon oxide film, which is formed by an atomic layer deposition (ALD) method, is used for the protective layer 146 and the insulating layer 125, whereby the protective layer 146 and the insulating layer 125 that have few pinholes and an excellent function of protecting the EL layer 112 can be formed.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The protective layer 146 and the insulating layer 125 can be formed by an ALD method, an evaporation method, a sputtering method, a chemical vapor deposition (CVD) method, a pulsed laser deposition (PLD) method, or the like. The insulating layer 125 is preferably formed by an ALD method with favorable coverage.

Here, as described above, the insulating layer 127a is configured to have a high visible-light-blocking property, for example. Accordingly, part of light emitted from the EL layer 112 adjacent to the PD layer 155 can be inhibited from entering the PD layer 155 due to stray light as compared to the case where the insulating layer 127a is configured to have a high visible-light-transmitting property, for example. Thus, the display apparatus 100 can be a display apparatus capable of image capturing with less noise and high image capturing sensitivity.

One embodiment of the present invention employs a structure in which a transmittance of light having a specific wavelength that is at least part of a visible light wavelength in the insulating layer 127a is lower than the transmittance of the light having the specific wavelength in the insulating layer 127b. For example, in the case where the specific wavelength is 450 nm in this structure, a transmittance of light having a wavelength of 450 nm in the insulating layer 127a is lower than the transmittance of the light having a wavelength of 450 nm in the insulating layer 127b. Moreover, a structure can be employed in which a transmittance of light of at least one color among red (e.g., a wavelength greater than or equal to 590 nm and less than 830 nm), green (e.g., a wavelength greater than or equal to 490 nm and less than 590 nm), and blue (e.g., a wavelength greater than or equal to 360 nm and less than 490 nm) in the insulating layer 127a is lower than the transmittance in the insulating layer 127b. For example, a structure can be employed in which a transmittance of blue light in the insulating layer 127a is lower than the transmittance of the blue light in the insulating layer 127b. Accordingly, the insulating layer 127a can be referred to as a coloring layer in some cases. For example, in the case where the insulating layer 127a blocks blue light and transmits red light and green light, the insulating layer 127a is brown.

The wavelength of light with respect to which the insulating layer 127a has a light-blocking property is preferably the wavelength of light with respect to which the PD layer 155 has sensitivity. For example, in the case where the PD layer has sensitivity with respect to light having a wavelength corresponding to blue light, the insulating layer 127a preferably has a light-blocking property with respect to light having a wavelength corresponding to blue light. Accordingly, a reduction in image capturing sensitivity of the display apparatus 100 due to stray light can be favorably inhibited.

Meanwhile, the insulating layer 127b is preferably configured to have a higher visible-light-transmitting property than the insulating layer 127a as described above. Accordingly, for example, light emitted from the EL layer 112 can be inhibited from being absorbed by the insulating layer 127b. Thus, the display apparatus 100 can be a display apparatus with high light extraction efficiency.

The insulating layer 127a and the insulating layer 127b each contain a photosensitive material. The insulating layer 127a and the insulating layer 127b each contain a photosensitive organic material, for example, and contain a photosensitive resin such as an acrylic resin, for example. The insulating layer 127a and the insulating layer 127b can each be a photoresist, for example.

Here, for the insulating layer 127a and the insulating layer 127b, a material that has a visible-light-blocking property before light exposure and has a visible-light-transmitting property after light exposure is used. That is, for the insulating layer 127a and the insulating layer 127b, a material whose visible-light-transmitting property is increased by light exposure is used. Moreover, for the insulating layer 127a and the insulating layer 127b, a positive material, i.e., a material that increases the solubility of a portion exposed to light in a developer is used.

In that case, the insulating layer 127a and the insulating layer 127b can be formed by the following method. First, application of an insulating film containing a photosensitive material is performed. Next, the applied insulating film is processed through light exposure and development process, whereby an insulating layer is formed between the EL layer 112 and the PD layer 155 adjacent to each other and between two adjacent EL layers 112. Since the applied insulating film is a positive insulating film, the formed insulating layer is not exposed to light. Thus, the insulating layer has a visible-light-blocking property.

Next, light exposure is performed on a region of the insulating layer provided between the two adjacent EL layers 112. Here, light exposure is not performed on the insulating layer provided between the EL layer 112 and the PD layer 155 adjacent to each other. The visible-light-transmitting property of the insulating layer is increased by light exposure, so that light exposure performed on the insulating layer provided between the two adjacent EL layers 112 changes the insulating layer into the insulating layer 127b having a visible-light-transmitting property. Meanwhile, light exposure is not performed on the insulating layer provided between the EL layer 112 and the PD layer 155, so that the insulating layer has a visible-light-blocking property. The insulating layer having a visible-light-blocking property is the insulating layer 127a.

In the above manner, the insulating layer 127a and the insulating layer 127b can have different visible light transmittances while containing the same material.

Here, for the insulating layer 127b, a photocurable material that is cured by light exposure is preferably used. Specifically, for an insulating film to be the insulating layer 127a and the insulating layer 127b, a photocurable material is preferably used. Thus, a change in the shape of the insulating layer 127b can be suppressed as compared to the case of using a material that is plasticized by light exposure for the insulating layer 127b. Therefore, the display apparatus 100 can be a highly reliable display apparatus. Accordingly, for the insulating layer 127a and the insulating layer 127b, a positive photosensitive material having photocurability can be used. That is, the insulating layer 127a and the insulating layer 127b can have a property in which solubility in a developer is increased by light exposure but the shape is hardly changed without immersion in a developer.

In the display apparatus 100, a reflective film (e.g., a metal film containing one or more selected from silver, palladium, copper, titanium, aluminum, and the like) may be provided between the insulating layer 125 and the insulating layer 127b so that light emitted from the light-emitting layer is reflected by the reflective film; hence, the function of increasing the light extraction efficiency may be added.

A protective layer 121 is provided over the common electrode 115 to cover the light-emitting elements 130 and the light-receiving element 150. The protective layer 121 has a function of preventing diffusion of impurities such as water into the light-emitting elements 130 and the light-receiving element 150 from above.

The protective layer 121 can have, for example, a single-layer structure or a stacked-layer structure including at least an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 121.

As the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. With this, the top surface of the organic insulating film can be flat, and accordingly, coverage with the inorganic insulating film thereover is improved, leading to an improvement in barrier properties. Moreover, the top surface of the protective layer 121 is flat; therefore, when a component (e.g., a color filter, an electrode of a touch sensor, a lens array, or the like) is provided above the protective layer 121, the component can be less affected by an uneven shape caused by the lower structure.

FIG. 2A2 is a schematic cross-sectional view taken along the dashed-dotted line A1-A2 in FIG. 1A and corresponds to the structure illustrated in FIG. 1B2. The structure illustrated in FIG. 2A2 is a modification example of the structure illustrated in FIG. 2A1.

In the example illustrated in FIG. 2A2, the insulating layer 127b is provided not only between two adjacent light-emitting elements 130 but also between the light-emitting element 130 and the light-receiving element 150 adjacent to each other. Specifically, in a region between the light-emitting element 130 and the light-receiving element 150 adjacent to each other, the insulating layer 127b is provided in a region close to the light-emitting element 130 and the insulating layer 127a is provided in a region close to the light-receiving element 150.

By employing the structure illustrated in FIG. 2A2, the area of the insulating layer 127b having a high visible-light-transmitting property in a top view can be larger than that in the example illustrated in FIG. 2A1. This can increase the light extraction efficiency of the display apparatus 100.

FIG. 2B1 is a schematic cross-sectional view taken along the dashed-dotted line B1-B2 in FIG. 1A and illustrates a connection portion 140 where the connection electrode 113 is electrically connected to the common electrode 115.

The connection portion 140 includes the connection electrode 113 over the layer 101 including transistors, the common layer 114 over the connection electrode 113, the common electrode 115 over the common layer 114, and the protective layer 121 over the common electrode 115. The protective layer 146 is provided to cover an end portion of the connection electrode 113, and the insulating layer 125, the insulating layer 127b, the common layer 114, the common electrode 115, and the protective layer 121 are stacked in this order over the protective layer 146. Note that in the connection portion 140, the insulating layer 127a may be provided instead of the insulating layer 127b.

In the connection portion 140, the connection electrode 113 is electrically connected to the common electrode 115. The connection electrode 113 is electrically connected to an FPC (not illustrated), for example. Accordingly, by supplying a power supply potential to the FPC, for example, the power supply potential can be supplied to the common electrode 115 through the connection electrode 113.

The connection electrode 113 can be formed through a process similar to that for the pixel electrode 111. For example, by forming a conductive film over the layer 101 including transistors and processing the conductive film by an etching method, for example, the pixel electrode 111 and the connection electrode 113 can be formed. Thus, the connection electrode 113 can contain a material similar to that for the pixel electrode 111.

Here, in the case where the electric resistance of the common layer 114 in the thickness direction is negligible, electrical continuity between the connection electrode 113 and the common electrode 115 can be ensured even when the common layer 114 is provided between the connection electrode 113 and the common electrode 115. When the common layer 114 is provided not only in the display portion but also in the connection portion 140, the common layer 114 can be formed, for example, without using a metal mask such as a mask for specifying a deposition area (also referred to as an area mask or a rough metal mask to be distinguished from a fine metal mask). Thus, the manufacturing process of the display apparatus 100 can be simplified, which leads to a reduction in manufacturing cost of the display apparatus 100. Thus, the display apparatus 100 can be an inexpensive display apparatus.

FIG. 2B2 is a modification example of the structure illustrated in FIG. 2B1. FIG. 2B2 illustrates a structure example in which the common layer 114 is not provided in the connection portion 140. The example illustrated in FIG. 2B2 can employ a structure in which the connection electrode 113 is in contact with the common electrode 115. Thus, electric resistance between the connection electrode 113 and the common electrode 115 can be reduced.

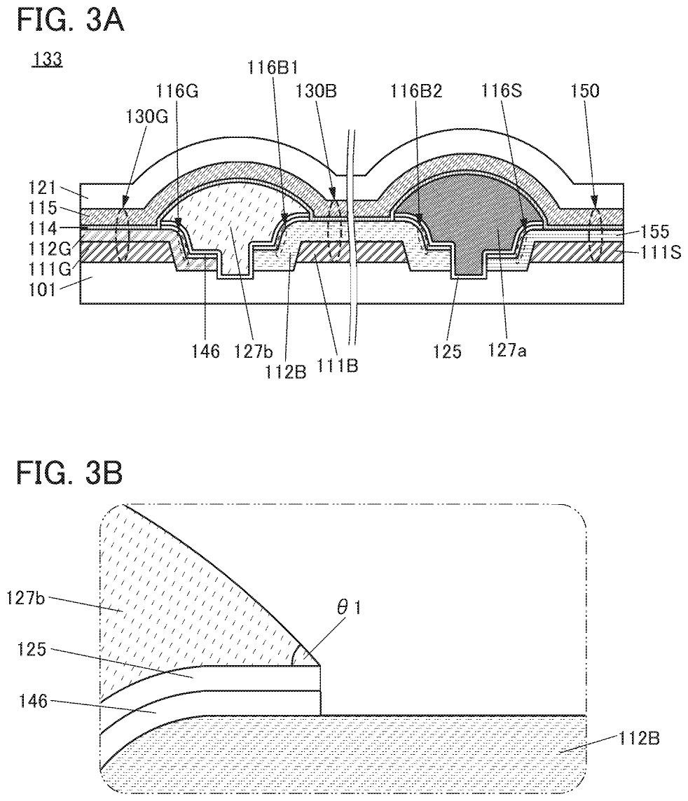

FIG. 3A is an enlarged view of a region 133 illustrated in FIG. 2A1. FIG. 3A illustrates the insulating layer 127a, the insulating layer 127b, and a peripheral region thereof.

An end portion of the pixel electrode 111 preferably has a tapered shape as illustrated in FIG. 3A, in which case a foreign substance (also referred to as dust or particles, for example) generated during the manufacturing process can be favorably removed by treatment such as cleaning.

In this specification and the like, a tapered shape indicates a shape in which at least part of the side surface of a structure is inclined to a substrate surface. For example, a tapered shape preferably includes a region where the angle between the inclined side surface and the substrate surface (such an angle is also referred to as a taper angle) is less than 90°.

The EL layer 112 and the PD layer 155 can each be provided to cover the end portion of the pixel electrode 111. FIG. 3A illustrates an example in which the EL layer 112G covers an end portion of the pixel electrode 111G, the EL layer 112B covers an end portion of the pixel electrode 111B, and the PD layer 155 covers an end portion of the pixel electrode 111S. Here, when the end portion of the pixel electrode 111 has a tapered shape, the EL layer 112 and the PD layer 155 can each include a tapered portion 116 in a cross-sectional view. FIG. 3A illustrates an example in which the EL layer 112G includes a tapered portion 116G between the end portion of the pixel electrode 111G and the insulating layer 127b. FIG. 3A illustrates an example in which the EL layer 112B includes a tapered portion 116B1 between the left end portion of the pixel electrode 111B and the insulating layer 127b and a tapered portion 116B2 between the right end portion of the pixel electrode 111B and the insulating layer 127a. FIG. 3A illustrates an example in which the PD layer 155 includes a tapered portion 116S between the end portion of the pixel electrode 111S and the insulating layer 127a.

The taper angle of the side surface of the pixel electrode 111 is less than 90°, preferably less than or equal to 60°, further preferably less than or equal to 45°. Such a forward tapered shape of the side surface of the pixel electrode 111 can prevent disconnection, local thinning, or the like from occurring in the EL layer 112 provided to cover the side surface of the pixel electrode 111, leading to formation with good coverage. Accordingly, the display apparatus 100 can be a highly reliable display apparatus.

The size of a taper angle of the tapered portion 116 can be a size corresponding to the taper angle of the side surface of the pixel electrode 111. For example, the smaller the taper angle of the side surface of the pixel electrode 111 is, the smaller the size of the taper angle of the tapered portion 116 can be. The taper angle of the tapered portion 116 is less than 90°, preferably less than or equal to 60°, further preferably less than or equal to 45°.

FIG. 3A illustrates an example in which the bottom surface of the insulating layer 125 is positioned below the bottom surface of the EL layer 112 and the bottom surface of the PD layer 155, and the bottom surface of the EL layer 112 and the bottom surface of the PD layer 155 are positioned below the bottom surface of the pixel electrode 111. In the display apparatus 100 having such a structure, the layer 101 including transistors can be configured to include depressed portions between the EL layers 112 and between the EL layer 112 and the PD layer 155, for example. Although the details will be described later, the depressed portions are formed during the formation of the EL layer 112 and the PD layer 155.

FIG. 3B is an enlarged view of the vicinity of an end portion of the insulating layer 127b over the EL layer 112B illustrated in FIG. 3A. The description with reference to FIG. 3B can also be applicable to the EL layer 112R, the EL layer 112G, the PD layer 155, and the insulating layer 127a. The same applies to the enlarged view of the vicinity of the end portion of the insulating layer 127b over the EL layer 112B in drawings other than FIG. 3B.

As illustrated in FIG. 3B, the side surface of the insulating layer 127b preferably has a tapered shape with a taper angle θ1 in the cross-sectional view of the display apparatus 100. The taper angle θ1 is an angle formed by the side surface of the insulating layer 127b and the substrate surface. Note that the taper angle θ1 may be an angle formed by the side surface of the insulating layer 127b and, instead of the substrate surface, the top surface of a flat portion of the insulating layer 125, the top surface of a flat portion of the EL layer 112B, the top surface of a flat portion of the pixel electrode 111, or the like.

The taper angle θ1 of the insulating layer 127b is less than 90°, preferably less than or equal to 60°, further preferably less than or equal to 45°. Such a forward tapered shape of the end portion of the side surface of the insulating layer 127b can prevent disconnection, local thinning, or the like from occurring in the common layer 114 and the common electrode 115 which are provided over the end portion of the side surface of the insulating layer 127b, leading to deposition with good coverage. Consequently, the in-plane uniformity of the common layer 114 and the common electrode 115 can be increased, so that the display quality of the display apparatus can be improved.

### Structure Example 2

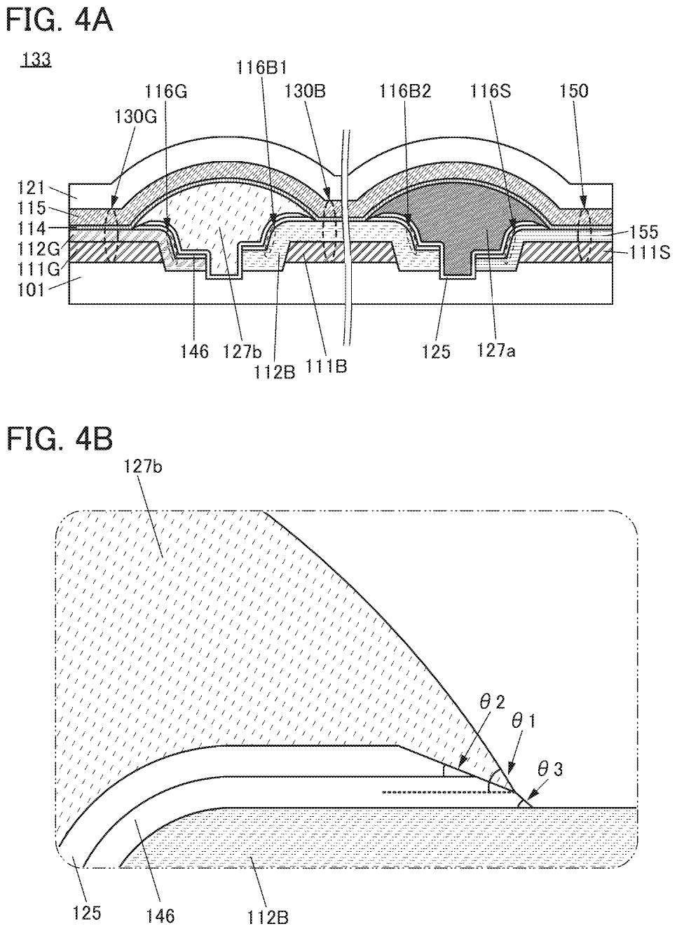

FIG. 4A is a modification example of the structure of the region 133 illustrated in FIG. 3A. The region 133 illustrated in FIG. 4A is different from the region 133 illustrated in FIG. 3A in the shapes of end portions of the protective layer 146, the insulating layer 125, and the insulating layer 127a, the end portion of the insulating layer 127b, and the like.

FIG. 4B is an enlarged view of the vicinity of the end portion of the insulating layer 127b over the EL layer 112B illustrated in FIG. 4A and is a modification example of the structure illustrated in FIG. 3B.

In the structure illustrated in FIG. 4B, the end portion of the insulating layer 127b is positioned on the outer side of the end portion of the insulating layer 125. Accordingly, unevenness of the surface where the common layer 114 and the common electrode 115 are formed is reduced, and coverage with the common layer 114 and the common electrode 115 can be improved.

As illustrated in FIG. 4B, the end portion of the insulating layer 125 preferably has a tapered shape with a taper angle θ2 in the cross-sectional view of the display apparatus. The taper angle θ2 is an angle formed by the side surface of the insulating layer 125 and the substrate surface. Note that the taper angle θ2 may be an angle formed by the side surface of the insulating layer 125 and, instead of the substrate surface, the top surface of the flat portion of the EL layer 112B or the top surface of the flat portion of the pixel electrode 111.

The taper angle θ2 of the insulating layer 125 is less than 90°, preferably less than or equal to 60°, further preferably less than or equal to 45°, still further preferably less than or equal to 20°.

As illustrated in FIG. 4B, the end portion of the protective layer 146 preferably has a tapered shape with a taper angle θ3 in the cross-sectional view of the display apparatus. The taper angle θ3 is an angle formed by the side surface of the protective layer 146 and the substrate surface. Note that the taper angle θ3 may be an angle formed by the side surface of the protective layer 146 and, instead of the substrate surface, the top surface of the flat portion of the EL layer 112B or the top surface of the flat portion of the pixel electrode 111.

The taper angle θ3 of the protective layer 146 is less than 90°, preferably less than or equal to 60°, further preferably less than or equal to 45°, still further preferably less than or equal to 20°. When the protective layer 146 has such a forward tapered shape, the common layer 114 and the common electrode 115 that are provided over the protective layer 146 can be deposited with favorable coverage.

The end portion of the protective layer 146 is preferably positioned on the outer side of the end portion of the insulating layer 125. Accordingly, unevenness of the surface where the common layer 114 and the common electrode 115 are formed is reduced, and coverage with the common layer 114 and the common electrode 115 can be improved.

Although the details will be described later, when the insulating layer 125 and the protective layer 146 are etched at once, the insulating layer 125 and the protective layer 146 under the end portion of the insulating layer 127b may disappear because of side-etching and a void may be formed. The void causes unevenness on the formation surface of the common layer 114 and the common electrode 115; hence, disconnection is more likely to be caused in the common layer 114 and the common electrode 115. Accordingly, when etching treatment is divided into two steps and heat treatment is performed therebetween, even if a void is formed by the first etching treatment, the shape of the insulating layer 127b is changed by the heat treatment to fill the void. Since the second etching treatment is for etching a thinner film, the amount of side-etching decreases, a void is less likely to be formed, and even if a void is formed, it can be extremely small. Thus, unevenness can be inhibited from being formed on the formation surface of the common layer 114 and the common electrode 115, and disconnection in the common layer 114 and the common electrode 115 can be suppressed. Since the etching treatment is performed twice in such a manner, the taper angle θ2 and the taper angle θ3 may be angles different from each other. Furthermore, the taper angle θ2 and the taper angle θ3 may each be an angle smaller than the taper angle θ1.

The insulating layer 127b may cover at least part of the side surface of the protective layer 146. For example, FIG. 4B illustrates an example in which the insulating layer 127b touches and covers a sloping surface that is formed by the first etching treatment and positioned at the end portion of the protective layer 146, and a sloping surface that is formed by the second etching treatment and positioned at the end portion of the protective layer 146 is exposed. These two sloping surfaces can sometimes be distinguished from each other because of different taper angles.

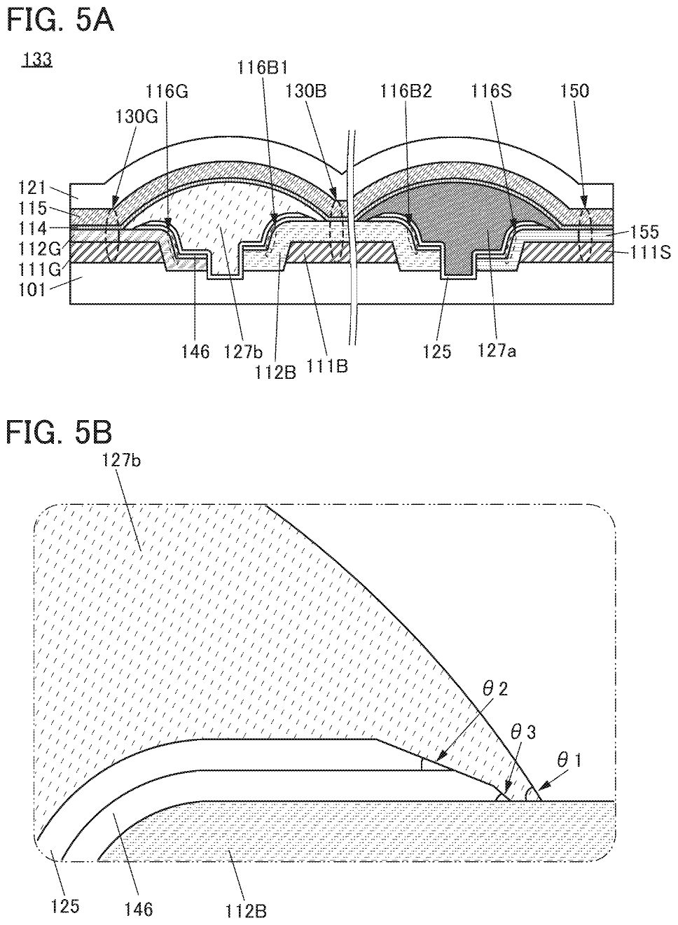

FIG. 5A and FIG. 5B illustrate an example in which the insulating layer 127b covers the entire side surface of the protective layer 146. Specifically, in FIG. 5B, the insulating layer 127b touches and covers both of the two sloping surfaces. This is preferred because unevenness on the formation surface of the common layer 114 and the common electrode 115 can be further reduced.

### Manufacturing Method Example 1

Hereinafter, a manufacturing method example of a display apparatus of one embodiment of the present invention will be described with reference to drawings. Here, description is made using the display apparatus 100 described in the above structure example as an example.

Note that thin films included in the display apparatus (insulating films, semiconductor films, conductive films, and the like) can be formed by a sputtering method, a CVD method, a vacuum evaporation method, a PLD method, an ALD method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organic CVD) method. Examples of the ALD method include a PEALD method and a thermal ALD method.

Alternatively, thin films included in the display apparatus (insulating films, semiconductor films, conductive films, and the like) can be formed by a method such as spin coating, dipping, spray coating, ink-jetting, dispensing, screen printing, offset printing, doctor blade coating, slit coating, roll coating, curtain coating, or knife coating.

The thin films included in the display apparatus can be processed by a photolithography method, for example. Besides, a nanoimprinting method, a sandblasting method, a lift-off method, or the like may be used for the processing of the thin films. Alternatively, island-shaped thin films may be directly formed by a deposition method using a shielding mask such as a metal mask.

There are the following two typical methods of a photolithography method. In one of the methods, a resist mask is formed over a thin film that is to be processed, the thin film is processed by, for example, etching, and then the resist mask is removed. In the other method, a photosensitive thin film is deposited and then processed into a desired shape by light exposure and development.

For light used for light exposure in a photolithography method, for example, it is possible to use light with the i-line (wavelength: 365 nm), light with the g-line (wavelength: 436 nm), light with the h-line (wavelength: 405 nm), or combined light of any of them. For light used for light exposure in a photolithography method, ultraviolet light, KrF laser light (wavelength: 248 nm), or ArF laser light (wavelength: 193 nm) may be used. Light exposure may be performed by liquid immersion exposure technique. For light used for the light exposure, extreme ultraviolet (EUV) light or X-rays may be used. Furthermore, instead of light used for the light exposure, an electron beam can also be used. It is preferable to use extreme ultraviolet light, X-rays, or an electron beam because extremely minute processing can be performed. Note that a photomask is not needed when light exposure is performed by scanning with a beam such as an electron beam.

For etching of the thin film, a dry etching method, a wet etching method, a sandblast method, or the like can be used.

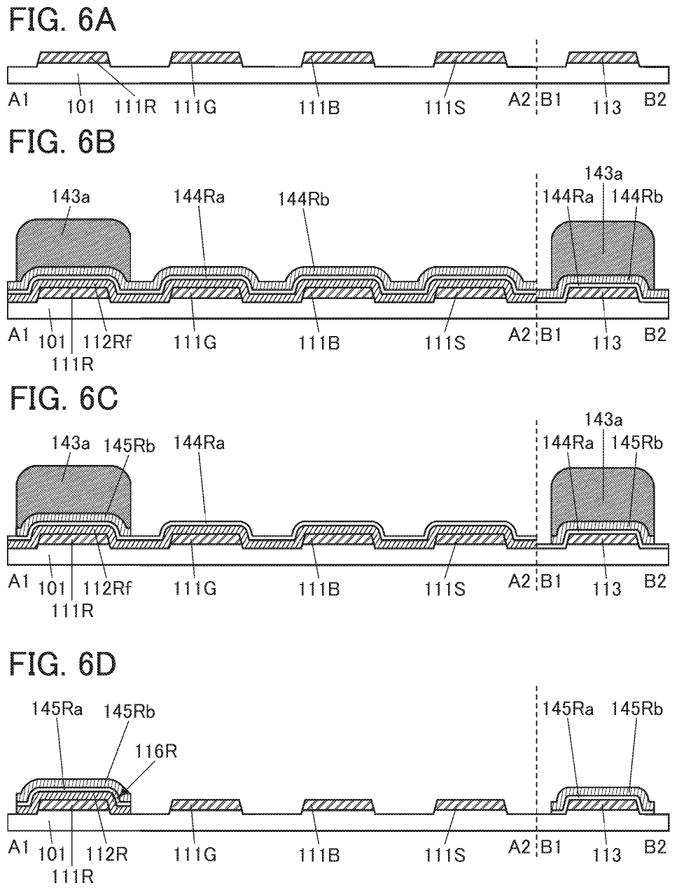

FIG. 6A to FIG. 12B are schematic cross-sectional views illustrating an example of a method for manufacturing the display apparatus 100 in which the light-emitting elements 130 and the light-receiving element 150 have the structure illustrated in FIG. 2A1 and the connection portion 140 has the structure illustrated in FIG. 2B1.

To manufacture the display apparatus 100, first, the layer 101 including transistors is formed as illustrated in FIG. 6A. Next, as illustrated in FIG. 6A, over the layer 101 including transistors, e.g., over an insulating layer positioned on the outermost surface of the layer 101 including transistors, the pixel electrode 111R, the pixel electrode 111G, the pixel electrode 111B, the pixel electrode 111S, and the connection electrode 113 are formed. For example, a conductive film is formed over the layer 101 including transistors and then part of the conductive film is removed by etching, whereby the pixel electrode 111R, the pixel electrode 111G, the pixel electrode 111B, the pixel electrode 111S, and the connection electrode 113 can be formed. In the formation of the pixel electrode 111R, the pixel electrode 111G, the pixel electrode 111B, the pixel electrode 111S, and the connection electrode 113, a depressed portion may be formed in the layer 101 including transistors. For example, a depressed portion may be formed in the insulating layer positioned on the outermost surface of the layer 101 including transistors. For example, when the conductive film formed over the layer 101 including transistors has high etching selectivity over the insulating layer positioned on the outermost surface of the layer 101 including transistors, a depressed portion is not formed in the layer 101 including transistors in some cases.

Subsequently, as illustrated in FIG. 6B, an EL film 112Rf to be the EL layer 112R later is formed over the pixel electrode 111R, the pixel electrode 111G, the pixel electrode 111B, the pixel electrode 111S, and the layer 101 including transistors. Here, the EL film 112Rf can be provided not to overlap with the connection electrode 113. For example, the EL film 112Rf can be formed not to overlap with the connection electrode 113 by shielding a region including the connection electrode 113 with a metal mask and then forming the EL film 112Rf. The metal mask used here does not need to shield a pixel region of the display portion; hence, a fine mask is not required, and a rough metal mask can be used, for example.

The EL film 112Rf includes at least a film containing a light-emitting compound (a light-emitting film). The EL film 112Rf preferably includes a light-emitting film and a film functioning as a carrier-transport layer over the light-emitting film. Accordingly, the light-emitting film is inhibited from being exposed on the outermost surface in the process of manufacturing the display apparatus 100, so that damage to the light-emitting film can be reduced. This can increase the reliability of the display apparatus 100.

Moreover, the EL film 112Rf may have a structure in which one or more films functioning as a hole-injection layer, a hole-transport layer, a hole-blocking layer, an electron-blocking layer, an electron-transport layer, and an electron-injection layer are stacked. For example, the EL film 112Rf can have a structure in which a film functioning as a hole-injection layer, a film functioning as a hole-transport layer, the light-emitting film, and a film functioning as an electron-transport layer are stacked in this order. Alternatively, the EL film 112Rf can have a structure in which a film functioning as an electron-injection layer, a film functioning as an electron-transport layer, the light-emitting film, and a film functioning as a hole-transport layer are stacked in this order.

The EL film 112Rf can be formed by, for example, an evaporation method, a sputtering method, or an inkjet method. Without limitation to this, the above-described deposition method can be used as appropriate.

Next, a mask film 144Ra is formed over the EL film 112Rf, the connection electrode 113, and the layer 101 including transistors, and a mask film 144Rb is formed over the mask film 144Ra. That is, a mask film having a two-layer stacked structure is formed over the EL film 112Rf, the connection electrode 113, and the layer 101 including transistors. Note that the mask film may have a single-layer structure or a stacked-layer structure of three or more layers. In a subsequent process of forming another mask film, a mask film has a two-layer stacked structure; however, the mask film may have a single-layer structure or a stacked-layer structure of three or more layers. The mask film may be referred to as a sacrificial film.

The mask film 144Ra and the mask film 144Rb can be formed by, for example, a sputtering method, a CVD method, an ALD method, or a vacuum evaporation method. Note that a formation method that causes less damage to the EL film is preferable, and the mask film 144Ra formed directly on the EL film 112Rf is preferably formed by an ALD method or a vacuum evaporation method.

As the mask film 144Ra, an inorganic film such as a metal film, an alloy film, a metal oxide film, a semiconductor film, or an inorganic insulating film or an organic film such as an organic insulating film can be suitably used.

Alternatively, an oxide film can be used as the mask film 144Ra. An oxide film or an oxynitride film of silicon oxide, silicon oxynitride, aluminum oxide, aluminum oxynitride, hafnium oxide, hafnium oxynitride, or the like can be typically used. For example, a nitride film can also be used as the mask film 144Ra. Specifically, it is also possible to use a nitride such as silicon nitride, aluminum nitride, hafnium nitride, titanium nitride, tantalum nitride, tungsten nitride, gallium nitride, or germanium nitride. A film containing such an inorganic insulating material can be formed by a deposition method such as a sputtering method, a CVD method, or an ALD method; the mask film 144Ra, which is formed directly on the EL film 112Rf, is particularly preferably formed by an ALD method.

For the mask film 144Ra, a metal material such as nickel, tungsten, chromium, molybdenum, cobalt, palladium, titanium, aluminum, yttrium, zirconium, or tantalum or an alloy material containing the metal material can be used, for example. It is particularly preferable to use a low-melting-point material such as aluminum or silver.

Alternatively, for the mask film 144Ra, a metal oxide such as indium gallium zinc oxide (In—Ga—Zn oxide) can be used. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, for example, indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be employed instead of gallium. Specifically, M is preferably one or more kinds selected from gallium, aluminum, and yttrium.

Any of the above-described materials usable for the mask film 144Ra can be used for the mask film 144Rb. For example, from the above materials usable for the mask film 144Ra, one material can be selected for the mask film 144Ra and another material can be selected for the mask film 144Rb. Alternatively, one or more materials can be selected for the mask film 144Ra from the above materials usable for the mask film 144Ra, and one or more materials selected from the materials excluding the material(s) selected for the mask film 144Ra can be used for the mask film 144Rb.

Specifically, aluminum oxide formed by an ALD method is preferably used for the mask film 144Ra, and silicon nitride formed by a sputtering method is suitably used for the mask film 144Rb. In the case of employing this structure, the deposition temperature at the time of depositing the materials by an ALD method and a sputtering method is preferably higher than or equal to room temperature and lower than or equal to 120° C., further preferably higher than or equal to room temperature and lower than or equal to 100° C., in which case adverse effects on the EL film 112Rf can be reduced. In the case of the stacked-layer structure of the mask film 144Ra and the mask film 144Rb, a stress applied to the stacked-layer structure is preferably small. Specifically, a stress applied to the stacked-layer structure is preferably higher than or equal to −500 MPa and less than or equal to +500 MPa, further preferably higher than or equal to −200 MPa and lower than or equal to +200 MPa, in which case troubles in the process, such as film separation and peeling, can be inhibited.

As the mask film 144Ra, it is possible to use a film highly resistant to etching treatment performed on various EL films such as the EL film 112Rf, i.e., a film having high etching selectivity. Moreover, as the mask film 144Ra, it is particularly preferable to use a film that can be removed by a wet etching method less likely to cause damage to EL films.

For the mask film 144Ra, a material that can be dissolved in a chemically stable solvent may be used. In particular, a material that is dissolved in water or alcohol can be suitably used for the mask film 144Ra. In deposition of the mask film 144Ra, it is preferable that application of such a material dissolved in a solvent such as water or alcohol be performed by a wet deposition method and followed by heat treatment for evaporating the solvent. At this time, the heat treatment is preferably performed in a reduced-pressure atmosphere, in which case the solvent can be removed at a low temperature in a short time and thermal damage to the EL film 112Rf can be reduced accordingly.

Examples of the wet deposition method that can be used for forming the mask film 144Ra include spin coating, dipping, spray coating, ink-jetting, dispensing, screen printing, offset printing, doctor blade coating, slit coating, roll coating, curtain coating, knife coating, and the like.

For the mask film 144Ra, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

A film, which has high etching selectivity over the mask film 144Ra, is used as the mask film 144Rb.

Preferably, an inorganic insulating material such as aluminum oxide, hafnium oxide, or silicon oxide formed by an ALD method is used for the mask film 144Ra, and a metal material such as nickel, tungsten, chromium, molybdenum, cobalt, palladium, titanium, aluminum, yttrium, zirconium, or tantalum or an alloy material containing any of the metal materials formed by a sputtering method is used for the mask film 144Rb. Tungsten formed by a sputtering method is particularly preferably used for the mask film 144Rb. Alternatively, a metal oxide containing indium, such as indium gallium zinc oxide (also denoted as In—Ga—Zn oxide), formed by a sputtering method may be used for the mask film 144Rb. Furthermore, an inorganic material may be used for the mask film 144Rb. For example, it is possible to use an oxide film or a nitride film such as a silicon oxide film, a silicon oxynitride film, a silicon nitride oxide film, a silicon nitride film, an aluminum oxide film, an aluminum oxynitride film, or a hafnium oxide film.

Alternatively, as the mask film 144Rb, an organic film that can be used for the EL film 112Rf and the like may be used. For example, the same film as the organic film is used for the EL film 112Rf can be used as the mask film 144Rb. The use of such an organic film is preferable, in which case the deposition apparatus for the EL film 112Rf can be used in common. Furthermore, the mask film 144Rb can be removed at the same time as the etching of the EL film 112Rf; thus, the process can be simplified.

Next, a resist mask 143a is formed over the mask film 144Rb as illustrated in FIG. 6B. For the resist mask 143a, a resist material containing a photosensitive resin, such as a positive resist material or a negative resist material can be used. For the resist mask 143a, a material that is the same as a material that can be used for the insulating layer 127a and the insulating layer 127b can be used. The resist mask 143a can be formed by performing application of a resist material and then performing light exposure and development, for example.

Then, as illustrated in FIG. 6C, part of the mask film 144Rb, which is not covered with the resist mask 143a, is removed by etching, whereby an island-shaped or band-shaped mask layer 145Rb is formed. The mask layer 145Rb can be formed over the pixel electrode 111R and the connection electrode 113, for example. The mask film and the mask layer have a function of protecting the EL layer and the PD layer in the manufacturing process of the display apparatus.

The mask film 144Rb can be processed by a wet etching method or a dry etching method. For example, the mask film 144Rb can be processed by a dry etching method using a fluorine-containing gas. This can inhibit a reduction in a pattern. The etching of the mask film 144Rb preferably employs etching conditions having high selectivity over the mask film 144Ra.

Next, the resist mask 143a is removed as illustrated in FIG. 6D. The mask film 144Ra and the EL film 112Rf are processed to form a mask layer 145Ra and the EL layer 112R. In the case where an end portion of the pixel electrode 111R has a tapered shape and the EL layer 112R covers the end portion of the pixel electrode 111R, the EL layer 112R can include a tapered portion 116R.

In the case where the mask film 144Ra and the EL film 112Rf are processed after the removal of the resist mask 143a, the mask layer 145Rb can be used as a hard mask.

In this specification and the like, a mask harder than a resist mask is referred to as a hard mask.

The removal of the resist mask 143a and the processing of the mask film 144Ra can be performed by a wet etching method or a dry etching method. For example, the resist mask 143a can be removed by a dry etching method using an oxygen-containing gas (also referred to as an oxygen gas) (such a method is also referred to as a plasma ashing method). The processing of the mask film 144Ra can be performed by a method similar to that for the processing of the mask film 144Rb.

When the mask film 144Ra is etched using the mask layer 145Rb as a hard mask, the resist mask 143a can be removed while the EL film 112Rf is covered with the mask film 144Ra. For example, if the EL film 112Rf is exposed to oxygen, the electrical characteristics of the light-emitting element 130R are adversely affected in some cases. Thus, in the case where the resist mask 143a is removed by a method using an oxygen gas, such as plasma ashing, the mask film 144Ra is preferably etched using the mask layer 145Rb as a hard mask.

The etching of the EL film 112Rf is preferably performed by a dry etching method using an oxygen gas. Accordingly, the etching rate of the EL film 112Rf can be increased. Thus, etching under a low-power condition can be performed while the etching rate is kept adequately high; hence, damage due to the etching can be reduced. Furthermore, a defect such as attachment of a reaction product generated at the etching onto, for example, the EL layer 112R can be inhibited.

Alternatively, when the EL film 112Rf is etched by a dry etching method using an etching gas that does not contain oxygen as its main component, a change in properties of the EL film 112Rf can be inhibited, so that the display apparatus 100 can be a highly reliable display apparatus. Examples of the etching gas that does not contain oxygen as its main component include a gas containing CF₄, C₄F₈, SF₆, CHF₃, Cl₂, H₂O, BCl₃, or the like and a gas containing a Group 18 element such as Ar or He. Alternatively, a mixed gas of the above gas and a dilution gas that does not contain oxygen can be used as the etching gas. Note that etching of the EL film 112Rf is not limited to the above and may be performed by a dry etching method using another gas or a wet etching method.

If impurities are attached to the side surface of the EL layer 112R when the EL layer 112R is formed by the etching of the EL film 112Rf, the impurities might enter the inside of the EL layer 112R in the subsequent process. This degrades the reliability of the display apparatus 100 in some cases. Thus, it is preferable to remove impurities attached to the surface of the EL layer 112R after the formation of the EL layer 112R, in which case the reliability of the display apparatus 100 can be increased.

Impurities attached to the surface of the EL layer 112R can be removed, for example, by irradiation of the surface of the EL layer 112R with an inert gas. Here, the surface of the EL layer 112R is exposed immediately after the EL layer 112R is formed. Specifically, the side surface of the EL layer 112R is exposed. Accordingly, impurities attached to the EL layer 112R can be removed, for example, when the substrate where the EL layer 112R is formed is put in an inert gas atmosphere after the formation of the EL layer 112R. As the inert gas, one or more selected from Group 18 elements (typically, helium, neon, argon, xenon, and krypton) and nitrogen can be used, for example.

Note that in the case where the EL film 112Rf is processed, a method can be considered in which processing is performed by a photolithography method directly on a light-emitting film included in the EL film 112Rf In this case, damage to the light-emitting layer (e.g., processing damage) might significantly degrade the reliability. In view of this, in order to manufacture the display apparatus 100, the mask layer 145Ra and the mask layer 145Rb are formed over a film (e.g., a film functioning as a carrier-transport layer or a carrier-injection layer, more specifically, an electron-transport layer, a hole-transport layer, an electron-injection layer, and a hole-injection layer) positioned above the light-emitting film, and then the light-emitting film is processed. Thus, the display apparatus 100 can be a highly reliable display apparatus.

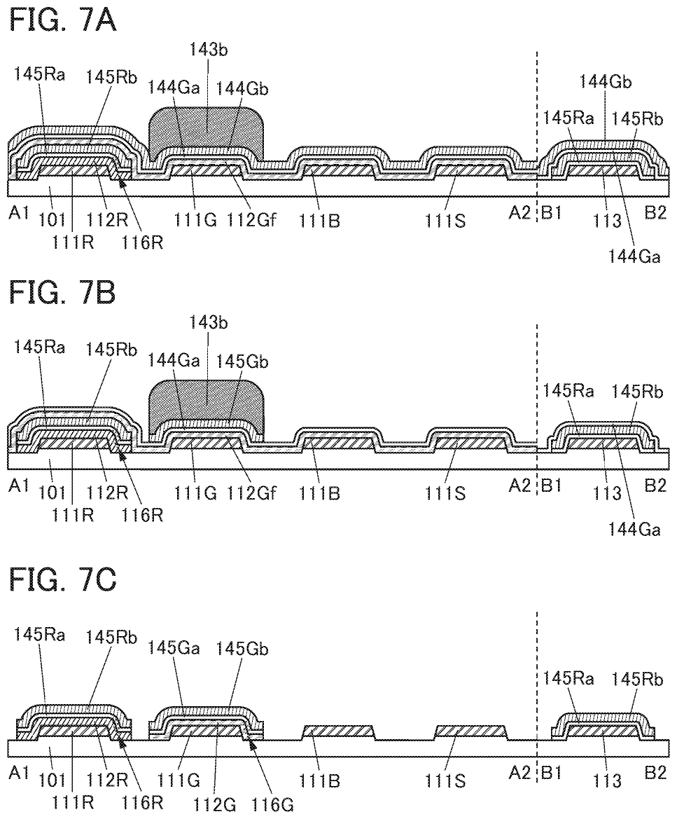

Next, as illustrated in FIG. 7A, an EL film 112Gf to be the EL layer 112G later is formed over the mask layer 145Rb, the pixel electrode 111G, the pixel electrode 111B, the pixel electrode 111S, and the layer 101 including transistors. Forming the EL film 112Gf after the formation of the mask layer 145Ra can inhibit the EL film 112Gf from being in contact with the EL layer 112R. For the formation of the EL film 112Gf, for example, the description of the formation of the EL film 112Rf can be referred to.

Subsequently, as illustrated in FIG. 7A, a mask film 144Ga is formed over the EL film 112Gf, the mask layer 145Rb, and the layer 101 including transistors, and a mask film 144Gb is formed over the mask film 144Ga. Then, as illustrated in FIG. 7A, a resist mask 143b is formed over the mask film 144Gb. The description of the formation and the like of the mask film 144Ra, the mask film 144Rb, and the resist mask 143a can be referred to for the formation and the like of the mask film 144Ga, the mask film 144Gb, and the resist mask 143b.

Then, as illustrated in FIG. 7B, part of the mask film 144Gb, which is not covered with the resist mask 143b, is removed by etching, whereby an island-shaped or band-shaped mask layer 145Gb is formed. The mask layer 145Gb can be formed over the pixel electrode 111G. For example, the description of the formation of the mask layer 145Rb can be referred to for the formation of the mask layer 145Gb.

Next, as illustrated in FIG. 7C, the resist mask 143b is removed. The mask film 144Ga and the EL film 112Gf are processed to form an island-shaped or band-shaped mask layer 145Ga and the island-shaped or band-shaped EL layer 112G. For example, the mask film 144Ga and the EL film 112Gf are processed using the mask layer 145Gb as a hard mask, whereby the mask layer 145Ga and the EL layer 112G can be formed over the pixel electrode 111G. The description of the removal of the resist mask 143a, the formation of the mask layer 145Ra, the formation of the EL layer 112R, and the like can be referred to for the removal of the resist mask 143b, the formation of the mask layer 145Ga, the formation of the EL layer 112G, and the like. Here, in the case where the end portion of the pixel electrode 111G has a tapered shape and the EL layer 112G covers the end portion of the pixel electrode 111G, the EL layer 112G can include the tapered portion 116G.

After the formation of the EL layer 112G, impurities attached to the surface of the EL layer 112G are preferably removed like impurities attached to the surface of the EL layer 112R. For example, impurities attached to the EL layer 112G can be removed when the substrate where the EL layer 112G is formed is put in an inert gas atmosphere after the formation of the EL layer 112G.

In the case of processing the EL film 112Gf, the mask layer 145Ga and the mask layer 145Gb are formed over the film positioned above the light-emitting film and then the light-emitting film is processed. Thus, the display apparatus 100 can be a highly reliable display apparatus.

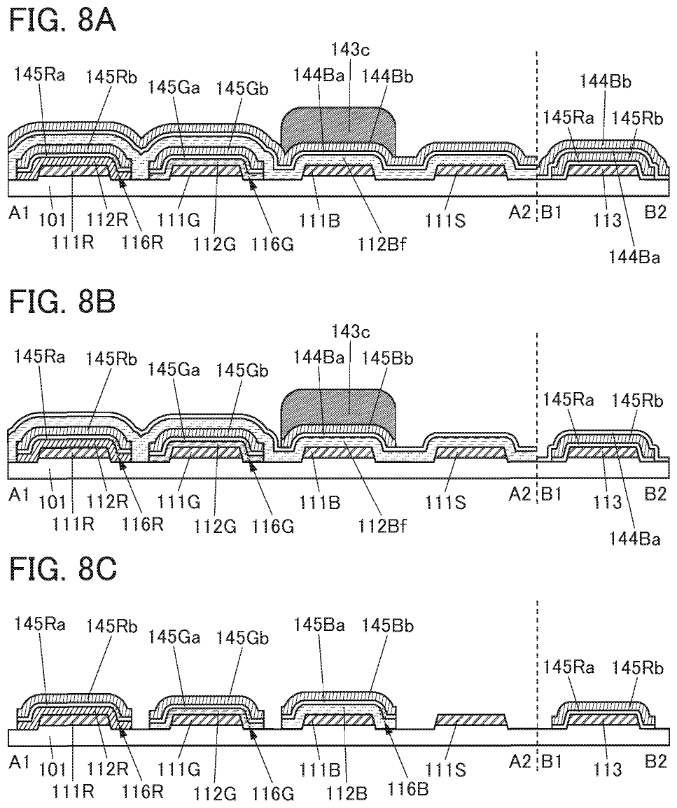

Next, as illustrated in FIG. 8A, an EL film 112Bf to be the EL layer 112B later is formed over the mask layer 145Rb, the mask layer 145Gb, the pixel electrode 111B, the pixel electrode 111S, and the layer 101 including transistors. Forming the EL film 112Bf after the formation of the mask layer 145Ra and the mask layer 145Ga can inhibit the EL film 112Bf from being in contact with the EL layer 112R and the EL layer 112G. For the formation of the EL film 112Bf, for example, the description of the formation of the EL film 112Rf can be referred to.

Subsequently, as illustrated in FIG. 8A, a mask film 144Ba is formed over the EL film 112Bf, the mask layer 145Rb, and the layer 101 including transistors, and a mask film 144Bb is formed over the mask film 144Ba. Then, as illustrated in FIG. 8A, a resist mask 143c is formed over the mask film 144Bb. The description of the formation and the like of the mask film 144Ra, the mask film 144Rb, and the resist mask 143a can be referred to for the formation and the like of the mask film 144Ba, the mask film 144Bb, and the resist mask 143c.

Then, as illustrated in FIG. 8B, part of the mask film 144Bb, which is not covered with the resist mask 143c, is removed by etching, whereby an island-shaped or band-shaped mask layer 145Bb is formed. The mask layer 145Bb can be formed over the pixel electrode 111B. For example, the description of the formation of the mask layer 145Rb can be referred to for the formation of the mask layer 145Bb.

Next, as illustrated in FIG. 8C, the resist mask 143c is removed. The mask film 144Ba and the EL film 112Bf are processed to form an island-shaped or band-shaped mask layer 145Ba and the island-shaped or band-shaped EL layer 112B. For example, the mask film 144Ba and the EL film 112Bf are processed using the mask layer 145Bb as a hard mask, whereby the mask layer 145Ba and the EL layer 112B can be formed over the pixel electrode 111B. The description of the removal of the resist mask 143a, the formation of the mask layer 145Ra, the formation of the EL layer 112R, and the like can be referred to for the removal of the resist mask 143c, the formation of the mask layer 145Ba, the formation of the EL layer 112B, and the like. Here, in the case where the end portion of the pixel electrode 111B has a tapered shape and the EL layer 112B covers the end portion of the pixel electrode 111B, the EL layer 112B can include the tapered portion 116B.

After the formation of the EL layer 112B, impurities attached to the surface of the EL layer 112B are preferably removed like impurities attached to the surface of the EL layer 112R. For example, impurities attached to the EL layer 112B can be removed when the substrate where the EL layer 112B is formed is put in an inert gas atmosphere after the formation of the EL layer 112B.

In the case of processing the EL film 112Bf, the mask layer 145Ba and the mask layer 145Bb are formed over the film positioned above the light-emitting film and then the light-emitting film is processed. Thus, the display apparatus 100 can be a highly reliable display apparatus.

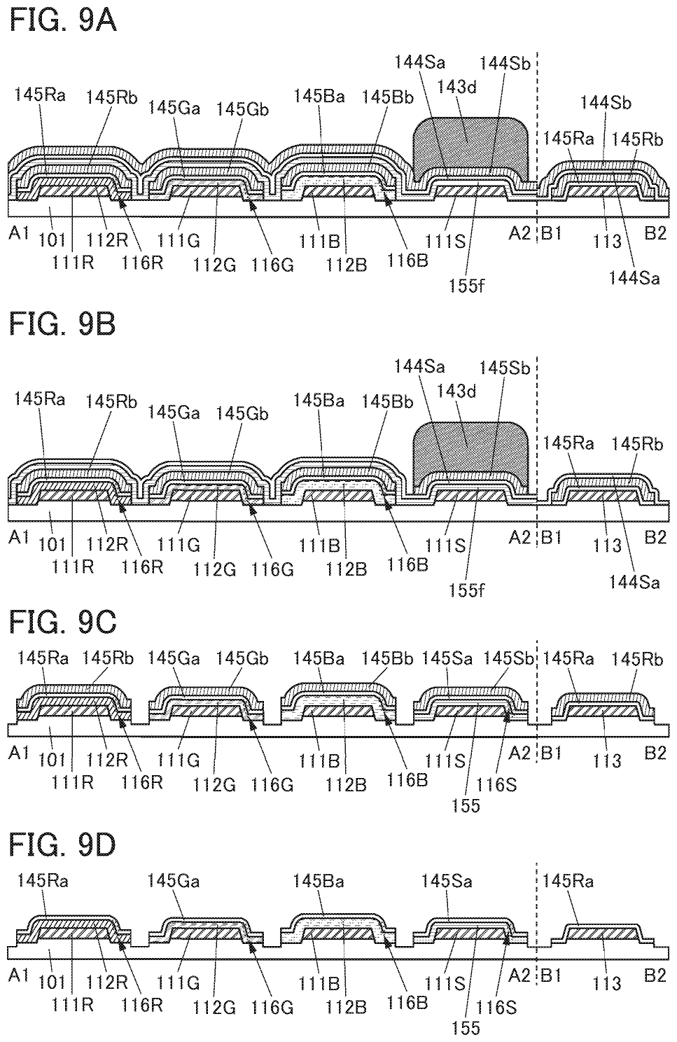

Next, as illustrated in FIG. 9A, a PD film 155f to be the PD layer 155 later is formed over the mask layer 145Rb, the mask layer 145Gb, the mask layer 145Bb, the pixel electrode 111S, and the layer 101 including transistors. Forming the PD film 155f after the formation of the mask layer 145Ra, the mask layer 145Ga, and the mask layer 145Ba can inhibit the PD film 155f from being in contact with the EL layer 112R, the EL layer 112G, and the EL layer 112B. For the formation of the PD film 155f, for example, the description of the formation of the EL film 112Rf can be referred to.

The PD film 155f includes at least a film containing a photoelectric conversion material having sensitivity with respect to visible light or infrared light (a photoelectric conversion film). The PD film 155f preferably includes a photoelectric conversion film and a film functioning as a carrier-transport layer over the photoelectric conversion film. Accordingly, the photoelectric conversion film is inhibited from being exposed on the outermost surface in the process of manufacturing the display apparatus 100, so that damage to the photoelectric conversion film can be reduced. This can increase the reliability of the display apparatus 100.

Moreover, the PD film 155f may have a structure in which one or more films functioning as a hole-transport layer, a hole-blocking layer, an electron-blocking layer, and an electron-transport layer are stacked. For example, the PD film 155f can have a structure in which a film functioning as a hole-transport layer, the photoelectric conversion film, and a film functioning as an electron-transport layer are stacked in this order. Alternatively, the PD film 155f can have a structure in which a film functioning as an electron-transport layer, the photoelectric conversion film, and a film functioning as a hole-transport layer are stacked in this order.

Subsequently, as illustrated in FIG. 9A, a mask film 144Sa is formed over the PD film 155f, the mask layer 145Rb, and the layer 101 including transistors, and a mask film 144Sb is formed over the mask film 144Sa. Then, as illustrated in FIG. 9A, a resist mask 143d is formed over the mask film 144Sb. The description of the formation and the like of the mask film 144Ra, the mask film 144Rb, and the resist mask 143a can be referred to for the formation and the like of the mask film 144Sa, the mask film 144Sb, and the resist mask 143d.

Then, as illustrated in FIG. 9B, part of the mask film 144Sb, which is not covered with the resist mask 143d, is removed by etching, whereby an island-shaped or band-shaped mask layer 145Sb is formed. The mask layer 145Sb can be formed over the pixel electrode 111S. For example, the description of the formation of the mask layer 145Rb can be referred to for the formation of the mask layer 145Sb.

Next, as illustrated in FIG. 9C, the resist mask 143d is removed. The mask film 144Sa and the PD film 155f are processed to form an island-shaped or band-shaped mask layer 145Sa and the island-shaped or band-shaped PD layer 155. For example, the mask film 144Sa and the PD film 155f are processed using the mask layer 145Sb as a hard mask, whereby the mask layer 145Sa and the PD layer 155 can be formed over the pixel electrode 111S. The description of the removal of the resist mask 143a, the formation of the mask layer 145Ra, the formation of the EL layer 112R, and the like can be referred to for the removal of the resist mask 143d, the formation of the mask layer 145Sa, the formation of the PD layer 155, and the like. Here, in the case where the end portion of the pixel electrode 111S has a tapered shape and the PD layer 155 covers the end portion of the pixel electrode 111S, the PD layer 155 can include the tapered portion 116S.

After the formation of the PD layer 155, impurities attached to the surface of the PD layer 155 are preferably removed like impurities attached to the surface of the EL layer 112R. For example, impurities attached to the PD layer 155 can be removed when the substrate where the PD layer 155 is formed is put in an inert gas atmosphere after the formation of the PD layer 155.

In the case of processing the PD film 155f, the mask layer 145Sa and the mask layer 145Sb are formed over the film positioned above the photoelectric conversion film and then the photoelectric conversion film is processed. Thus, the display apparatus 100 can be a highly reliable display apparatus.

As described above, through the steps illustrated in FIG. 6B to FIG. 9C, the EL layer 112R, the EL layer 112G, the EL layer 112B, and the PD layer 155 can be formed separately. Note that although the EL layer 112R, the EL layer 112G, the EL layer 112B, and the PD layer 155 are formed in this order in the above steps, the formation order of the EL layer 112R, the EL layer 112G, the EL layer 112B, and the PD layer 155 is not particularly limited. For example, the EL layer 112 may be formed after the formation of the PD layer 155.

Then, as illustrated in FIG. 9D, the mask layer 145Rb, the mask layer 145Gb, the mask layer 145Bb, and the mask layer 145Sb are removed by etching or the like. The mask layer 145Rb, the mask layer 145Gb, the mask layer 145Bb, and the mask layer 145Sb are preferably removed by a method having high selectivity over the mask layer 145Ra, the mask layer 145Ga, the mask layer 145Ba, and the mask layer 145Sa. For example, the mask layer 145Rb, the mask layer 145Gb, the mask layer 145Bb, and the mask layer 145Sb can be removed by a dry etching method. Note that the mask layer 145Rb, the mask layer 145Gb, the mask layer 145Bb, and the mask layer 145Sb may be removed not immediately after the formation of the EL layer 112R, the EL layer 112G, the EL layer 112B, or the PD layer 155 but in a later step.

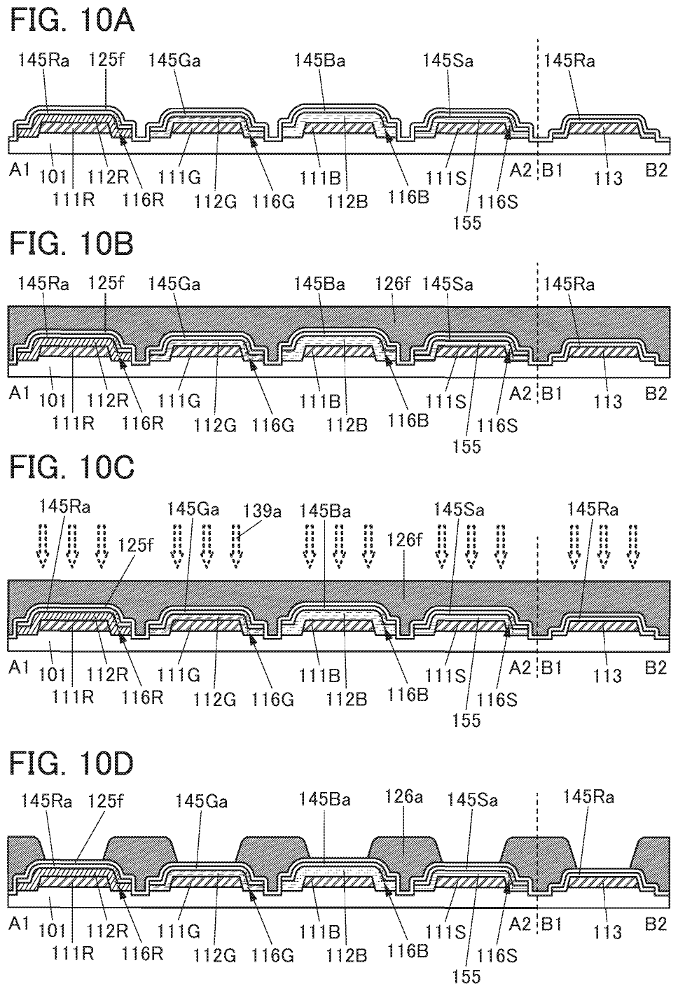

Next, as illustrated in FIG. 10A, an insulating film 125f to be the insulating layer 125 later is formed to cover the top surface of the layer 101 including transistors, the side surfaces of the EL layer 112 and the PD layer 155, and the side surface and the top surface of the mask layer 145a.

In this specification and the like, for example, a description common to the mask layer 145Ra, the mask layer 145Ga, the mask layer 145Ba, and the mask layer 145Sa is sometimes made using the term “mask layer 145a”. A description common to the mask layer 145a and the mask layer 145b is sometimes made using the term “mask layer 145”. Other components are sometimes described using reference numerals with the letters of the alphabet omitted, as mentioned above.

The insulating film 125f can be formed by an ALD method, an evaporation method, a sputtering method, a CVD method, a PLD method, or the like and is preferably formed by an ALD method achieving favorable coverage. For the insulating film 125f, an inorganic material can be used, for example, and an inorganic insulating film such as an oxide insulating film, a nitride insulating film, an oxynitride insulating film, or a nitride oxide insulating film can be used, for instance. In particular, using an inorganic insulating film such as an aluminum oxide film, a hafnium oxide film, or a silicon oxide film formed by an ALD method enables the insulating film 125f to have few pinholes.

Next, as illustrated in FIG. 10B, an insulating film 126f is formed over the insulating film 125f. Accordingly, the insulating film 126f is formed to cover the side surface of the EL layer 112 and the side surface of the PD layer 155, for example. The insulating film 126f is planarized in some cases. Alternatively, the insulating film 126f may have a slight unevenness reflecting unevenness of the formation surface.

The insulating film 126f contains a photosensitive material. The insulating film 126f contains a photosensitive organic material, for example, and contains a photosensitive resin such as an acrylic resin, for example. The insulating film 126f can be a photoresist, for example. The viscosity of the insulating film 126f is greater than or equal to 1 cP and less than or equal to 1500 cP, and is preferably greater than or equal to 1 cP and less than or equal to 12 cP. By setting the viscosity of the insulating film 126f in the above range, the insulating layer 127a and the insulating layer 127b each having a tapered shape as illustrated in FIG. 3(A) and FIG. 3B can be formed relatively easily.

For the insulating film 126f, a material that has a visible-light-blocking property before light exposure and has a visible-light-transmitting property after light exposure is used. That is, for the insulating film 126f, a material whose visible-light-transmitting property is increased by light exposure is used. Moreover, for the insulating film 126f, a positive material, i.e., a material that increases the solubility of a portion exposed to light in a developer is used.

The insulating film 126f can be formed by a wet deposition method such as spin coating, dipping, spray coating, ink-jetting, dispensing, screen printing, offset printing, doctor blade coating, slit coating, roll coating, curtain coating, or knife coating. Specifically, the insulating film 126f is preferably formed by spin coating.

After the application of the insulating film 126f, heat treatment is preferably performed. The heat treatment is performed at a temperature lower than the upper temperature limits of the EL layer 112 and the PD layer 155. The substrate temperature in the heat treatment is higher than or equal to 50° C. and lower than or equal to 200° C., preferably higher than or equal to 60° C. and lower than or equal to 150° C., further preferably higher than or equal to 70° C. and lower than or equal to 120° C. Accordingly, a solvent contained in the insulating film 126f can be removed.

Next, light exposure is performed on the insulating film 126f. Specifically, as illustrated in FIG. 10C, the insulating film 126f is irradiated with light 139a. For example, a region of the insulating film 126f overlapping with the pixel electrode 111 or the connection electrode 113 is irradiated with the light 139a, and a region between two adjacent EL layers 112, a region between the EL layer 112 and the PD layer 155 adjacent to each other, and the like are not irradiated with the light 139a. For example, the insulating film 126f can be irradiated with the light 139a using a first mask. The light 139a can be ultraviolet light or visible light, for example. The spectrum of the light 139a can have a peak in an ultraviolet light region or a visible light region, for example.

Next, development is performed on the insulating film 126f. Since the insulating film 126f contains a positive photosensitive material, the region exposed to light is removed by the development as illustrated in FIG. 10D. In this manner, an insulating layer 126a is formed. Specifically, the insulating layer 126a is formed between the two adjacent EL layers 112 and between the EL layer 112 and the PD layer 155 adjacent to each other, for example. In the case where an acrylic resin is used for the insulating film 126f, for example, an alkaline solution is preferably used as a developer, and for example, an aqueous solution of tetramethyl ammonium hydroxide (TMAH) is used.

FIG. 10D illustrates a plurality of cross sections of the insulating layer 126a; however, when a structure illustrated in FIG. 10D is seen from above, the insulating layer 126a can be one continuous layer in the structure. That is, the structure illustrated in FIG. 10D can be a structure including one insulating layer 126a. Here, in this specification and the like, one region of the insulating layer 126a may be referred to as a “first insulating layer” and another region may be referred to as a “second insulating layer”, for example. The insulating layer 126a provided between the EL layer 112 and the PD layer 155 adjacent to each other may be referred to as a first insulating layer and the insulating layer 126a provided between the two adjacent EL layers 112 may be referred to as a second insulating layer, for example. The same applies to components other than the insulating layer 126a.

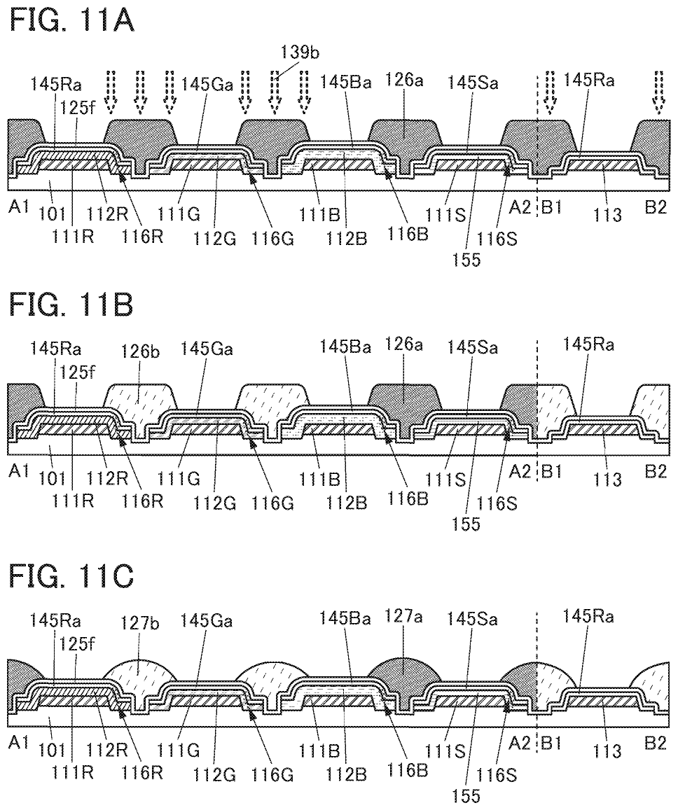

Next, light exposure is performed on the region of the insulating layer 126a between the two adjacent EL layers 112. Specifically, as illustrated in FIG. 11A, the region of the insulating layer 126a between the two adjacent EL layers 112 is irradiated with light 139b. For example, the insulating layer 126a can be irradiated with the light 139b using a second mask. The insulating layer 126a in the region irradiated with the light 139b has a high visible-light-transmitting property.

As illustrated in FIG. 11B, the insulating layer 126a having an improved visible-light-transmitting property is an insulating layer 126b. In other words, the insulating layer 126a is irradiated with the light 139b, whereby the insulating layer 126b is formed. Here, in the case of manufacturing the display apparatus 100 having a structure in which the insulating layer 127b is provided also between the light-emitting element 130 and the light-receiving element 150 adjacent to each other as illustrated in FIG. 2A2, part of the region between the EL layer 112 and the PD layer 155 adjacent to each other is also irradiated with the light 139b. Note that although the insulating layer 126a in the periphery of the connection electrode 113 is irradiated with the light 139b in FIG. 11B, the insulating layer 126a in the periphery of the connection electrode 113 is not necessarily irradiated with the light 139b. In this case, the insulating layer 126b is not formed at the insulating layer 126a in the periphery of the connection electrode 113 and the insulating layer 126a remains.

A structure is employed in which a transmittance of light having a specific wavelength that is at least part of a visible light wavelength in the insulating layer 126b is higher than the transmittance of the light having the specific wavelength in the insulating layer 126a. Moreover, a structure can be employed in which a transmittance of light of at least one color among red, green, and blue in the insulating layer 126b is higher than the transmittance in the insulating layer 126a.

The energy density of the light 139b is greater than 0 mJ/cm² and less than or equal to 800 mJ/cm², preferably greater than 0 mJ/cm² and less than or equal to 500 mJ/cm². In that case, the visible-light-transmitting property of the insulating layer 126a can be effectively improved.

The light 139b is preferably ultraviolet light or visible light. The light 139b is preferably light having the same wavelength as the light 139a. For example, the light 139b preferably includes light having the same wavelength as the light 139a. For example, the spectrum of the light 139a and the spectrum of the light 139b each preferably have a peak in an ultraviolet light region. Alternatively, the spectrum of the light 139a and the spectrum of the light 139b each preferably have a peak in a visible light region. Accordingly, a light exposure apparatus used for irradiation of the light 139a can be the same light exposure apparatus as an apparatus used for irradiation of the light 139b. By setting the wavelength of light for light exposure in the formation of the resist mask 143 to be equal to the wavelengths of the light 139a and the light 139b, all of the EL layer 112, the PD layer 155, the insulating layer 126a, and the insulating layer 126b can be formed using the same light exposure apparatus. Accordingly, the manufacturing cost of the display apparatus 100 can be reduced, whereby the display apparatus 100 can be an inexpensive display apparatus.

Here, for the insulating film 126f, a photocurable material is preferably used. In this case, the insulating layer 126b can be made harder than that in the case of using a material that is plasticized by light exposure for the insulating film 126f, which can suppress an unintentional change in the shape of the insulating layer 126b in a later step. Accordingly, for the insulating film 126f, a positive photosensitive material having photocurability can be used. That is, the insulating film 126f can have a property in which solubility in a developer is increased by light exposure but the shape is hardly changed without immersion in a developer.

For the resist mask 143, a material similar to that for the insulating layer 126a is preferably used. Thus, the formation of the resist mask 143 and the formation of the insulating layer 126a can be performed with the same apparatus. Specifically, application of a material to be the resist mask 143 and the formation of the insulating film 126f can be performed with the same deposition apparatus. Accordingly, the manufacturing cost of the display apparatus 100 can be reduced, whereby the display apparatus 100 can be an inexpensive display apparatus.

Subsequently, heat treatment is performed. Accordingly, as illustrated in FIG. 11C, the insulating layer 126a can be transformed into the insulating layer 127a whose side surface has a tapered shape and the insulating layer 126b can be transformed into the insulating layer 127b whose side surface has a tapered shape. The heat treatment is performed at a temperature lower than the upper temperature limits of the EL layer 112 and the PD layer 155. The substrate temperature in the heat treatment is higher than or equal to 50° C. and lower than or equal to 200° C., preferably higher than or equal to 60° C. and lower than or equal to 150° C., further preferably higher than or equal to 70° C. and lower than or equal to 130° C. The substrate temperature in the heat treatment of this step is preferably higher than that in the heat treatment after the formation of the insulating film 126f. Accordingly, adhesion between the insulating film 125f and each of the insulating layer 127a and the insulating layer 127b can be improved and corrosion resistance of the insulating layer 127a and the insulating layer 127b can be increased.

As illustrated in FIG. 3B and the like, the side surface of each of the insulating layer 127a and the insulating layer 127b preferably has a tapered shape with the taper angle θ1 in the cross-sectional view. The top surface of each of the insulating layer 127a and the insulating layer 127b preferably has a convex shape in the cross-sectional view.

Here, the insulating layer 127a and the insulating layer 127b are preferably reduced in size so that end portions overlap with the pixel electrodes 111. Such a structure allows the end portions of the insulating layer 127a and the insulating layer 127b to be formed over substantially flat regions of the EL layer 112 and the PD layer 155. This makes it relatively easy to process the insulating layer 127a and the insulating layer 127b into tapered shapes.

After the insulating layer 127a and the insulating layer 127b are processed into tapered shapes, additional heat treatment is preferably performed. By the heat treatment, water included in the EL layer 112 or the PD layer 155 and water adsorbed on the surface of the EL layer 112 or the surface of the PD layer 155, for example, can be removed. For example, heat treatment can be performed in an inert gas atmosphere or a reduced-pressure atmosphere. The heat treatment can be performed at a substrate temperature higher than or equal to 80° C. and lower than or equal to 230° C., preferably higher than or equal to 80° C. and lower than or equal to 200° C., further preferably higher than or equal to 80° C. and lower than or equal to 100° C. Employing a reduced-pressure atmosphere is preferable, in which case dehydration at a lower temperature is possible.

Etching may be performed so that the surface levels of the insulating layer 127a and the insulating layer 127b are adjusted. The insulating layer 127a and the insulating layer 127b may be processed by ashing using oxygen plasma, for example.

Accordingly, through the steps illustrated in FIG. 10B to FIG. 11C, the insulating layer 127a having a visible-light-blocking property and the insulating layer 127b having a visible-light-transmitting property can be separately formed. A photosensitive material is used for the insulating film 126f as described above, whereby the insulating layer 127a and the insulating layer 127b can be formed only by light exposure, development, and heating steps. In other words, the insulating layer 127a and the insulating layer 127b can be formed without employing, for example, a dry etching method for the insulating film 126f. Thus, the manufacturing process of the display apparatus 100 can be simplified. In addition, damage to the EL layer 112 and the PD layer 155 due to etching of the insulating film 126f can be reduced.

Note that in the above steps, the insulating film 126f is irradiated with the light 139a to form the insulating layer 126a and the insulating layer 126a is irradiated with the light 139b to form the insulating layer 126b. After that, the insulating layer 127a and the insulating layer 127b are formed by the heat treatment. As described above, light exposure is performed twice after the insulating film 126f is formed, whereby the insulating layer 127a and the insulating layer 127b are formed.

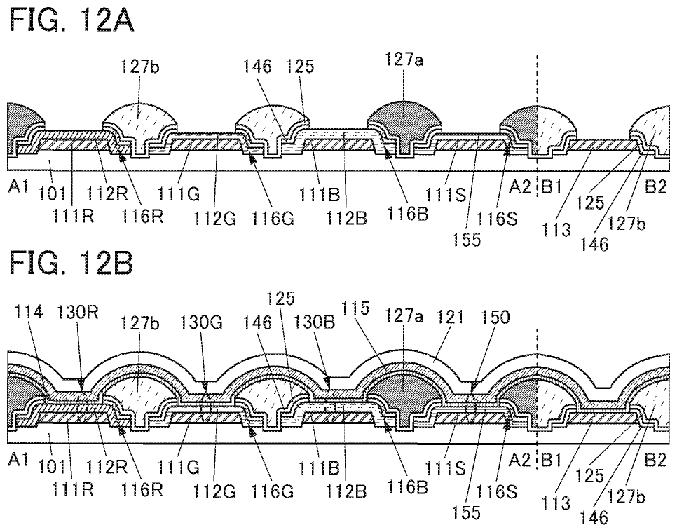

Next, as illustrated in FIG. 12A, the insulating film 125f is etched to form the insulating layer 125 and the mask layer 145a is etched to form the protective layer 146. Here, the mask layer 145a is etched to form the protective layer 146, so that the protective layer 146 can also be referred to as a mask layer.

The mask layer 145a and the insulating film 125f can be etched using the insulating layer 127a and the insulating layer 127b as masks. Thus, the insulating layer 125 and the protective layer 146 are formed to overlap with the insulating layer 127a, and the insulating layer 125 and the protective layer 146 are formed to overlap with the insulating layer 127b. Note that in the case where the step illustrated in FIG. 9D is not performed, i.e., the insulating film 125f is deposited without removing the mask layer 145b after the PD layer 155 is formed, the protective layer 146 is formed by etching the mask layer 145b and the mask layer 145a.

The etching of the mask layer 145a is preferably performed by a method that causes damage to the EL layer 112 and the PD layer 155 as little as possible. For example, the mask layer 145a can be etched by a wet etching method.

Anisotropic etching is preferably performed for the etching of the insulating film 125f, in which case the insulating layer 125 can be suitably formed without patterning using a photolithography method, for instance. Forming the insulating layer 125 without patterning using a photolithography method, for example, enables simplification of the manufacturing process of the display apparatus 100, resulting in lower manufacturing cost of the display apparatus 100. Thus, the display apparatus 100 can be an inexpensive display apparatus. For example, a dry etching method can be given as anisotropic etching. In the case where the insulating film 125f is etched by a dry etching method, for example, the insulating film 125f can be etched with use of an etching gas usable in etching of the mask film 144.

Next, vacuum baking treatment is performed to remove water and the like adsorbed on the surface of the EL layer 112 and the surface of the PD layer 155. The vacuum baking is preferably performed in a range of temperatures with which properties of the organic compounds contained in the EL layer 112, the PD layer 155, and the like are not changed and can be performed, for example, at higher than or equal to 70° C. and lower than or equal to 120° C., preferably higher than or equal to 80° C. and lower than or equal to 100° C. The vacuum baking treatment is not necessarily performed when water and the like adsorbed on the surface of the EL layer 112, the surface of the PD layer 155, and the like are small in amount and are less likely to adversely affect the reliability of the display apparatus 100, for example.

Next, as illustrated in FIG. 12B, the common layer 114 is formed over the EL layer 112, the PD layer 155, the insulating layer 127a, the insulating layer 127b, and the connection electrode 113. As described above, the common layer 114 includes at least one of a hole-injection layer, a hole-transport layer, a hole-blocking layer, an electron-blocking layer, an electron-transport layer, and an electron-injection layer and includes, for example, an electron-injection layer or a hole-injection layer. The common layer 114 can be formed by, for example, an evaporation method, a sputtering method, an inkjet method, or the like. Note that in the case where the common layer 114 is not provided over the connection electrode 113, a metal mask that shields the upper portion of the connection electrode 113 is used in the formation of the common layer 114. The metal mask used here does not need to shield a pixel region of the display portion; hence, a fine mask is not required and, for example, a rough metal mask can be used.

Next, as illustrated in FIG. 12B, the common electrode 115 is formed over the common layer 114. The common electrode 115 can be formed by a sputtering method or a vacuum evaporation method, for example. Accordingly, the light-emitting element 130R, the light-emitting element 130G, the light-emitting element 130B, and the light-receiving element 150 can be formed.

Next, as illustrated in FIG. 12B, the protective layer 121 is formed over the common electrode 115. When an inorganic insulating film is used as the protective layer 121, the protective layer 121 is preferably formed by a sputtering method, a CVD method, or an ALD method, for example. When an organic insulating film is used as the protective layer 121, the protective layer 121 is preferably formed by an inkjet method, for example, in which case a uniform film can be formed in a desired area.

Through the above steps, the display apparatus 100 can be manufactured.

In this specification and the like, a device manufactured using a metal mask or an FMM (a fine metal mask, a high-resolution metal mask) may be referred to as a device having an MM (a metal mask) structure. In this specification and the like, a device manufactured without using a metal mask or an FMM may be referred to as a device having an MML (metal maskless) structure.

In the method for manufacturing a display apparatus having an MML structure illustrated in FIG. 6A to FIG. 12B, an island-shaped EL layer 112 is formed not by using a fine metal mask but by processing an EL film 112f deposited over an entire surface. Similarly, the island-shaped PD layer 155 is formed not by using a fine metal mask but by processing the PD film 155f deposited over the entire surface.

According to the above, a display apparatus and an image capturing device having high resolution or a high aperture ratio can be achieved. In addition, a display apparatus having an image capturing function and high resolution or a high aperture ratio can be achieved. Moreover, the EL layers 112 can be formed separately for the respective colors, enabling the display apparatus to perform extremely clear display with high contrast and high display quality. Furthermore, providing the mask layers over the EL layer 112 and the PD layer 155 can reduce damage to the EL layer 112 and the PD layer 155 during the manufacturing process of the display apparatus 100, so that the reliability of the light-emitting element 130 and the light-receiving element 150 can be increased.

The display apparatus 100 can have a structure in which an insulator for covering the end portion of the pixel electrode 111 is not provided. In other words, an insulating layer is not provided between the pixel electrode 111 provided in the light-emitting element 130 and the EL layer 112, and between the pixel electrode 111 provided in the light-receiving element 150 and the PD layer 155. With this structure, light emitted from the EL layer 112 can be extracted efficiently, and light emitted to the PD layer 155 can be detected with high sensitivity.

In the display apparatus 100, light can be efficiently extracted from the EL layer 112, leading to extremely low viewing angle dependence. For example, in the display apparatus 100, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction. The display apparatus of one embodiment of the present invention can have improved viewing angle dependence and high image visibility.

In the case where the display apparatus 100 is a device having a fine metal mask (FMM) structure, the pixel arrangement structure is restricted in some cases, for example. Here, the FMM structure is described below.

In fabrication of the FMM structure, a metal mask (also referred to as an FMM) provided with an opening so that an EL material or a PD material is deposited to a desired region at the time of EL evaporation or PD evaporation is set to be opposed to a substrate. Then, the EL material or the PD material is deposited to the desired region by EL evaporation or PD evaporation through the FMM. As the area of a substrate subjected to EL evaporation or PD evaporation increases, the area of the FMM also increases and the weight of the FMM also increases accordingly. In addition, heat or the like is applied to the FMM at the time of EL evaporation and PD evaporation and may change the shape of the FMM. There is also a method in which EL evaporation or PD evaporation is performed while a certain level of tension is applied to the FMM, for example; therefore, the weight and strength of the FMM are important parameters.

Therefore, the pixel arrangement structure with an FMM needs to be designed under certain restrictions and, for example, the above-described parameters need to be considered. In contrast, the display apparatus of one embodiment of the present invention is fabricated using the MML structure, and thus offers an excellent effect such as higher flexibility in, for example, the pixel arrangement structure than the FMM structure. Note that this structure is highly compatible with a flexible device, for example, and thus one or both of a pixel and a driver circuit can have a variety of circuit arrangements.

Furthermore, in the method for manufacturing a display apparatus illustrated in FIG. 6A to FIG. 12B, the insulating film 126f containing a positive photosensitive material whose visible-light-transmitting property is increased by light exposure is formed and light exposure is performed twice, whereby the insulating layer 127a and the insulating layer 127b can be formed. As described above, since the insulating layer 127a has a high visible-light-blocking property, part of light emitted from the EL layer 112 adjacent to the PD layer 155 can be inhibited from entering the PD layer 155 due to stray light, for example. Since the insulating layer 127b has a high visible-light-transmitting property, light emitted from the EL layer 112 can be inhibited from being absorbed by the insulating layer 127b. Accordingly, the display apparatus 100 can be a display apparatus capable of image capturing with high sensitivity and have high light extraction efficiency.

### Manufacturing Method Example 2

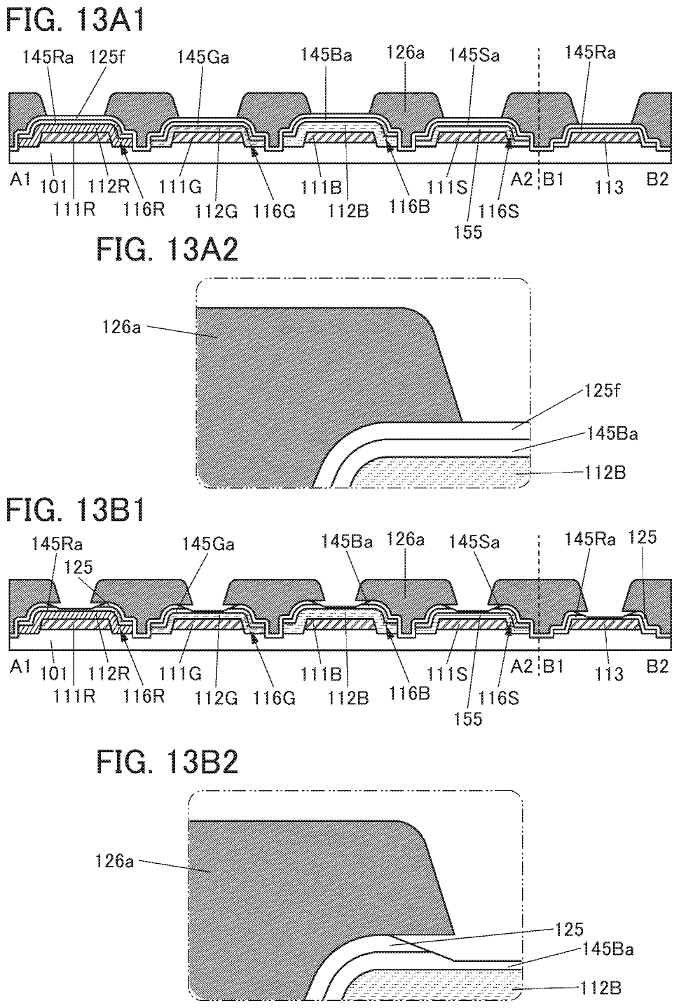

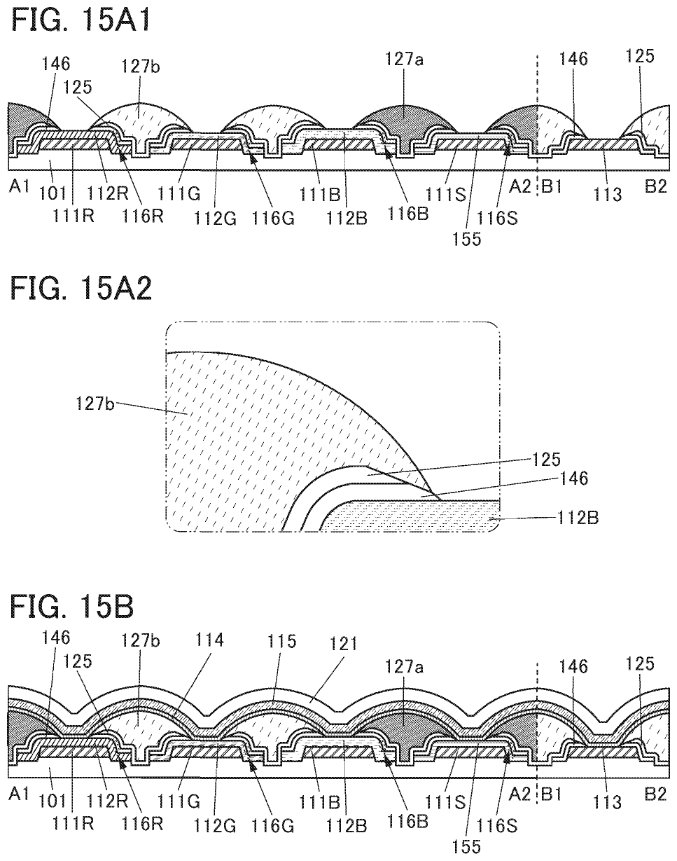

FIG. 13A1 to FIG. 15B are schematic cross-sectional views illustrating an example of a method for manufacturing the display apparatus 100 in which the light-emitting elements 130 and the light-receiving element 150 have the structure illustrated in FIG. 4A. FIG. 13A1 to FIG. 15B also illustrate a method for manufacturing the connection portion 140 taken along the dashed-dotted line B1-B2 in FIG. 1A.

First, steps similar to the steps illustrated in FIG. 6A to FIG. 10C are performed. Accordingly, the structure illustrated in FIG. 13A1 is fabricated. Here, FIG. 13A2 illustrates an enlarged view of the EL layer 112 and the insulating layer 126a that are illustrated in FIG. 13A1 and their vicinity.

Next, as illustrated in FIG. 13B1 and FIG. 13B2, etching treatment is performed with the insulating layer 126a as a mask to remove part of the insulating film 125f and reduce the thickness of part of the mask layer 145a. Thus, the insulating layer 125 is formed under the insulating layer 126a. In addition, the surface of the portion having a small thickness of the mask layer 145a is exposed. Note that FIG. 13B2 is an enlarged view of end portions of the EL layer 112B and the insulating layer 126a that are illustrated in FIG. 13B1 and their vicinity. The etching treatment using the insulating layer 126a as a mask may be hereinafter referred to as first etching treatment.

The first etching treatment can be performed by dry etching or wet etching. Note that the insulating film 125f is preferably deposited using a material similar to that for the mask layer 145a, in which case the first etching treatment can be performed collectively.

As illustrated in FIG. 13B2, etching is performed using the insulating layer 126a whose side surface has a tapered shape as a mask, so that the side surface of the insulating layer 125 and an upper end portion of the side surface of the mask layer 145a can be relatively easily processed into tapered shapes.

In the case of performing dry etching, a chlorine-based gas is preferably used. As the chlorine-based gas, Cl₂, BCl₃, SiCl₄, CCl₄, or the like can be used alone or two or more of the gases can be mixed and used. Moreover, an oxygen gas, a hydrogen gas, a helium gas, an argon gas, or the like or a mixture of two or more of the gases can be added to the chlorine-based gas as appropriate. By employing dry etching, a thin region of the mask layer 145a can be formed with a favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

In the case of performing dry etching, a by-product or the like generated by the dry etching might be deposited on the top surface and the side surface of the insulating layer 126a, for example. Thus, a component contained in the etching gas, a component contained in the insulating film 125f, a component contained in the mask layer 145a, or the like might be contained in the insulating layer 127a after the display apparatus is completed.

The first etching treatment is preferably performed by wet etching. Employing a wet etching method can reduce damage to the EL layer 112 and the PD layer 155 as compared with the case of employing a dry etching method. Wet etching can be performed using an alkaline solution, for example. For example, for wet etching of an aluminum oxide film, an aqueous solution of tetramethyl ammonium hydroxide (TMAH) that is an alkaline solution is preferably used. In that case, wet etching can be performed by a puddle method. Note that the insulating film 125f is preferably deposited using a material similar to that for the mask layer 145a, in which case the etching treatment can be performed collectively.

As illustrated in FIG. 13B1 and FIG. 13B2, the mask layer 145a is not completely removed in the first etching treatment, and the etching treatment is stopped in a state where the thickness is small. By making the mask layer 145a remain over the EL layer 112 and the PD layer 155 in such a manner, processing damage to the EL layer 112 and the PD layer 155 can be reduced in a later step.

Note that although the thickness of the mask layer 145a is reduced in the structure in FIG. 13B1 and FIG. 13B2, the present invention is not limited thereto. For example, depending on the thickness of the insulating film 125f and the thickness of the mask layer 145a, the first etching treatment might be stopped before the insulating film 125f is processed into the insulating layer 125. Specifically, the first etching treatment may be stopped only after reducing the thickness of part of the insulating film 125f. In the case where the insulating film 125f is deposited using a material similar to that for the mask layer 145a and accordingly a boundary between the insulating film 125f and the mask layer 145a is unclear, whether the insulating layer 125 is formed or whether the thickness of the mask layer 145a is reduced cannot be determined in some cases.

Although FIG. 13B1 and FIG. 13B2 illustrate an example in which the shape of the insulating layer 126a is not changed from that in FIG. 13A1 and FIG. 13A2, the present invention is not limited thereto. For example, the end portion of the insulating layer 126a may sag to cover the end portion of the insulating layer 125. In another case, the end portion of the insulating layer 126a is in contact with the top surface of the mask layer 145a, for example.

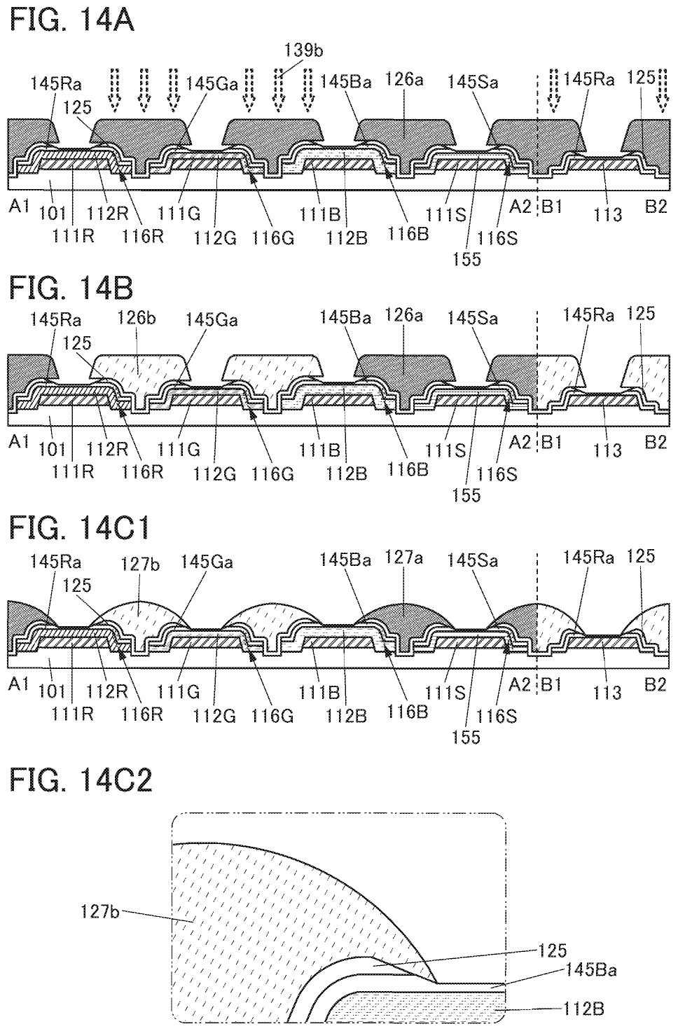

Next, in a step similar to that illustrated in FIG. 11A, light exposure is performed on the region of the insulating layer 126a between the two adjacent EL layers 112. Specifically, as illustrated in FIG. 14A, the region of the insulating layer 126a between the two adjacent EL layers 112 is irradiated with light 139b. As illustrated in FIG. 14B, the insulating layer 126a in the region irradiated with the light 139b becomes the insulating layer 126b having a high visible-light-transmitting property.

Then, as illustrated in FIG. 14C1 and FIG. 14C2, heat treatment (also referred to as post-baking) is performed. As illustrated in FIG. 14C1 and FIG. 14C2, performing the heat treatment can transform the insulating layer 126a and the insulating layer 126b respectively into the insulating layer 127a and the insulating layer 127b whose side surfaces have tapered shapes. Note that as described above, in some cases, the insulating layer 126a is already changed in shape and has a tapered shape in the side surface at the moment when the first etching treatment ends. In this case, the insulating layer 126b has a tapered shape in the side surface at the moment when the light exposure illustrated in FIG. 14(A) ends. The heat treatment is performed at a temperature lower than the upper temperature limits of the EL layer 112 and the PD layer 155. The heat treatment can be performed with a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Employing a reduced-pressure atmosphere is preferable, in which case drying at a lower temperature is possible. The substrate temperature in the heat treatment of this step is preferably higher than that in the heat treatment (also referred to as prebaking) after the formation of the insulating film 126f. Accordingly, adhesion between the insulating layer 125 and each of the insulating layer 127a and the insulating layer 127b can be improved and corrosion resistance of the insulating layer 127a and the insulating layer 127b can also be increased. Note that FIG. 14C2 is an enlarged view of the end portions of the EL layer 112B and the insulating layer 127b that are illustrated in FIG. 14C1 and their vicinity.

In the first etching treatment, the mask layer 145a is not completely removed and the mask layer 145a having a reduced thickness is made to remain, so that the EL layer 112 and the PD layer 155 can be prevented from being damaged by the heat treatment and deteriorating. Accordingly, a highly reliable display apparatus can be manufactured.

Next, as illustrated in FIG. 15A1 and FIG. 15A2, etching treatment is performed with the insulating layer 127a and the insulating layer 127b as masks to remove part of the mask layer 145a. Note that part of the insulating layer 125 is also removed in some cases. Accordingly, the top surfaces of the EL layer 112, the PD layer 155, and the connection electrode 113 are exposed, whereby the protective layer 146 is formed. Note that FIG. 15A2 is an enlarged view of the end portions of the EL layer 112B and the insulating layer 127b that are illustrated in FIG. 15A1 and their vicinity. The etching treatment using the insulating layer 127a and the insulating layer 127b as masks may be hereinafter referred to as second etching treatment.

The end portions of the insulating layer 125 are covered with the insulating layer 127a and the insulating layer 127b. FIG. 15A1 and FIG. 15A2 illustrate an example in which part of the end portion of the protective layer 146 (specifically, a portion having a tapered shape formed by the first etching treatment) is covered with the insulating layer 127a or the insulating layer 127b and a portion having a tapered shape formed by the second etching treatment is exposed. That is, this structure corresponds to the structure illustrated in FIG. 4A and FIG. 4B.

If the first etching treatment is not performed and the insulating layer 125 and the mask layer 145a are collectively etched after the post-baking, the insulating layer 125 and the mask layer 145a under the end portions of the insulating layer 127a and the insulating layer 127b may disappear because of side-etching and avoid may be formed. The void causes unevenness on the formation surface of the common layer 114 and the common electrode 115; hence, disconnection is more likely to be caused in the common layer 114 and the common electrode 115. Even when a void is formed because of side-etching of the inorganic insulating layer 125 and the mask layer 145a by the first etching treatment, the post-baking performed subsequently can make the insulating layer 127a and the insulating layer 127b fill the void. Since the subsequent second etching treatment is for etching the mask layer 145a having a smaller thickness, the amount of side-etching decreases, a void is less likely to be formed, and even if a void is formed, it can be extremely small. Therefore, the flatness of the formation surface of the common layer 114 and the common electrode 115 can be improved.

Note that as illustrated in FIG. 5A and FIG. 5B, the insulating layer 127a and the insulating layer 127b may cover the entire end portion of the protective layer 146. For example, the end portions of the insulating layer 127a and the insulating layer 127b sag and cover the end portion of the protective layer 146 in some cases. Alternatively, for example, the end portion of the insulating layer 127a or the insulating layer 127b is in contact with the top surface of at least one of the EL layer 112 and the PD layer 155 in some cases. In the case where a photocurable material is used for the insulating layer 126, the insulating layer 126a is more likely to be changed in shape than the insulating layer 126b in some cases. Thus, the end portion of the insulating layer 126a is more likely to sag than the insulating layer 126b in some cases.

The second etching treatment is preferably performed by wet etching. Employing a wet etching method can reduce damage to the EL layer 112 and the PD layer 155 as compared with the case of employing a dry etching method. Wet etching can be performed using an alkaline solution, for example.

As described above, providing the insulating layer 127a, the insulating layer 127b, the insulating layer 125, and the protective layer 146 can inhibit the common layer 114 and the common electrode 115 from having connection defects due to a disconnected portion and an increase in electric resistance due to a locally thinned portion. Accordingly, a highly reliable display apparatus can be manufactured.

After part of the EL layer 112 and part of the PD layer 155 are exposed, additional heat treatment may be performed. Accordingly, as described above, water and the like adsorbed on the surfaces of the EL layer 112 and the PD layer 155 can be removed.

Here, the shapes of the insulating layer 127a and the insulating layer 127b may be changed by the heat treatment. Specifically, the insulating layer 127a and the insulating layer 127b may be widened to cover at least one of the end portion of the insulating layer 125, the end portion of the protective layer 146, the end portion of the EL layer 112, and the top surface of the PD layer 155. For example, the insulating layer 127a and the insulating layer 127b may have the shapes illustrated in FIG. 5A and FIG. 5B.

The heat treatment can be performed in an inert gas atmosphere or a reduced-pressure atmosphere, for example. The heat treatment can be performed with a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case dehydration at a lower temperature is possible. Note that the temperature range of the heat treatment is preferably set as appropriate also in consideration of the upper temperature limits of the EL layer 112 and the PD layer 155. In consideration of the upper temperature limits of the EL layer 112 and the PD layer 155, a temperature higher than or equal to 70° C. and lower than or equal to 120° C. is particularly preferable in the above temperature ranges.

Next, as illustrated in FIG. 15B, the common layer 114, the common electrode 115, and the protective layer 121 are formed in a step similar to that illustrated in FIG. 12B. Through the above steps, the display apparatus 100 can be manufactured.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 2

In this embodiment, display apparatuses of embodiments of the present invention are described.

### Structure Example 1

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

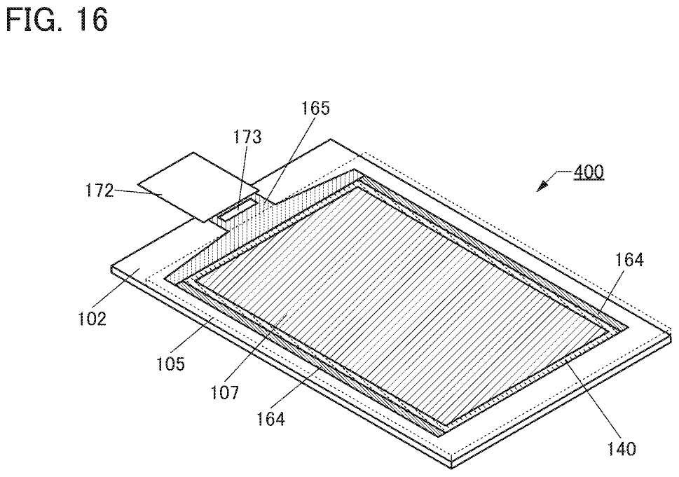

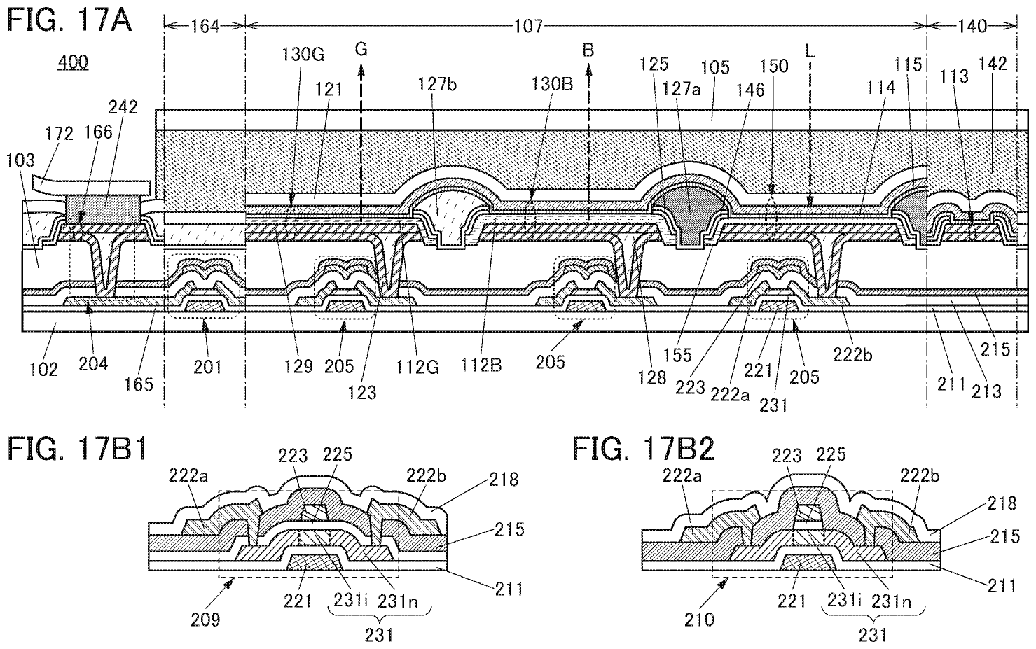

FIG. 16 illustrates a perspective view of a display apparatus 400, and FIG. 17A illustrates a cross-sectional view of the display apparatus 400.

In the display apparatus 400, a substrate 102 and a substrate 105 are bonded to each other. In FIG. 16, the substrate 105 is denoted by a dashed line.

The display apparatus 400 includes a display portion 107, the connection portion 140, a circuit 164, a wiring 165, and the like. FIG. 16 illustrates an example in which an IC 173 and an FPC 172 are mounted on the display apparatus 400. Thus, the structure illustrated in FIG. 16 can also be regarded as a display module including the display apparatus 400, the IC (integrated circuit), and the FPC. Here, a display apparatus in which a substrate is equipped with a connector such as an FPC or the substrate is mounted with an IC is referred to as a display module.

The connection portion 140 is provided outside the display portion 107. The connection portion 140 can be provided along one side or a plurality of sides of the display portion 107. The number of connection portions 140 can be one or more. FIG. 16 illustrates an example in which the connection portion 140 is provided to surround the four sides of the display portion 107. A common electrode of a light-emitting element is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 107 and the circuits 164. The signal and power are input to the wiring 165 from the outside through the FPC 172 or input to the wiring 165 from the IC 173.

FIG. 16 illustrates an example in which the IC 173 is provided over the substrate 102 by a COG method, a COF (Chip On Film) method, or the like. An IC including a scan line driver circuit, a signal line driver circuit, or the like can be used as the IC 173, for example. Note that the display apparatus 400 and the display module are not necessarily provided with an IC. The IC may be mounted on the FPC by a COF method, for example.

FIG. 17A illustrates an example of cross sections of part of a region including the FPC 172, part of the circuit 164, part of the display portion 107, part of the connection portion 140, and part of a region including an end portion of the display apparatus 400.

FIG. 17A illustrates a structure in which the insulating layer 127b is provided over the insulating layer 125 outside the display portion 107. Note that the insulating layer 127a may be provided in at least part of a region over the insulating layer 125 outside the display portion 107.

The display apparatus 400 illustrated in FIG. 17A includes a transistor 201, a transistor 205, the light-emitting elements 130, the light-receiving element 150, and the like between the substrate 102 and the substrate 105. FIG. 17A illustrates the light-emitting element 130G and the light-emitting element 130B as the light-emitting elements 130.

The light-emitting elements 130 and the light-receiving element 150 each have the same structure as the stacked-layer structure illustrated in FIG. 2A1 except the structure of the pixel electrode. Embodiment 1 can be referred to for the details of the light-emitting elements 130 and the light-receiving element 150.

The light-emitting element 130 and the light-receiving element 150 each include a conductive layer 123 and a conductive layer 129 over the conductive layer 123. Here, in the light-emitting element 130 and the light-receiving element 150, one or both of the conductive layer 123 and the conductive layer 129 can be referred to as a pixel electrode.

The conductive layer 123 is connected to a conductive layer 222b included in the transistor 205 through an opening provided in the insulating layer 103. Here, in the display apparatus 400, an end portion of the conductive layer 123 and an end portion of the conductive layer 129 are aligned or substantially aligned with each other; however, the present invention is not limited thereto. For example, the conductive layer 129 may be provided to cover the end portion of the conductive layer 123.

A depressed portion is formed in the conductive layer 123 to cover the opening provided in the insulating layer 103, an insulating layer 215, and an insulating layer 213. A layer 128 is embedded in the depressed portion.

The layer 128 has a planarization function for the depressed portion of the conductive layer 123. The conductive layer 129 electrically connected to the conductive layer 123 is provided over the conductive layer 123 and the layer 128. Thus, a region overlapping with the depressed portion of the conductive layer 123 can also be used as the light-emitting region, increasing the aperture ratio of the pixels. Note that in the case where the region overlapping with the depressed portion of the conductive layer 123 is sufficiently smaller than a light-emitting region of the conductive layer 123, for example, the conductive layer 129 is not necessarily provided.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surface of the conductive layer 123. When the layer 128 is formed using a negative photosensitive resin, the layer 128 can sometimes be formed using the same photomask (light-exposure mask) as the photomask used for forming the opening in the insulating layer 103, the insulating layer 215, and the insulating layer 213.

The top surface and the side surface of the conductive layer 129 are covered with the EL layer 112 or the PD layer 155. Note that the side surface of the conductive layer 129 is not necessarily covered with the EL layer 112 or the PD layer 155. Alternatively, part of the top surface of the conductive layer 129 is not necessarily covered with the EL layer 112 or the PD layer 155.

The protective layer 146 is provided to cover part of the end portion of the EL layer 112, and the protective layer 146 is provided to cover part of the end portion of the PD layer 155. The insulating layer 125 is provided to cover the top and side surfaces of the protective layer 146 and the side surface of the EL layer 112, and the insulating layer 125 is provided to cover the top and side surfaces of the protective layer 146 and the side surface of the PD layer 155. Furthermore, the insulating layer 127a is provided between the EL layer 112 and the PD layer 155 over the insulating layer 125, and the insulating layer 127b is provided between two adjacent EL layers 112 over the insulating layer 125. Specifically, for example, in the region over the insulating layer 125, the insulating layer 127a can be provided between the EL layer 112 and the PD layer 155 adjacent to each other, and the insulating layer 127b can be provided in other regions. The common layer 114 is provided over the EL layer 112, the PD layer 155, the insulating layer 127a, and the insulating layer 127b, and the common electrode 115 is provided over the common layer 114. The common layer 114 and the common electrode 115 are each one continuous film shared by the plurality of light-emitting elements 130 and the light-receiving element 150.

The protective layer 121 is provided over the light-emitting element 130 and the light-receiving element 150. Provision of the protective layer 121 covering the light-emitting element 130 and the light-receiving element 150 can inhibit impurities such as water from entering the light-emitting element 130 and the light-receiving element 150, and increase the reliability of the light-emitting element 130 and the light-receiving element 150.

The protective layer 121 and the substrate 105 are bonded to each other with an adhesive layer 142. A solid sealing structure, a hollow sealing structure, or the like can be employed to seal the light-emitting elements. In FIG. 17A, a solid sealing structure is employed in which a space between the substrate 102 and the substrate 105 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting element 130 and the light-receiving element 150. The space may be filled with a resin different from the frame-shaped adhesive layer 142.

The connection electrode 113 is provided over the insulating layer 103 in the connection portion 140. FIG. 17A illustrates an example in which the connection electrode 113 has a stacked-layer structure of a conductive film obtained by processing the same conductive film as the conductive layer 123 and a conductive film obtained by processing the same conductive film as the conductive layer 129. The side surface of the connection electrode 113 is covered with the protective layer 146. The insulating layer 125 is provided over the protective layer 146, and the insulating layer 127b is provided over the insulating layer 125. The common layer 114 is provided over the connection electrode 113, and the common electrode 115 is provided over the common layer 114. The connection electrode 113 and the common electrode 115 are electrically connected to each other through the common layer 114. Note that the common layer 114 is not necessarily formed in the connection portion 140. In this case, the connection electrode 113 and the common electrode 115 are in direct contact with each other to be electrically connected to each other.

The display apparatus 400 illustrated in FIG. 17A has a top emission structure. Light emitted from the light-emitting element 130 is emitted toward the substrate 105 side. Light enters the light-receiving element 150 through the substrate 105. For the substrate 105, a material having a high visible-light-transmitting property is preferably used. Note that the display apparatus 400 can have a bottom emission structure. In this case, a material having a high visible-light-transmitting property is preferably used for the substrate 102. The display apparatus 400 can have a dual emission structure. In this case, a material having a high visible-light-transmitting property is preferably used for both the substrate 102 and the substrate 105.

The transistor 201 and the transistor 205 are formed over the substrate 102. These transistors can be fabricated using the same material in the same step.

An insulating layer 211, the insulating layer 213, the insulating layer 215, and the insulating layer 103 are provided in this order over the substrate 102. Part of the insulating layer 211 functions as a gate insulating layer of each transistor. Part of the insulating layer 213 functions as a gate insulating layer of each transistor. The insulating layer 215 is provided to cover the transistors. The insulating layer 103 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 103 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 103 may have a stacked-layer structure of an organic insulating layer and an inorganic insulating film. The uppermost layer of the insulating layer 103 preferably has a function of an etching protective layer. Accordingly, a depressed portion can be prevented from being formed in the insulating layer 103 at the time of processing the conductive layer 123, the conductive layer 129, or the like. Alternatively, a depressed portion may be formed in the insulating layer 103 at the time of processing the conductive layer 123, the conductive layer 129, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. Atop-gate or a bottom-gate transistor structure may be employed. Alternatively, gates may be provided above and below the semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter, also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display apparatus can be simplified, and component cost and mounting cost can be reduced.

An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

The off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, a current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting elements even when the current-voltage characteristics of the light-emitting elements vary, for example. In other words, when the OS transistor operates in the saturation region, the source-drain current hardly changes with an increase in the source-drain voltage; hence, the emission luminance of the light-emitting element can be stable.

As described above, with the use of an OS transistor as a driving transistor included in the pixel circuit, it is possible to achieve “inhibition of black floating”, “increase in emission luminance”, “increase in the number of gray levels”, “inhibition of variation in characteristics of light-emitting elements”, and the like.

The metal oxide used for the semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used. Alternatively, an oxide containing indium (In), aluminum (Al), gallium (Ga), and zinc (Zn) (also referred to as IAGZO) is preferably used.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 107 may have the same structure or different structures. One structure or two or more types of structures may be employed for a plurality of transistors included in the circuit 164. Similarly, one structure or two or more types of structures may be employed for a plurality of transistors included in the display portion 107.

All of the transistors included in the display portion 107 may be OS transistors or all of the transistors included in the display portion 107 may be Si transistors; alternatively, some of the transistors included in the display portion 107 may be OS transistors and the others may be Si transistors.

For example, when both an LTPS transistor and an OS transistor are used in the display portion 107, the display apparatus can have low power consumption and high drive capability. A structure in which an LTPS transistor and an OS transistor are used in combination is referred to as LTPO in some cases. Note that as a further preferable example, a structure is given in which an OS transistor is used as a transistor functioning as a switch for controlling conduction and non-conduction between wirings and an LTPS transistor is used as a transistor for controlling current.

For example, one of the transistors included in the display portion 107 functions as a transistor for controlling a current flowing through the light-emitting element and can be referred to as a driving transistor. One of a source and a drain of the driving transistor is electrically connected to the pixel electrode of the light-emitting element. An LTPS transistor is preferably used as the driving transistor. Accordingly, the amount of current flowing through the light-emitting element can be increased in the pixel circuit.

Another transistor included in the display portion 107 functions as a switch for controlling selection and non-selection of the pixel and can also be referred to as a selection transistor. A gate of the selection transistor is electrically connected to a gate line, and one of a source and a drain thereof is electrically connected to a data line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting element having an MML (metal maskless) structure. With this structure, the leakage current that might flow through the transistor and the leakage current that might flow between adjacent light-emitting elements (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting elements are extremely low, display with little leakage of light at the time of black display can be achieved, for example.

FIG. 17B1 and FIG. 17B2 illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 17B1 illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 17B2, the insulating layer 225 overlaps with the channel formation region 231i of the semiconductor layer 231 and does not overlap with the low-resistance regions 231n. The structure illustrated in FIG. 17B2 can be formed by processing the insulating layer 225 with the conductive layer 223 as a mask, for example. In FIG. 17B2, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 102 where the substrate 105 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layer 123 and a conductive film obtained by processing the same conductive film as the conductive layer 129. The conductive layer 166 is exposed on the top surface of the connection portion 204. Thus, the connection portion 204 and the FPC 172 can be electrically connected to each other through the connection layer 242.

For the substrate 102 and the substrate 105, glass, quartz, ceramic, sapphire, resin, or the like can be used. When a flexible material is used for the substrate 102 and the substrate 105, the flexibility of the display apparatus 400 can be increased.

For the adhesive layer 142, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet may be used, for example.

As the connection layer 242, an anisotropic conductive film (ACF), an anisotropic conductive paste (ACP), or the like can be used.

As materials that can be used for conductive layers such as a variety of wirings and electrodes that constitute a display apparatus, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the thickness is preferably set small enough to be able to transmit light. A stacked film of any of the above materials can be used as a conductive layer. For example, a stacked film of indium tin oxide and an alloy of silver and magnesium is preferably used, in which case the conductivity can be increased. These materials can also be used for the conductive layers such as a variety of wirings and electrodes included in a display apparatus, and conductive layers (conductive layers functioning as a pixel electrode or a common electrode) included in the light-emitting element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

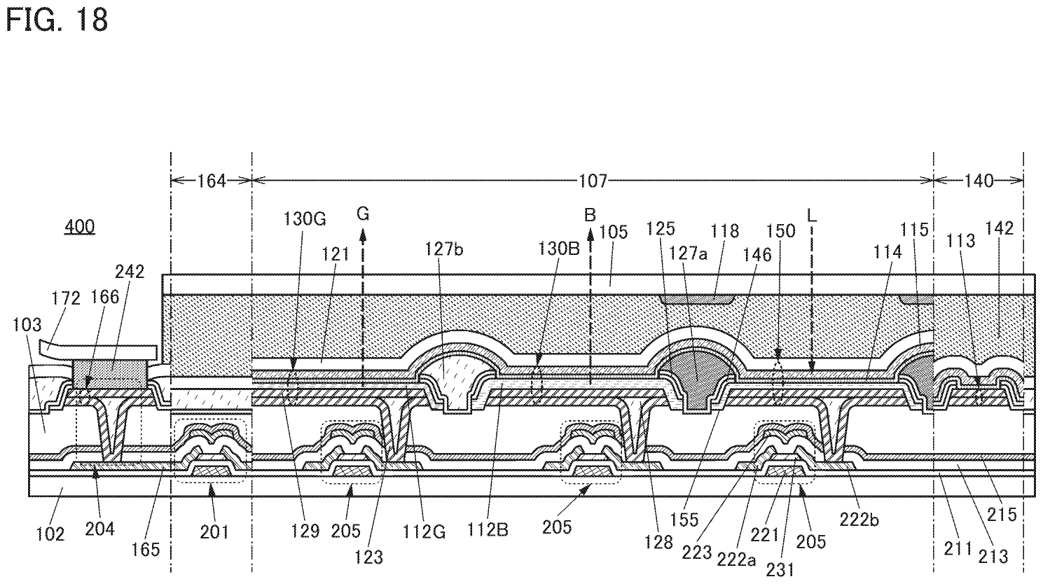

FIG. 18 illustrates a modification example of the structure illustrated in FIG. 17A, which is an example in which a light-blocking layer 118 is provided over the insulating layer 127a. FIG. 18 illustrates an example in which the light-blocking layer 118 is provided on the surface of the substrate 105 on the substrate 102 side.

By providing the light-blocking layer 118 over the insulating layer 127a, part of light emitted from the EL layer 112 adjacent to the PD layer 155 can be favorably inhibited from entering the PD layer 155 due to stray light, for example. Thus, the display apparatus 400 illustrated in FIG. 18 can be a display apparatus capable of image capturing with less noise and high image capturing sensitivity.

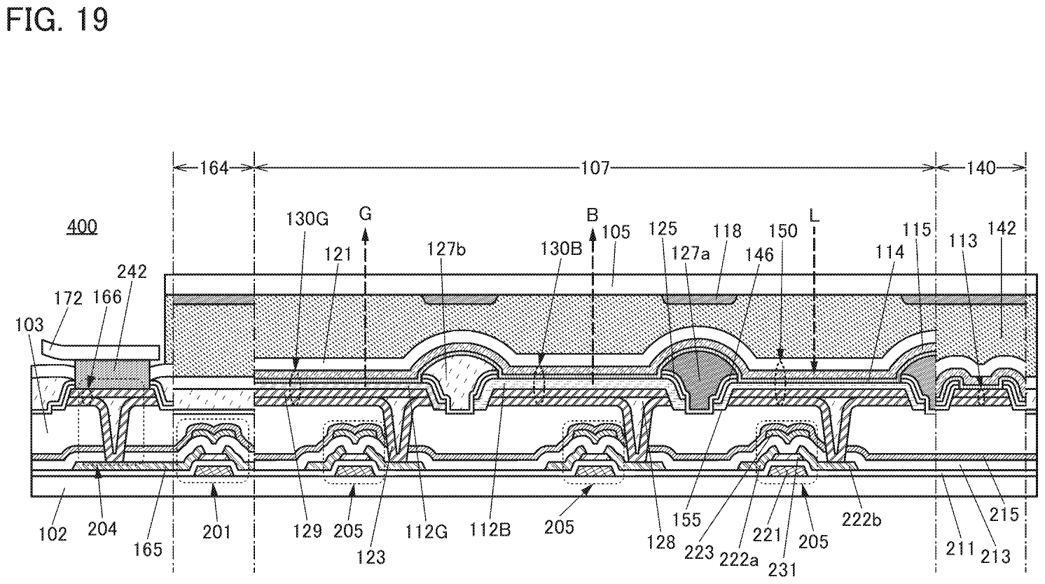

FIG. 19 is a modification example of the structure illustrated in FIG. 18 and is different from the structure illustrated in FIG. 18 in that the light-blocking layer 118 is provided not only over the insulating layer 127a but also over the insulating layer 127b, in a circuit 164, and in the connection portion 140. For example, by providing the light-blocking layer 118 over the insulating layer 127b, i.e., by providing the light-blocking layer 118 between two adjacent light-emitting elements 130, light emitted from the light-emitting element 130 can be inhibited from being reflected by the substrate 105 and scattered in the display apparatus 400. Thus, the display apparatus 400 can display a high-quality image.

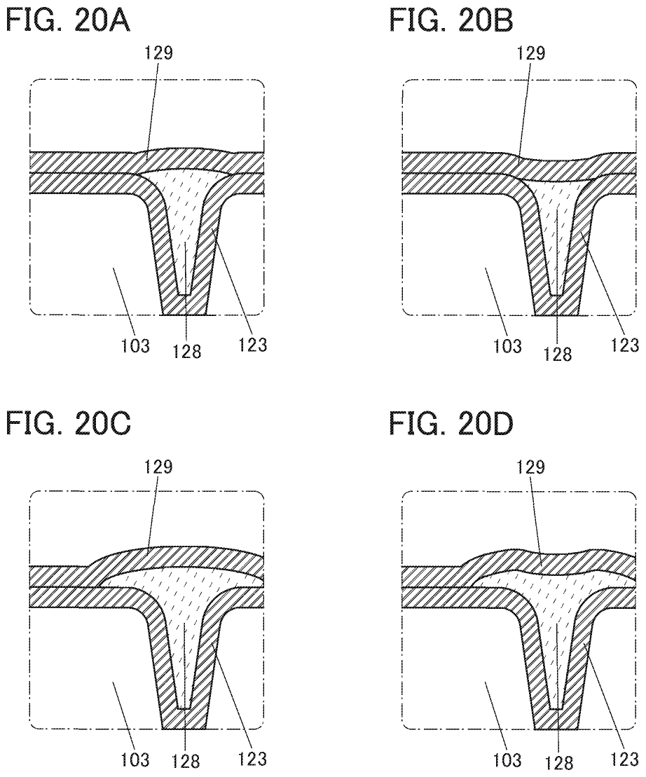

Here, FIG. 20A to FIG. 20D illustrate cross-sectional structures of a region including the conductive layer 123, the layer 128, and their vicinity in the display apparatus 400.

For example, FIG. 17A illustrates an example in which the top surface of the layer 128 and the top surface of the conductive layer 123 are substantially at the same level; however, the present invention is not limited thereto. For example, as illustrated in FIG. 20A, the top surface of the layer 128 may be at a higher level than the top surface of the conductive layer 123. In this case, the top surface of the layer 128 has a convex shape that is gently bulged toward the center.

As illustrated in FIG. 20B, the top surface of the layer 128 may be at a lower level than the top surface of the conductive layer 123. In this case, the top surface of the layer 128 has a concave shape that is gently recessed toward the center.

When the top surface of the layer 128 is at a higher level than the top surface of the conductive layer 123 as illustrated in FIG. 20C, the upper portion of the layer 128 may be formed to extend beyond a depressed portion formed in the conductive layer 123. In this case, part of the layer 128 may be formed to cover part of a region of the conductive layer 123 which is substantially flat.

As illustrated in FIG. 20D, part of the top surface of the layer 128 has another depressed portion in the structure illustrated in FIG. 20C, in some cases. The depressed portion has a shape that is gently recessed toward the center.

### Structure Example 2

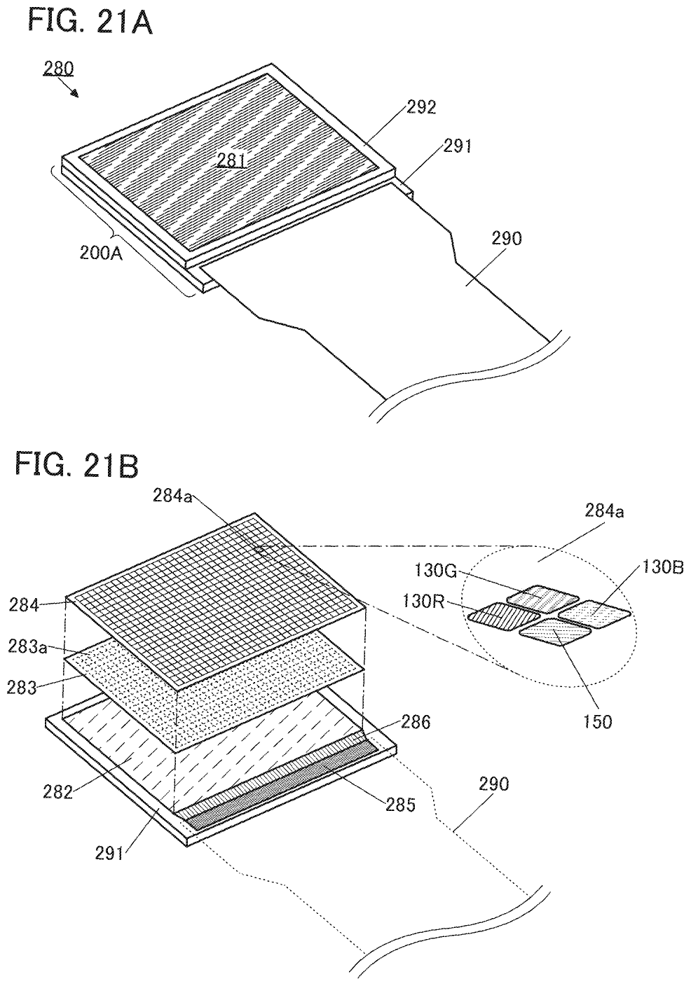

FIG. 21A is a perspective view of a display module 280. The display module 280 includes a display apparatus 200A and an FPC 290. Note that the display apparatus included in the display module 280 is not limited to the display apparatus 200A and may be any of a display apparatus 200B to a display apparatus 200F described later.

The display module 280 includes a substrate 291 and a substrate 292. The display module 280 includes a display portion 281. The display portion 281 is a region where an image is displayed.

FIG. 21B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. A terminal portion 285 to be connected to the FPC 290 is provided in a portion over the substrate 291 which does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 21B. The pixel 284a is provided with, for example, a subpixel including the light-emitting element 130R, a subpixel including the light-emitting element 130G, a subpixel including the light-emitting element 130B, and a subpixel including the light-receiving element 150.

The pixel circuit portion 283 includes a plurality of pixel circuits 283a arranged periodically. One pixel circuit 283a is a circuit that controls light emission of three light-emitting elements included in one pixel 284a. One pixel circuit 283a may be provided with three circuits each of which controls light emission of one light-emitting element. For example, the pixel circuit 283a can include at least one selection transistor, one current control transistor (driving transistor), and a capacitor for one light-emitting element. In this case, a gate signal is input to a gate of the selection transistor, and a video signal is input to one of a source and a drain of the selection transistor. With such a structure, an active-matrix display apparatus is achieved.

The circuit portion 282 includes a circuit for driving the pixel circuits 283a in the pixel circuit portion 283. For example, one or both of a gate line driver circuit and a data line driver circuit are preferably included. In addition, at least one of an arithmetic circuit, a memory circuit, a power supply circuit, and the like may be included. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution while the light-receiving element 150 is provided in the pixel 284a.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a watch.

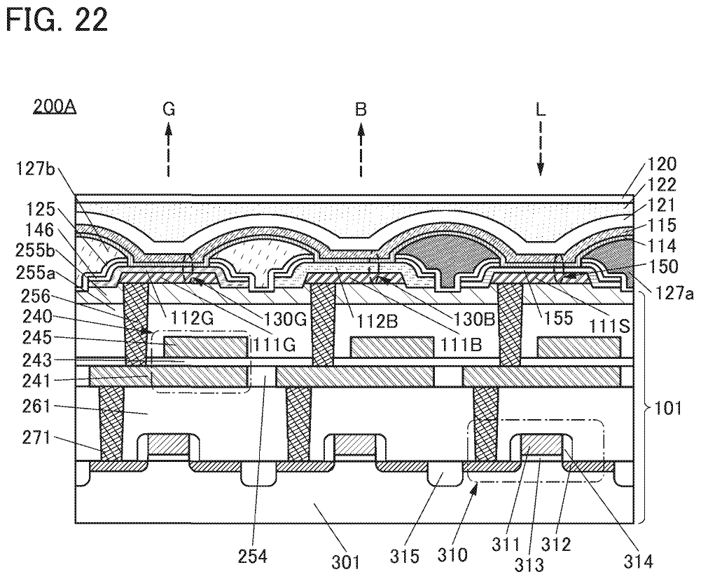

The display apparatus 200A illustrated in FIG. 22 includes a substrate 301, the light-emitting elements 130, the light-receiving element 150, a capacitor 240, and a transistor 310. FIG. 22 illustrates the light-emitting element 130G and the light-emitting element 130B as the light-emitting elements 130.

The light-emitting elements 130 and the light-receiving element 150 each have the stacked-layer structure illustrated in FIG. 2A1. Embodiment 1 can be referred to for the details of the light-emitting elements 130 and the light-receiving element 150.

The substrate 301 corresponds to the substrate 291 in FIG. 21A and FIG. 21B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, and an insulating layer 255b is provided over the insulating layer 255a. Here, a stacked-layer structure including the substrate 301 and the components thereover up to the insulating layer 255b corresponds to the layer 101 including transistors in Embodiment 1.

The light-emitting element 130 and the light-receiving device 150 are provided over the insulating layer 255b. Embodiment 1 can be referred to for the structures of the light-emitting element 130 and the light-receiving element 150.

In the display apparatus 200A, since the light-emitting elements 130 of different emission colors are separately formed, the difference between the chromaticity at low luminance emission and that at high luminance emission is small. Furthermore, since the EL layer 112R, the EL layer 112G, and the EL layer 112B are separated from each other, crosstalk generated between adjacent subpixels can be suppressed while the display apparatus has high resolution. Accordingly, the display apparatus having high resolution and high display quality can be achieved.

The protective layer 146, the insulating layer 125, and the insulating layer 127b are provided between two adjacent light-emitting elements 130. The protective layer 146, the insulating layer 125, and the insulating layer 127a are provided between the light-emitting element 130 and the light-receiving element 150 adjacent to each other.

The pixel electrodes 111 included in the light-emitting elements 130 and the light-receiving element 150 are each electrically connected to one of the source and the drain of the transistor 310 through a plug 256 embedded in the insulating layer 243, the insulating layer 255a, and the insulating layer 255b; the conductive layer 241 embedded in the insulating layer 254; and the plug 271 embedded in the insulating layer 261. The level of the top surface of the insulating layer 255b is equal to or substantially equal to the level of the top surface of the plug 256. A variety of conductive materials can be used for the plugs.

The protective layer 121 is provided over the light-emitting elements 130. A substrate 120 is bonded to the protective layer 121 with an adhesive layer 122.

An insulating layer (also referred to as a bank or a structure body) covering the end portion of the top surface of the pixel electrode 111 is not provided between two adjacent pixel electrodes 111. This allows the distance between adjacent light-emitting elements 130 to be extremely short. As a result, the display apparatus can have high resolution or high definition.

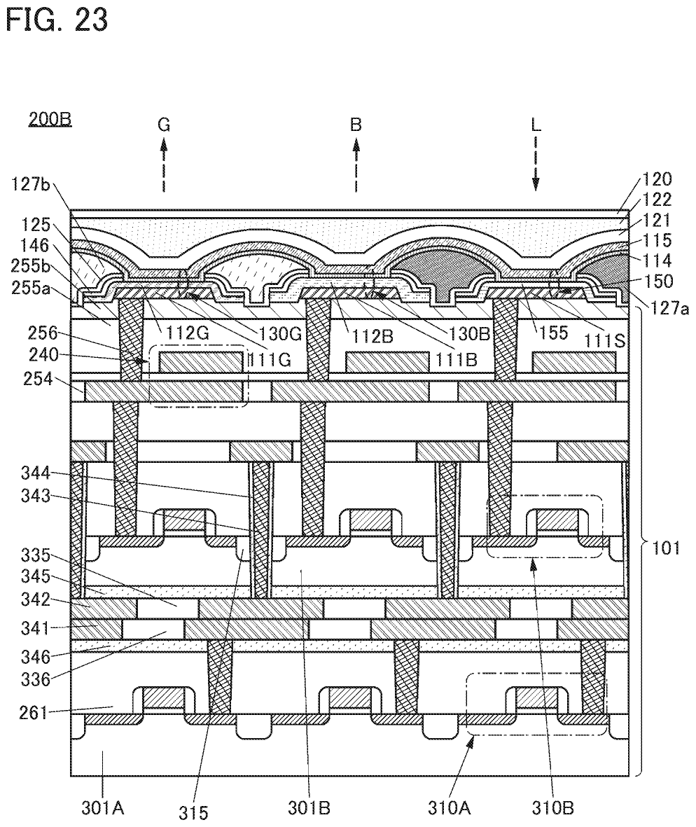

The display apparatus 200B illustrated in FIG. 23 has a structure in which a transistor 310A and a transistor 310B in each of which a channel is formed in a semiconductor substrate are stacked. Note that in the description of the display apparatus below, portions similar to those of the above-mentioned display apparatus are not described in some cases.

In the display apparatus 200B, a substrate 301B provided with the transistor 310B, the capacitor 240, and the light-emitting elements 130 is bonded to a substrate 301A provided with the transistor 310A. Here, a stacked-layer structure including the substrate 301A and the components thereover up to the insulating layer 255b corresponds to the layer 101 including transistors in Embodiment 1.

Here, an insulating layer 345 is provided on the bottom surface of the substrate 301B and an insulating layer 346 is provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 121 can be used.

The substrate 301B is provided with a plug 343 that penetrates the substrate 301B and the insulating layer 345. Here, an insulating layer 344 functioning as a protective layer is preferably provided to cover the side surface of the plug 343.

A conductive layer 342 is provided under the insulating layer 345 on the rear surface of the substrate 301B. The conductive layer 342 is embedded in an insulating layer 335 and the bottom surfaces of the conductive layer 342 and the insulating layer 335 are planarized. The conductive layer 342 is electrically connected to the plug 343.

Between the substrate 301A and the substrate 301B, a conductive layer 341 is provided over the insulating layer 346. The conductive layer 341 is embedded in an insulating layer 336 and the top surfaces of the conductive layer 341 and the insulating layer 336 are planarized.

For the conductive layer 341 and the conductive layer 342, the same conductive material is preferably used. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ Cu-to-Cu (copper-to-copper) direct bonding technique (a technique for achieving electrical continuity by connecting Cu (copper) pads).

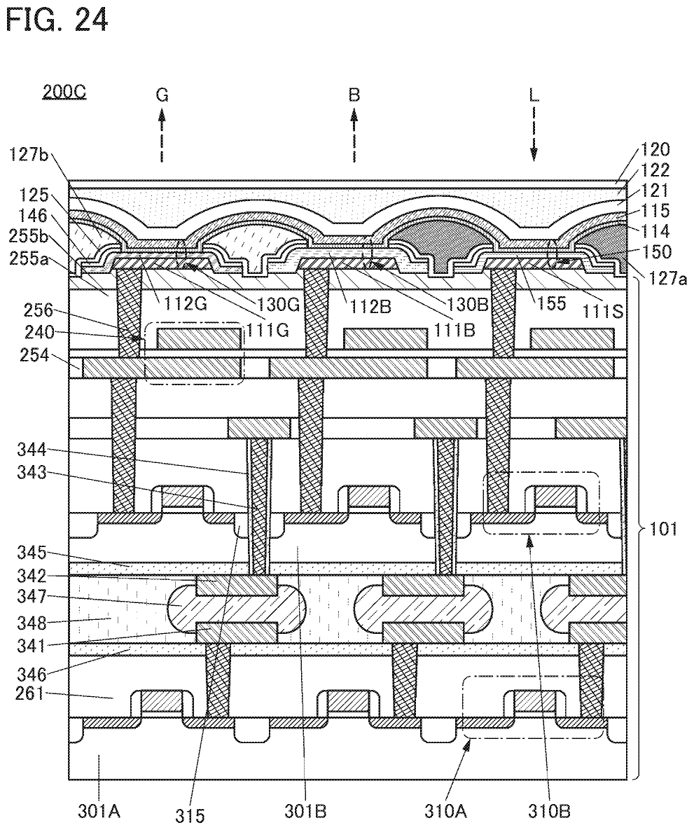

The display apparatus 200C illustrated in FIG. 24 has a structure in which the conductive layer 341 and the conductive layer 342 are bonded to each other through a bump 347.

As illustrated in FIG. 24, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

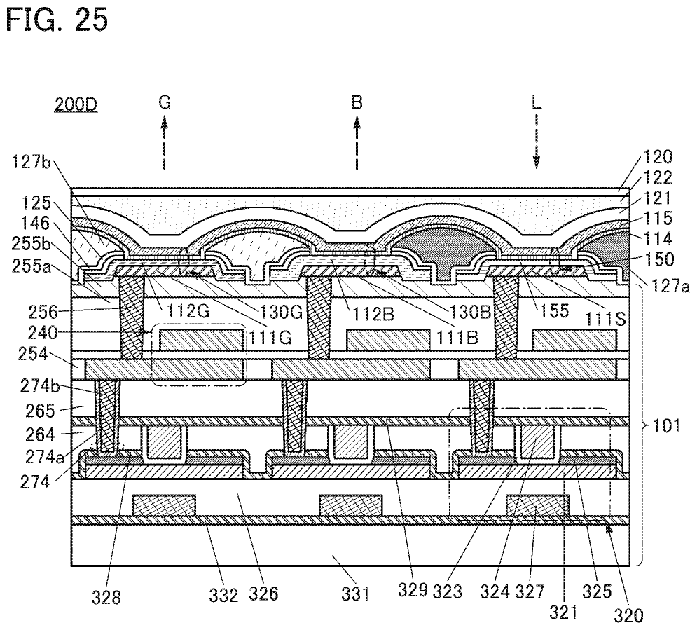

The display apparatus 200D illustrated in FIG. 25 is different from the display apparatus 200A mainly in a structure of a transistor.

A transistor 320 is a transistor that contains a metal oxide in a semiconductor layer where a channel is formed (an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 21A and FIG. 21B. Here, a stacked-layer structure including the substrate 331 and components thereover up to the insulating layer 255b corresponds to the layer 101 including transistors in Embodiment 1.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide film exhibiting semiconductor characteristics. The pair of conductive layers 325 are provided over and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from, for example, the insulating layer 264 into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323, which is in contact with the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment so that their levels are equal to or substantially equal to each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from, for example, the insulating layer 265 into the transistor 320. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material through which hydrogen and oxygen are less likely to diffuse is preferably used for the conductive layer 274a.

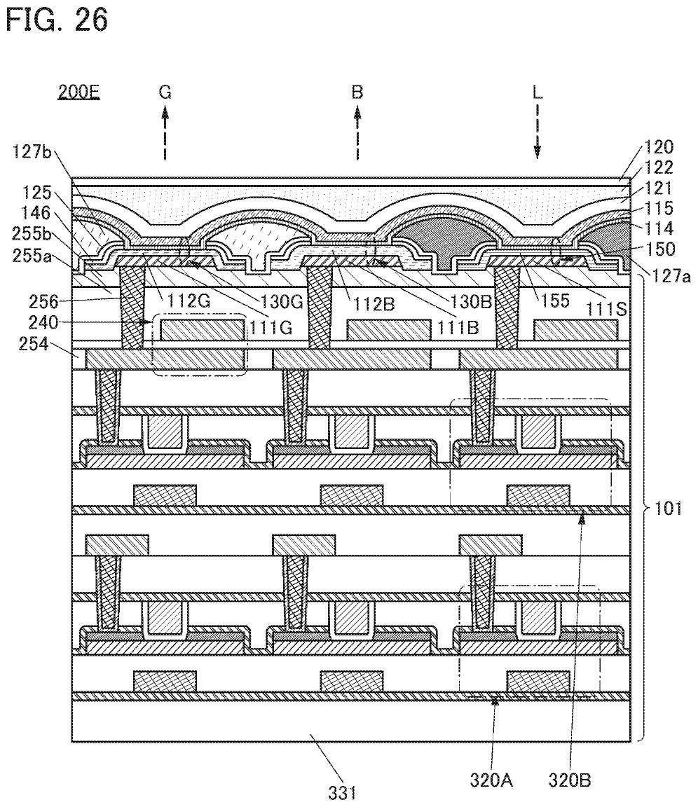

The display apparatus 200E illustrated in FIG. 26 has a structure in which a transistor 320A and a transistor 320B each including an oxide semiconductor in a semiconductor where a channel is formed are stacked.

The description of the display apparatus 200D can be referred to for the transistor 320A, the transistor 320B, and the components around them.

Although the structure in which two transistors including an oxide semiconductor are stacked is described, the present invention is not limited thereto. For example, three or more transistors may be stacked.

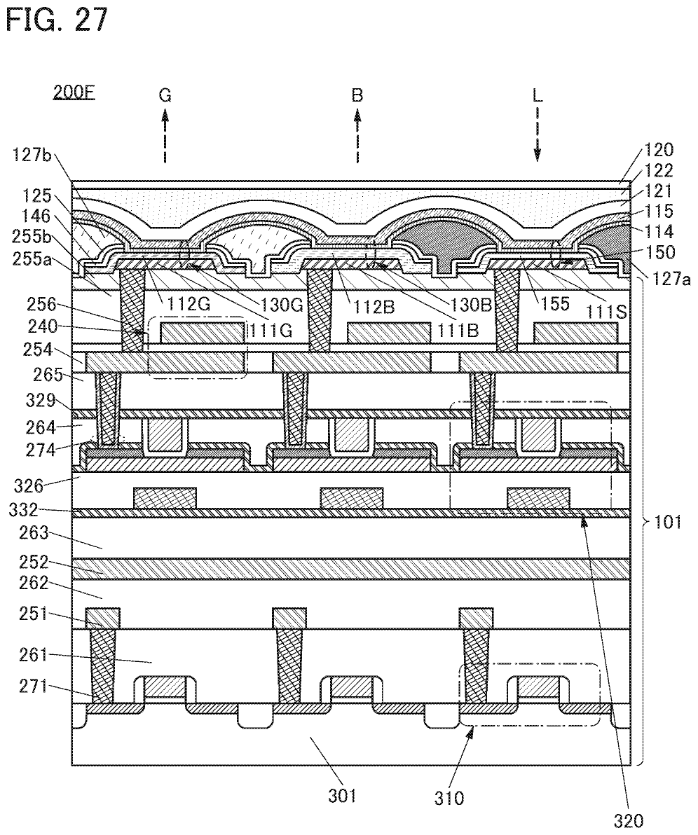

The display apparatus 200F illustrated in FIG. 27 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit. Alternatively, the transistor 310 can be used as a transistor included in a driver circuit (a gate line driver circuit or a data line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit, for example, can be formed directly under the light-emitting elements 130; thus, the display apparatus can be downsized as compared with the case where a driver circuit is provided around a display region.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 3

In this embodiment, a display apparatus of one embodiment of the present invention will be described.

The display apparatus of one embodiment of the present invention includes a light-receiving element (also referred to as a light-receiving device) and a light-emitting element (also referred to as a light-emitting device). Alternatively, the display apparatus of one embodiment of the present invention may include a light-emitting and light-receiving element (also referred to as a light-emitting and light-receiving device) and a light-emitting element.

First, a display apparatus including a light-receiving element and a light-emitting element is described.

The display apparatus of one embodiment of the present invention includes a light-receiving element and a light-emitting element in a light-emitting and light-receiving portion. In the display apparatus of one embodiment of the present invention, the light-emitting elements are arranged in a matrix in the light-emitting and light-receiving portion, and an image can be displayed on the light-emitting and light-receiving portion. Furthermore, the light-receiving elements are arranged in a matrix in the light-emitting and light-receiving portion, and the light-emitting and light-receiving portion has one or both of an image capturing function and a sensing function. The light-emitting and light-receiving portion can be used as an image sensor, a touch sensor, or the like. That is, by detecting light with the light-emitting and light-receiving portion, an image can be captured and touch operation of an object (e.g., a finger or a stylus) can be detected. Furthermore, in the display apparatus of one embodiment of the present invention, the light-emitting elements can be used as a light source of the sensor. Accordingly, a light-receiving portion and a light source do not need to be provided separately from the display apparatus; hence, the number of components of an electronic device can be reduced.

In the display apparatus of one embodiment of the present invention, when an object reflects (or scatters) light emitted from the light-emitting element included in the light-emitting and light-receiving portion, the light-receiving element can detect the reflected light (or the scattered light); thus, image capturing, touch operation detection, or the like is possible even in a dark place.

The light-emitting element included in the display apparatus of one embodiment of the present invention functions as a display element (also referred to as a display device).

As the light-emitting elements, EL elements (also referred to as EL devices) such as OLEDs or QLEDs are preferably used. As a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given. An LED such as a micro LED can also be used as the light-emitting element.

The display apparatus of one embodiment of the present invention has a function of detecting light with the use of a light-receiving element.

When the light-receiving elements are used as an image sensor, the display apparatus can capture an image using the light-receiving elements. For example, the display apparatus can be used as a scanner.

An electronic device including the display apparatus of one embodiment of the present invention can obtain data related to biological information such as a fingerprint or a palm print by using a function of an image sensor. That is, a biometric authentication sensor can be incorporated in the display apparatus. When the display apparatus incorporates a biometric authentication sensor, the number of components of an electronic device can be reduced as compared to the case where a biometric authentication sensor is provided separately from the display apparatus; thus, the size and weight of the electronic device can be reduced.

When the light-receiving elements are used as the touch sensor, the display apparatus can detect touch operation of an object with the use of the light-receiving elements.

As the light-receiving element, a pn photodiode or a pin photodiode can be used, for example. The light-receiving element functions as a photoelectric conversion element (also referred to as a photoelectric conversion device) that detects light incident on the light-receiving element and generates charge. The amount of charge generated from the light-receiving element depends on the amount of light incident on the light-receiving element.

It is particularly preferable to use an organic photodiode including a layer containing an organic compound as the light-receiving element. An organic photodiode, which is easily made thin, lightweight, and large in area and has a high degree of freedom for shape and design, can be used in a variety of devices.

In one embodiment of the present invention, organic EL elements are used as the light-emitting elements, and organic photodiodes are used as the light-receiving elements. The organic EL elements and the organic photodiodes can be formed over one substrate. Thus, the organic photodiodes can be incorporated in the display apparatus including the organic EL elements.

In the case where all the layers of the organic EL elements and the organic photodiodes are formed separately, the number of deposition steps becomes extremely large. However, a large number of layers of the organic photodiodes can have a structure in common with the organic EL elements; thus, concurrently depositing the layers that can have a common structure can inhibit an increase in the number of deposition steps.

For example, one of a pair of electrodes (a common electrode) can be a layer shared by the light-receiving element and the light-emitting element. For example, at least one of a hole-injection layer, a hole-transport layer, an electron-transport layer, and an electron-injection layer may be a layer shared by the light-receiving element and the light-emitting element. When the light-receiving element and the light-emitting element include a common layer in such a manner, the number of deposition steps and the number of masks can be reduced, thereby reducing the number of manufacturing steps and the manufacturing cost of the display apparatus. Furthermore, the display apparatus including the light-receiving element can be manufactured using an existing manufacturing apparatus and an existing manufacturing method for the display apparatus.

Next, a display apparatus including light-emitting and light-receiving elements and light-emitting elements is described. Note that functions, behavior, effects, and the like similar to those in the above are not described in some cases.

In the display apparatus of one embodiment of the present invention, a subpixel exhibiting any color includes a light-emitting and light-receiving element instead of a light-emitting element, and subpixels exhibiting the other colors each include a light-emitting element. The light-emitting and light-receiving element has both a function of emitting light (a light-emitting function) and a function of receiving light (a light-receiving function). For example, in the case where a pixel includes three subpixels of a red subpixel, a green subpixel, and a blue subpixel, at least one of the subpixels includes a light-emitting and light-receiving element, and the other subpixels each include a light-emitting element. Thus, the light-emitting and light-receiving portion of the display apparatus of one embodiment of the present invention has a function of displaying an image using both light-emitting and light-receiving elements and light-emitting elements.

The light-emitting and light-receiving element functions as both a light-emitting element and a light-receiving element, whereby the pixel can have a light-receiving function without an increase in the number of subpixels included in the pixel. Thus, the light-emitting and light-receiving portion of the display apparatus can be provided with one or both of an image capturing function and a sensing function while keeping the aperture ratio of the pixel (aperture ratio of each subpixel) and the resolution of the display apparatus. Accordingly, in the display apparatus of one embodiment of the present invention, the aperture ratio of the pixel can be more increased and the resolution can be increased more easily than in a display apparatus provided with a subpixel including a light-receiving element separately from a subpixel including a light-emitting element.

In the light-emitting and light-receiving portion of the display apparatus of one embodiment of the present invention, the light-emitting and light-receiving elements and the light-emitting elements are arranged in a matrix, and an image can be displayed on the light-emitting and light-receiving portion. The light-emitting and light-receiving portion can be used as an image sensor, a touch sensor, or the like. In the display apparatus of one embodiment of the present invention, the light-emitting elements can be used as a light source of the sensor. Thus, image capturing, touch operation detection, or the like is possible even in a dark place.

The light-emitting and light-receiving element can be manufactured by combining an organic EL element and an organic photodiode. For example, by adding an active layer of an organic photodiode to a stacked-layer structure of an organic EL element, the light-emitting and light-receiving element can be manufactured. Furthermore, in the light-emitting and light-receiving element manufactured by combining an organic EL element and an organic photodiode, concurrently depositing layers that can be shared by the organic EL element can inhibit an increase in the number of deposition steps.

For example, one of a pair of electrodes (a common electrode) can be a layer shared by the light-emitting and light-receiving element and the light-emitting element. For example, at least one of a hole-injection layer, a hole-transport layer, an electron-transport layer, and an electron-injection layer may be a layer shared by the light-emitting and light-receiving element and the light-emitting element.

Note that a layer included in the light-emitting and light-receiving element might have a different function between the case where the light-emitting and light-receiving element functions as a light-receiving element and the case where the light-emitting and light-receiving element functions as a light-emitting element. In this specification, the name of a component is based on its function in the case where the light-emitting and light-receiving element functions as a light-emitting element.

The display apparatus of this embodiment has a function of displaying an image with the use of the light-emitting elements and the light-emitting and light-receiving elements. That is, the light-emitting elements and the light-emitting and light-receiving elements function as display elements.

The display apparatus of this embodiment has a function of detecting light with the use of the light-emitting and light-receiving elements. The light-emitting and light-receiving element can detect light having a shorter wavelength than light emitted from the light-emitting and light-receiving element itself.

When the light-emitting and light-receiving elements are used as an image sensor, the display apparatus of this embodiment can capture an image using the light-emitting and light-receiving elements. When the light-emitting and light-receiving elements are used as a touch sensor, the display apparatus of this embodiment can detect touch operation of an object with the use of the light-emitting and light-receiving elements.

The light-emitting and light-receiving element functions as a photoelectric conversion element. The light-emitting and light-receiving element can be manufactured by adding an active layer of the light-receiving element to the above-described structure of the light-emitting element. For the light-emitting and light-receiving element, an active layer of a pn photodiode or a pin photodiode can be used, for example.

It is particularly preferable to use, for the light-emitting and light-receiving element, an active layer of an organic photodiode including a layer containing an organic compound. An organic photodiode, which is easily made thin, lightweight, and large in area and has a high degree of freedom for shape and design, can be used in a variety of devices.

The display apparatus that is an example of the display apparatus of one embodiment of the present invention is specifically described below with reference to drawings.

### Structure Example 1

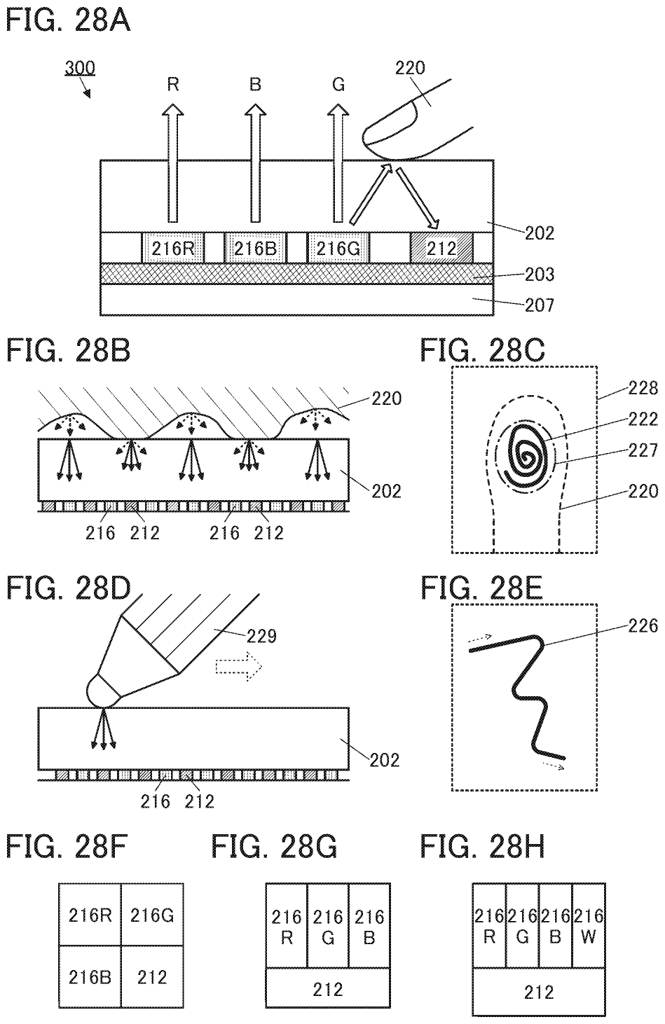

FIG. 28A is a schematic view of a display panel 300. The display panel 300 includes a substrate 207, a substrate 202, a light-receiving element 212, a light-emitting element 216R, a light-emitting element 216G, a light-emitting element 216B, a functional layer 203, and the like.

The light-emitting element 216R, the light-emitting element 216G, the light-emitting element 216B, and the light-receiving element 212 are provided between the substrate 207 and the substrate 202. The light-emitting element 216R, the light-emitting element 216G, and the light-emitting element 216B emit red (R) light, green (G) light, and blue (B) light, respectively. Note that in the following description, the term “light-emitting element 216” may be used when the light-emitting element 216R, the light-emitting element 216G, and the light-emitting element 216B are not distinguished from each other.

The display panel 300 includes a plurality of pixels arranged in a matrix. One pixel includes one or more subpixels. One subpixel includes one light-emitting element. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes the light-receiving element 212. The light-receiving element 212 may be provided in all the pixels or may be provided in some of the pixels. In addition, one pixel may include a plurality of light-receiving elements 212.

FIG. 28A illustrates a state where a finger 220 touches a surface of the substrate 202. Part of light emitted from the light-emitting element 216G is reflected at a contact portion of the substrate 202 and the finger 220. In the case where part of the reflected light is incident on the light-receiving element 212, the contact of the finger 220 with the substrate 202 can be detected. That is, the display panel 300 can function as a touch sensor.

The functional layer 203 includes a circuit for driving the light-emitting element 216R, the light-emitting element 216G, and the light-emitting element 216B and a circuit for driving the light-receiving element 212. The functional layer 203 is provided with a switch, a transistor, a capacitor, a wiring, and the like. Note that in the case where the light-emitting element 216R, the light-emitting element 216G, the light-emitting element 216B, and the light-receiving element 212 are driven by a passive-matrix method, a structure not provided with a switch, a transistor, or the like may be employed.

The display panel 300 preferably has a function of detecting a fingerprint of the finger 220. FIG. 28B schematically illustrates an enlarged view of the contact portion in a state where the finger 220 touches the substrate 202. FIG. 28B illustrates light-emitting elements 216 and the light-receiving elements 212 that are alternately arranged.

The fingerprint of the finger 220 is formed of depressed portions and projected portions. Therefore, as illustrated in FIG. 28B, the projected portions of the fingerprint touch the substrate 202.

Reflection of light from a surface, an interface, or the like is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 220. Meanwhile, regular reflection components are dominant in the light reflected from the interface between the substrate 202 and the air.

The intensity of light that is reflected from contact surfaces or non-contact surfaces between the finger 220 and the substrate 202 and is incident on the light-receiving elements 212 positioned directly below the contact surfaces or the non-contact surfaces is the sum of intensities of regularly reflected light and diffusely reflected light. As described above, regularly reflected light (indicated by solid arrows) is dominant near the depressed portions of the finger 220, where the finger 220 is not in contact with the substrate 202; whereas diffusely reflected light (indicated by dashed arrows) from the finger 220 is dominant near the projected portions of the finger 220, where the finger 220 is in contact with the substrate 202. Thus, the intensity of light received by the light-receiving element 212 positioned directly below the depressed portion is higher than that of light received by the light-receiving element 212 positioned directly below the projected portion. Accordingly, a fingerprint image of the finger 220 can be captured.

In the case where an arrangement interval between the light-receiving elements 212 is smaller than a distance between two projected portions of a fingerprint, preferably a distance between a depressed portion and a projected portion adjacent to each other, a clear fingerprint image can be obtained. The distance between a depressed portion and a projected portion of a human's fingerprint is approximately 200 μm; thus, the arrangement interval between the light-receiving elements 212 is, for example, less than or equal to 400 μm, preferably less than or equal to 200 μm, further preferably less than or equal to 150 μm, still further preferably less than or equal to 100 μm, even still further preferably less than or equal to 50 μm and greater than or equal to 1 μm, preferably greater than or equal to 10 μm, further preferably greater than or equal to 20 μm.

FIG. 28C illustrates an example of a fingerprint image captured by the display panel 300. In an image-capturing range 228 in FIG. 28C, the outline of the finger 220 is indicated by a dashed line and the outline of a contact portion 227 is indicated by a dashed-dotted line. In the contact portion 227, a high-contrast image of a fingerprint 222 can be captured owing to a difference in the amount of light incident on the light-receiving elements 212.

The display panel 300 can also function as a touch sensor or a pen tablet. FIG. 28D illustrates a state where a tip of a stylus 229 slides in a direction indicated with a dashed arrow while the tip of the stylus 229 touches the substrate 202.

As illustrated in FIG. 28D, when diffusely reflected light that is diffused at the contact surface of the tip of the stylus 229 and the substrate 202 is incident on the light-receiving element 212 positioned in a portion overlapping with the contact surface, the position of the tip of the stylus 229 can be detected with high accuracy.

FIG. 28E illustrates an example of a path 226 of the stylus 229 that is detected by the display panel 300. The display panel 300 can detect the position of a detection target, such as the stylus 229, with high position accuracy, so that high-definition drawing can be performed using, for example, a drawing application. Unlike the case of using a capacitive touch sensor, an electromagnetic induction touch pen, or the like, the display panel 300 can detect even the position of a highly insulating object to be detected, the material of a tip portion of the stylus 229 is not limited, and a variety of writing materials (e.g., a brush, a glass pen, and a quill pen) can be used.

Here, FIG. 28F to FIG. 28H illustrate examples of a pixel that can be used in the display panel 300.

The pixels illustrated in FIG. 28F and FIG. 28G each include the light-emitting element 216R for red (R), the light-emitting element 216G for green (G), the light-emitting element 216B for blue (B), and the light-receiving element 212. The pixels each include a pixel circuit for driving the light-emitting element 216R, the light-emitting element 216G, the light-emitting element 216B, and the light-receiving element 212.

FIG. 28F illustrates an example in which three light-emitting elements and one light-receiving element are provided in a matrix of 2×2. FIG. 28G illustrates an example in which three light-emitting elements are arranged in one line and one laterally long light-receiving element 212 is provided below the three light-emitting elements.

The pixel illustrated in FIG. 28H is an example including a light-emitting element 216W for white (W). Here, four light-emitting elements are arranged in one line and the light-receiving element 212 is provided below the four light-emitting elements.

Note that the pixel structure is not limited to the above structure, and a variety of arrangement methods can be employed.

### Structure Example 2

An example of a structure including light-emitting elements emitting visible light, a light-emitting element emitting infrared light, and a light-receiving element is described below.

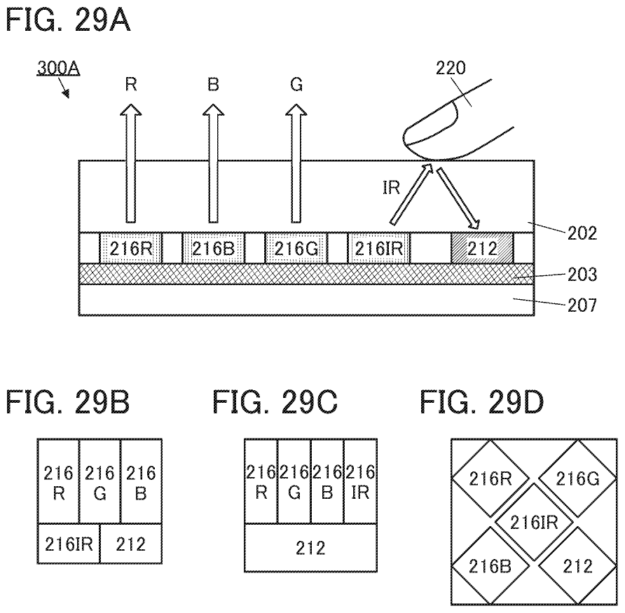

A display panel 300A illustrated in FIG. 29A includes a light-emitting element 216IR in addition to the components illustrated in FIG. 28A as an example. The light-emitting element 216IR is a light-emitting element emitting infrared light IR. Moreover, in that case, an element capable of receiving at least the infrared light IR emitted from the light-emitting element 216IR is preferably used as the light-receiving element 212. As the light-receiving element 212, an element capable of receiving visible light and infrared light is further preferably used.

As illustrated in FIG. 29A, when the finger 220 touches the substrate 202, the infrared light IR emitted from the light-emitting element 216IR is reflected by the finger 220 and part of reflected light is incident on the light-receiving element 212, so that the positional information of the finger 220 can be obtained.

FIG. 29B to FIG. 29D illustrate examples of a pixel that can be used in the display panel 300A.

FIG. 29B illustrates an example in which three light-emitting elements are arranged in one line and the light-emitting element 216IR and the light-receiving element 212 are arranged below the three light-emitting elements in a horizontal direction. FIG. 29C illustrates an example in which four light-emitting elements including the light-emitting element 216IR are arranged in one line and the light-receiving element 212 is provided below the four light-emitting elements.

FIG. 29D illustrates an example in which three light-emitting elements and the light-receiving element 212 are arranged in all directions with the light-emitting element 216IR as the center.

Note that in the pixels illustrated in FIG. 29B to FIG. 29D, the positions of the light-emitting elements can be interchangeable, or the positions of the light-emitting element and the light-receiving element can be interchangeable.

### Structure Example 3

An example of a structure including a light-emitting element emitting visible light and a light-emitting and light-receiving element emitting visible light and receiving visible light is described below.

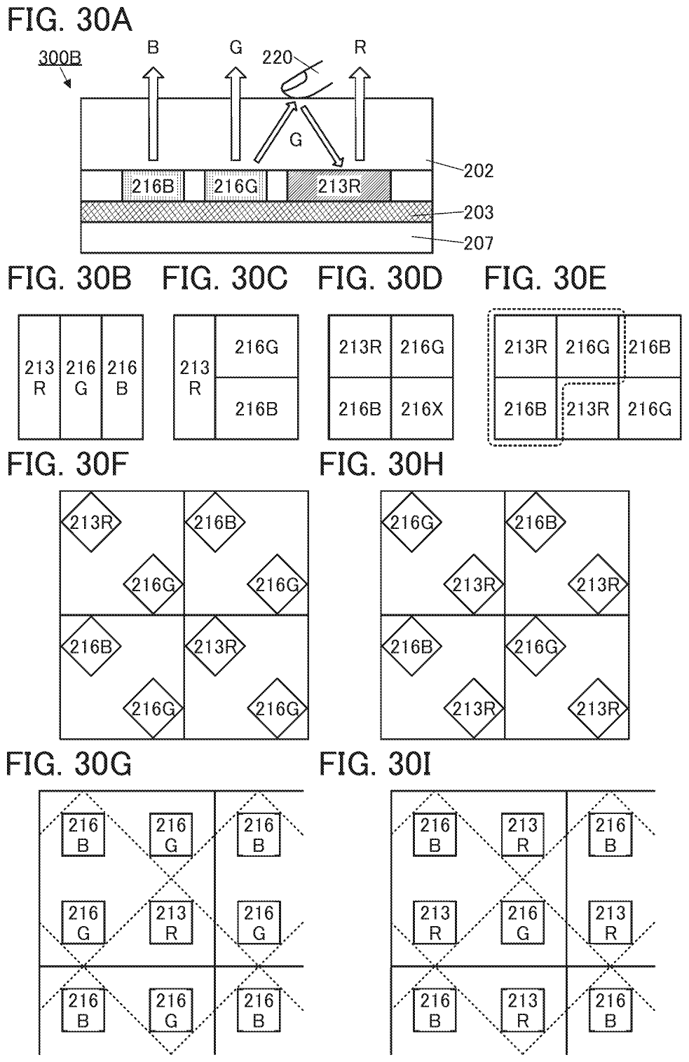

A display panel 300B illustrated in FIG. 30A includes the light-emitting element 216B, the light-emitting element 216G, and a light-emitting and light-receiving element 213R. The light-emitting and light-receiving element 213R has a function of a light-emitting element that emits red (R) light, and a function of a photoelectric conversion element that receives visible light. FIG. 30A illustrates an example in which the light-emitting and light-receiving element 213R receives green (G) light emitted from the light-emitting element 216G. Note that the light-emitting and light-receiving element 213R may receive blue (B) light emitted from the light-emitting element 216B. The light-emitting and light-receiving element 213R may receive both green light and blue light.

For example, the light-emitting and light-receiving element 213R preferably receives light having a shorter wavelength than light emitted from itself. Alternatively, the light-emitting and light-receiving element 213R may receive light (e.g., infrared light) having a longer wavelength than light emitted from itself. The light-emitting and light-receiving element 213R may receive light having approximately the same wavelength as light emitted from itself; however, in that case, the light-emitting and light-receiving element 213R also receives light emitted from itself, whereby its emission efficiency might be decreased. Therefore, the peak of the emission spectrum and the peak of the absorption spectrum of the light-emitting and light-receiving element 213R preferably overlap as little as possible.

Here, light emitted from the light-emitting and light-receiving element is not limited to red light. Furthermore, the light emitted from the light-emitting elements is not limited to the combination of green light and blue light. For example, the light-emitting and light-receiving element can be an element that emits green or blue light and receives light having a different wavelength from light emitted from itself.

The light-emitting and light-receiving element 213R serves as both a light-emitting element and a light-receiving element as described above, whereby the number of elements provided in one pixel can be reduced. Thus, higher resolution, a higher aperture ratio, higher definition, and the like can be easily achieved.

FIG. 30B to FIG. 30I illustrate examples of a pixel that can be used in the display panel 300B.

FIG. 30B illustrates an example in which the light-emitting and light-receiving element 213R, the light-emitting element 216G, and the light-emitting element 216B are arranged in one column. FIG. 30C illustrates an example in which the light-emitting element 216G and the light-emitting element 216B are alternately arranged in the vertical direction and the light-emitting and light-receiving element 213R is provided alongside the light-emitting elements.

FIG. 30D illustrates an example in which three light-emitting elements (the light-emitting element 216G, the light-emitting element 216B, and a light-emitting element 216X) and one light-emitting and light-receiving element are arranged in a matrix of 2×2. The light-emitting element 216X is an element that emits light of a color other than R, G, and B. The light of a color other than R, G, and B can be white (W) light, yellow (Y) light, cyan (C) light, magenta (M) light, infrared light (IR), ultraviolet light (UV), or the like. In the case where the light-emitting element 216X emits infrared light, the light-emitting and light-receiving element preferably has a function of detecting infrared light or a function of detecting both visible light and infrared light. The wavelength of light detected by the light-emitting and light-receiving element can be determined depending on the application of a sensor.

FIG. 30E illustrates two pixels. A region that includes three elements and is enclosed by a dotted line corresponds to one pixel. Each of the pixels includes the light-emitting element 216G, the light-emitting element 216B, and the light-emitting and light-receiving element 213R. In the left pixel illustrated in FIG. 30E, the light-emitting element 216G is provided in the same row as the light-emitting and light-receiving element 213R, and the light-emitting element 216B is provided in the same column as the light-emitting and light-receiving element 213R. In the right pixel illustrated in FIG. 30E, the light-emitting element 216G is provided in the same row as the light-emitting and light-receiving element 213R, and the light-emitting element 216B is provided in the same column as the light-emitting element 216G. In the pixel layout illustrated in FIG. 30E, the light-emitting and light-receiving element 213R, the light-emitting element 216G, and the light-emitting element 216B are repeatedly arranged in both the odd-numbered row and the even-numbered row, and in each column, the light-emitting elements or the light-emitting element and the light-emitting and light-receiving element that are arranged in the odd-numbered row and the even-numbered row emit light of different colors.

FIG. 30F illustrates four pixels which employ a PenTile arrangement; adjacent two pixels have different combinations of light-emitting elements or light-emitting and light-receiving elements that emit light of two different colors. FIG. 30F illustrates the top-surface shapes of the light-emitting elements or light-emitting and light-receiving elements.

The upper left pixel and the lower right pixel in FIG. 30F each include the light-emitting and light-receiving element 213R and the light-emitting element 216G. The upper right pixel and the lower left pixel each include the light-emitting element 216G and the light-emitting element 216B. That is, in the example illustrated in FIG. 30F, the light-emitting element 216G is provided in each pixel.

The top surface shape of the light-emitting elements and the light-emitting and light-receiving elements is not particularly limited and can be a circular shape, an elliptical shape, a polygonal shape, a polygonal shape with rounded corners, or the like. For example, FIG. 30F illustrates an example in which the top surface shapes of the light-emitting elements and the light-emitting and light-receiving elements are each a square tilted at approximately 450 (a diamond shape). Note that the top surface shapes of the light-emitting elements and the light-emitting and light-receiving elements may vary depending on the color thereof, or the light-emitting elements and the light-emitting and light-receiving elements of some colors or every color may have the same top surface shape.

The sizes of light-emitting regions (or light-emitting and light-receiving regions) of the light-emitting elements and the light-emitting and light-receiving elements may vary depending on the color thereof, or the light-emitting elements and the light-emitting and light-receiving elements of some colors or every color may have light-emitting regions of the same size. For example, in FIG. 30F, the light-emitting region of the light-emitting element 216G provided in each pixel may have a smaller area than the light-emitting region (or the light-emitting and light-receiving region) of the other elements.

FIG. 30G is a modification example of the pixel arrangement illustrated in FIG. 30F. Specifically, the structure in FIG. 30G is obtained by rotating the structure in FIG. 30F by 45°. Although one pixel is regarded as including two elements in FIG. 30F, one pixel can be regarded as being formed of four elements as illustrated in FIG. 30G.

FIG. 30H is a modification example of the pixel arrangement of FIG. 30F. The upper left pixel and the lower right pixel in FIG. 30H each include the light-emitting and light-receiving element 213R and the light-emitting element 216G. The upper right pixel and the lower left pixel each include the light-emitting and light-receiving element 213R and the light-emitting element 216B. That is, in the example illustrated in FIG. 30H, the light-emitting and light-receiving element 213R is provided in each pixel. The structure illustrated in FIG. 30H achieves higher-resolution image capturing than the structure illustrated in FIG. 30F because of having the light-emitting and light-receiving element 213R in each pixel. Thus, the accuracy of biometric authentication can be increased, for example.

FIG. 30I illustrates a modification example of the pixel arrangement illustrated in FIG. 30H, obtained by rotating the pixel arrangement illustrated in FIG. 30H by 45°.

In FIG. 30I, one pixel is described as being formed of four elements (two light-emitting elements and two light-emitting and light-receiving elements). When one pixel includes a plurality of light-emitting and light-receiving elements having a light-receiving function as described above, high-resolution image capturing can be performed. Accordingly, the accuracy of biometric authentication can be increased. For example, the resolution of image capturing can be the square root of 2 times the resolution of display.

A display apparatus that employs the structure illustrated in FIG. 30H or FIG. 30I includes p (p is an integer greater than or equal to 2) first light-emitting elements, q (q is an integer greater than or equal to 2) second light-emitting elements, and r (r is an integer greater than p and q) light-emitting and light-receiving elements. As for p and r, r=2p is satisfied. As for p, q, and r, r=p+q is satisfied. Either the first light-emitting elements or the second light-emitting elements emit green light, and the other light-emitting elements emit blue light. The light-emitting and light-receiving elements emit red light and have a light-receiving function.

In the case where touch operation is detected with the light-emitting and light-receiving elements, for example, it is preferable that light emitted from a light source be hard for a user to recognize. Since blue light has lower visibility than green light, light-emitting elements that emit blue light are preferably used as a light source. Accordingly, the light-emitting and light-receiving elements preferably have a function of receiving blue light. Note that without limitation to the above, light-emitting elements used as a light source can be selected as appropriate depending on the sensitivity of the light-emitting and light-receiving elements.

As described above, the display apparatus of this embodiment can employ any of various types of pixel arrangements.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 4

In this embodiment, a light-emitting element (also referred to as a light-emitting device) and a light-receiving element (also referred to as a light-receiving device) that can be used in a light-emitting and light-receiving apparatus of one embodiment of the present invention will be described.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device having a single structure includes one light-emitting unit between a pair of electrodes, and the light-emitting unit preferably includes one or more light-emitting layers. To obtain white light emission by using two light-emitting layers, two light-emitting layers are selected such that the light-emitting layers emit light of complementary colors. For example, when the emission color of a first light-emitting layer and the emission color of a second light-emitting layer are complementary colors, the light-emitting device can be configured to emit white light as a whole. To obtain white light emission by using three or more light-emitting layers, the light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. When light-emitting layers that emit light of the same color are used in each light-emitting unit, luminance per predetermined current can be increased, and the light-emitting device can have higher reliability than that with a single structure. To obtain white light emission in the tandem structure, the structure is made so that light from light-emitting layers of the plurality of light-emitting units can be combined to be white light. Note that a combination of emission colors for obtaining white light emission is similar to that in the case of a single structure. In the device having a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. To reduce power consumption, a light-emitting device having an SBS structure is suitably used. Meanwhile, the white-light-emitting device is suitable in terms of lower manufacturing cost or higher manufacturing yield because the manufacturing process is simpler than that of the light-emitting device having an SBS structure.

Next, detailed structures of the light-emitting element, the light-receiving element, and the light-emitting and light-receiving element which can be used in the display apparatus of one embodiment of the present invention will be described.

The display apparatus of one embodiment of the present invention can have any of the following structures: a top-emission structure in which light is emitted in a direction opposite to the substrate where the light-emitting elements are formed, a bottom-emission structure in which light is emitted toward the substrate where the light-emitting elements are formed, and a dual-emission structure in which light is emitted toward both surfaces.

In this embodiment, a top-emission display apparatus is described as an example.

In this specification and the like, unless otherwise specified, in describing a structure including a plurality of components (light-emitting elements, light-emitting layers, or the like), alphabets are omitted when a common part of the components is described. For example, the term “light-emitting layer 383” is sometimes used to describe a common part of a light-emitting layer 383R, a light-emitting layer 383G, and the like.

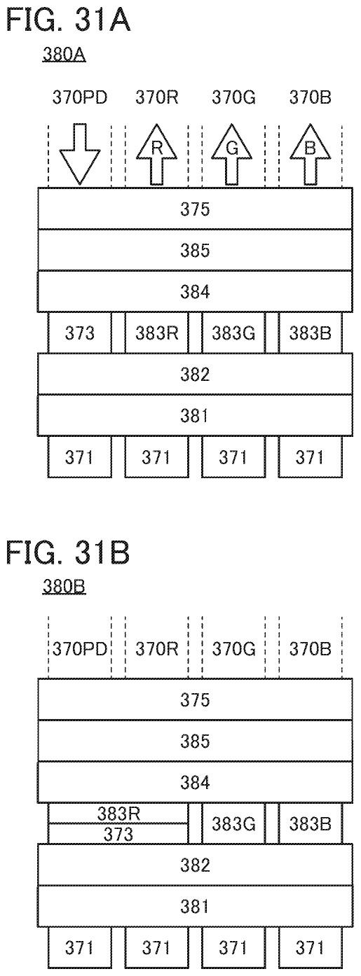

A display apparatus 380A illustrated in FIG. 31A includes a light-receiving element 370PD, a light-emitting element 370R that emits red (R) light, a light-emitting element 370G that emits green (G) light, and a light-emitting element 370B that emits blue (B) light.

Each of the light-emitting elements includes a pixel electrode 371, a hole-injection layer 381, a hole-transport layer 382, a light-emitting layer, an electron-transport layer 384, an electron-injection layer 385, and a common electrode 375 that are stacked in this order. The light-emitting element 370R includes the light-emitting layer 383R, the light-emitting element 370G includes the light-emitting layer 383G, and the light-emitting element 370B includes a light-emitting layer 383B. The light-emitting layer 383R contains a light-emitting substance that emits red light, the light-emitting layer 383G contains a light-emitting substance that emits green light, and the light-emitting layer 383B contains a light-emitting substance that emits blue light.

The light-emitting elements are electroluminescent elements that emit light to the common electrode 375 side by voltage application between the pixel electrode 371 and the common electrode 375.

The light-receiving element 370PD includes the pixel electrode 371, the hole-injection layer 381, the hole-transport layer 382, an active layer 373, the electron-transport layer 384, the electron-injection layer 385, and the common electrode 375 that are stacked in this order.

The light-receiving element 370PD is a photoelectric conversion element that receives light entering from the outside of the display apparatus 380A and converts it into an electric signal.

This embodiment is described assuming that the pixel electrode 371 functions as an anode and the common electrode 375 functions as a cathode in both of the light-emitting element and the light-receiving element. In other words, the light-receiving element is driven by application of reverse bias between the pixel electrode 371 and the common electrode 375, whereby light incident on the light-receiving element can be detected and charge can be generated and extracted as current.

In the display apparatus of this embodiment, an organic compound is used for the active layer 373 of the light-receiving element 370PD. The light-receiving element 370PD can share the layers other than the active layer 373 with the light-emitting elements. Therefore, the light-receiving element 370PD can be formed concurrently with the formation of the light-emitting elements only by adding a step of depositing the active layer 373 in the formation step of the light-emitting elements. The light-emitting elements and the light-receiving element 370PD can be formed over one substrate. Accordingly, the light-receiving element 370PD can be incorporated into the display apparatus without a significant increase in the number of manufacturing steps.

The display apparatus 380A is an example in which the light-receiving element 370PD and the light-emitting elements have a common structure except that the active layer 373 of the light-receiving element 370PD and the light-emitting layers 383 of the light-emitting elements are separately formed. Note that the structures of the light-receiving element 370PD and the light-emitting elements are not limited thereto. The light-receiving element 370PD and the light-emitting elements may include separately formed layers in addition to the active layer 373 and the light-emitting layers 383. The light-receiving element 370PD and the light-emitting elements preferably include at least one layer used in common (common layer). Thus, the light-receiving element 370PD can be incorporated into the display apparatus without a significant increase in the number of manufacturing steps.

A conductive film that transmits visible light is used as the electrode through which light is extracted, which is either the pixel electrode 371 or the common electrode 375. A conductive film that reflects visible light is preferably used as the electrode through which light is not extracted.

The light-emitting element includes at least the light-emitting layer 383. In addition to the light-emitting layer 383, the light-emitting element may further include a layer containing a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

For example, the light-emitting elements and the light-receiving element can share at least one of the hole-injection layer, the hole-transport layer, the electron-transport layer, and the electron-injection layer. Furthermore, at least one of the hole-injection layer, the hole-transport layer, the electron-transport layer, and the electron-injection layer can be separately formed for the light-emitting elements and the light-receiving element.

The hole-injection layer is a layer that injects holes from an anode to the hole-transport layer and contains a material with a high hole-injection property. As the material with a high hole-injection property, an aromatic amine compound or a composite material containing a hole-transport material and an acceptor material (an electron-accepting material) can be used.

In the light-emitting element, the hole-transport layer is a layer that transports holes, which are injected from the anode by the hole-injection layer, to the light-emitting layer. In the light-receiving element, the hole-transport layer is a layer that transports holes, which are generated in the active layer on the basis of incident light, to the anode. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

In the light-emitting element, the electron-transport layer is a layer that transports electrons, which are injected from the cathode by the electron-injection layer, to the light-emitting layer. In the light-receiving element, the electron-transport layer is a layer that transports electrons, which are generated in the active layer on the basis of incident light, to the cathode. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a Ti-electron deficient heteroaromatic compound such as a nitrogen-containing heteroaromatic compound.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The light-emitting layer 383 is a layer that contains a light-emitting substance. The light-emitting layer 383 can contain one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer 383 may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer 383 preferably contains a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In a combination of materials for forming an exciplex, the HOMO level (the highest occupied molecular orbital level) of the hole-transport material is preferably higher than or equal to the HOMO level of the electron-transport material. The LUMO level (the lowest unoccupied molecular orbital level) of the hole-transport material is preferably higher than or equal to the LUMO level of the electron-transport material. The LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of a mixed film in which the hole-transport material and the electron-transport material are mixed is shifted to the longer wavelength side than the emission spectrum of each of the materials (or has another peak on the longer wavelength side), observed by comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the PL lifetime of each of the materials, observed by comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed by comparison of the transient EL of the hole-transport material, the transient EL of the electron-transport material, and the transient EL of the mixed film of these materials.

The active layer 373 includes a semiconductor. Examples of the semiconductor include an inorganic semiconductor such as silicon and an organic semiconductor including an organic compound. This embodiment illustrates an example in which an organic semiconductor is used as the semiconductor included in the active layer 373. An organic semiconductor is preferably used, in which case the light-emitting layer 383 and the active layer 373 can be formed by the same method (e.g., a vacuum evaporation method) and thus the same manufacturing apparatus can be used.

Examples of an n-type semiconductor material contained in the active layer 373 are electron-accepting organic semiconductor materials such as fullerene (e.g., C₆₀ fullerene and C₇₀ fullerene) and a fullerene derivative. Fullerene has a soccer ball-like shape, which is energetically stable. Both the HOMO level and the LUMO level of fullerene are deep (low). Having a deep LUMO level, fullerene has an extremely high electron-accepting property (acceptor property). In general, when Tc-electron conjugation (resonance) spreads in a plane as in benzene, an electron-donating property (donor property) becomes high; however, since fullerene has a spherical shape, fullerene has a high electron-accepting property even when Tc-electron conjugation widely spreads. The high electron-accepting property efficiently causes rapid charge separation and is useful for a light-receiving element. Both C₆₀ fullerene and C₇₀ fullerene have a wide absorption band in the visible light region, and C₇₀ fullerene is especially preferable because of having a larger π-electron conjugation system and a wider absorption band in the long wavelength region than C₆₀ fullerene. Other examples of fullerene derivatives include [6,6]-Phenyl-C71-butyric acid methyl ester (abbreviation: PC70BM), [6,6]-Phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C60 (abbreviation: ICBA).

Another example of an n-type semiconductor material is a perylenetetracarboxylic derivative such as N,N-dimethyl-3,4,9,10-perylenetetracarboxylic diimide (abbreviation: Me-PTCDI).

Another example of an n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer 373 include electron-donating organic semiconductor materials such as copper(II) phthalocyanine (CuPc), tetraphenyldibenzoperiflanthene (DBP), zinc phthalocyanine (ZnPc), tin(II) phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the active layer 373 is preferably formed by co-evaporation of an n-type semiconductor and a p-type semiconductor. Alternatively, the active layer 373 may be formed by stacking an n-type semiconductor and a p-type semiconductor.

Either a low molecular compound or a high molecular compound can be used for the light-emitting element and the light-receiving element, and an inorganic compound may also be contained. Each of the layers included in the light-emitting element and the light-receiving element can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

For the active layer 373, a high molecular compound such as Poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

A display apparatus 380B illustrated in FIG. 31B is different from the display apparatus 380A in that the light-receiving element 370PD and the light-emitting element 370R have the same structure.

The light-receiving element 370PD and the light-emitting element 370R share the active layer 373 and the light-emitting layer 383R.

Here, it is preferable that the light-receiving element 370PD have the same structure as the light-emitting element that emits light having a wavelength longer than that of the light desired to be detected. For example, the light-receiving element 370PD with a structure for detecting blue light can have the same structure as one or both of the light-emitting element 370R and the light-emitting element 370G. For example, the light-receiving element 370PD with a structure for detecting green light can have the same structure as the light-emitting element 370R.

When the light-receiving element 370PD and the light-emitting element 370R have a common structure, the number of deposition steps and the number of masks can be smaller than those for the structure in which the light-receiving element 370PD and the light-emitting element 370R include separately formed layers. As a result, the number of manufacturing steps and the manufacturing cost of the display apparatus can be reduced.

When the light-receiving element 370PD and the light-emitting element 370R have a common structure, a margin for misalignment can be narrower than that for the structure in which the light-receiving element 370PD and the light-emitting element 370R include separately formed layers. Accordingly, the aperture ratio of a pixel can be increased, so that the light extraction efficiency of the display apparatus can be increased. This can extend the lifetime of the light-emitting element. Furthermore, the display apparatus can exhibit a high luminance. Moreover, the resolution of the display apparatus can also be increased.

The light-emitting layer 383R contains a light-emitting substance that emits red light. The active layer 373 contains an organic compound that absorbs light having a wavelength shorter than that of red light (e.g., one or both of green light and blue light). The active layer 373 preferably contains an organic compound that does not easily absorb red light and that absorbs light having a wavelength shorter than that of red light. In that case, red light can be efficiently extracted from the light-emitting element 370R, and the light-receiving element 370PD can detect light having a wavelength shorter than that of red light with high accuracy.

Although the light-emitting element 370R and the light-receiving element 370PD have the same structure in an example of the display apparatus 380B, the light-emitting element 370R and the light-receiving element 370PD may include optical adjustment layers with different thicknesses.

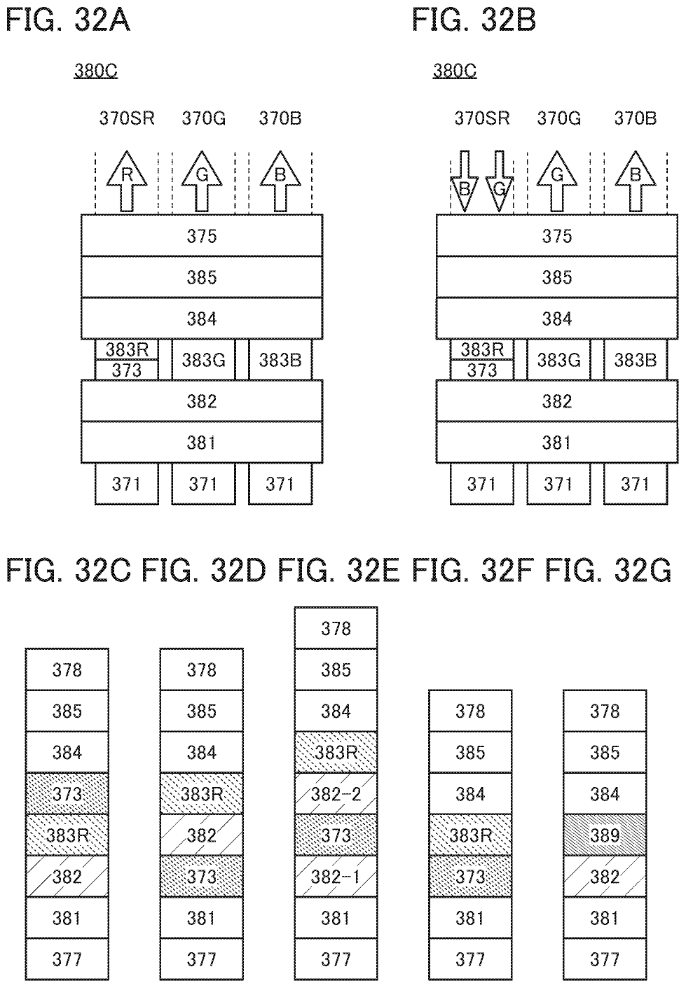

A display apparatus 380C illustrated in FIG. 32A and FIG. 32B includes a light-emitting and light-receiving element 370SR that emits red (R) light and has a light-receiving function, the light-emitting element 370G, and the light-emitting element 370B. The above description of the display apparatus 380A can be referred to for the structures of the light-emitting element 370G and the light-emitting element 370B, for example.

The light-emitting and light-receiving element 370SR includes the pixel electrode 371, the hole-injection layer 381, the hole-transport layer 382, the active layer 373, the light-emitting layer 383R, the electron-transport layer 384, the electron-injection layer 385, and the common electrode 375 that are stacked in this order. The light-emitting and light-receiving element 370SR has the same structure as the light-emitting element 370R and the light-receiving element 370PD exemplified in the display apparatus 380B.

FIG. 32A illustrates the case where the light-emitting and light-receiving element 370SR functions as a light-emitting element. FIG. 32A illustrates an example in which the light-emitting element 370B emits blue light, the light-emitting element 370G emits green light, and the light-emitting and light-receiving element 370SR emits red light.

FIG. 32B illustrates the case where the light-emitting and light-receiving element 370SR functions as a light-receiving element. FIG. 32B illustrates an example in which the light-emitting and light-receiving element 370SR receives blue light emitted by the light-emitting element 370B and green light emitted by the light-emitting element 370G.

The light-emitting element 370B, the light-emitting element 370G, and the light-emitting and light-receiving element 370SR each include the pixel electrode 371 and the common electrode 375. In this embodiment, the case where the pixel electrode 371 functions as an anode and the common electrode 375 functions as a cathode is described as an example. The light-emitting and light-receiving element 370SR is driven by application of reverse bias between the pixel electrode 371 and the common electrode 375, whereby light incident on the light-emitting and light-receiving element 370SR can be detected and charge can be generated and extracted as current.

It can be said that the light-emitting and light-receiving element 370SR has a structure in which the active layer 373 is added to the light-emitting element. That is, the light-emitting and light-receiving element 370SR can be formed concurrently with the formation of the light-emitting elements only by adding a step of depositing the active layer 373 in the formation step of the light-emitting element. The light-emitting element and the light-emitting and light-receiving element can be formed over one substrate. Thus, the display portion can be provided with one or both of an image capturing function and a sensing function without a significant increase in the number of manufacturing steps.

The stacking order of the light-emitting layer 383R and the active layer 373 is not limited. FIG. 32A and FIG. 32B each illustrate an example in which the active layer 373 is provided over the hole-transport layer 382 and the light-emitting layer 383R is provided over the active layer 373. The stacking order of the light-emitting layer 383R and the active layer 373 may be reversed.

The light-emitting and light-receiving element may exclude at least one layer of the hole-injection layer 381, the hole-transport layer 382, the electron-transport layer 384, and the electron-injection layer 385. Furthermore, the light-emitting and light-receiving element may include another functional layer such as a hole-blocking layer or an electron-blocking layer.

In the light-emitting and light-receiving element, a conductive film that transmits visible light is used as the electrode through which light is extracted. A conductive film that reflects visible light is preferably used as the electrode through which light is not extracted.

The functions and materials of the layers constituting the light-emitting and light-receiving element are similar to the functions and materials of the layers constituting the light-emitting elements and the light-receiving element and are not described in detail.

FIG. 32C to FIG. 32G illustrate examples of stacked-layer structures of light-emitting and light-receiving elements.

The light-emitting and light-receiving element illustrated in FIG. 32C includes a first electrode 377, the hole-injection layer 381, the hole-transport layer 382, the light-emitting layer 383R, the active layer 373, the electron-transport layer 384, the electron-injection layer 385, and a second electrode 378.

FIG. 32C illustrates an example in which the light-emitting layer 383R is provided over the hole-transport layer 382 and the active layer 373 is stacked over the light-emitting layer 383R.

As illustrated in FIG. 32A to FIG. 32C, the active layer 373 and the light-emitting layer 383R may be in contact with each other.

A buffer layer is preferably provided between the active layer 373 and the light-emitting layer 383R. In that case, the buffer layer preferably has a hole-transport property and an electron-transport property. For example, a substance with a bipolar property is preferably used for the buffer layer. Alternatively, as the buffer layer, at least one layer of a hole-injection layer, a hole-transport layer, an electron-transport layer, an electron-injection layer, a hole-blocking layer, an electron-blocking layer, and the like can be used. FIG. 32D illustrates an example in which the hole-transport layer 382 is used as the buffer layer.

The buffer layer provided between the active layer 373 and the light-emitting layer 383R can inhibit transfer of excitation energy from the light-emitting layer 383R to the active layer 373. Furthermore, the optical path length (cavity length) of the microcavity structure can be adjusted with the buffer layer. Thus, high emission efficiency can be obtained from the light-emitting and light-receiving element including the buffer layer between the active layer 373 and the light-emitting layer 383R.

FIG. 32E illustrates an example of a stacked-layer structure in which a hole-transport layer 382-1, the active layer 373, a hole-transport layer 382-2, and the light-emitting layer 383R are stacked in this order over the hole-injection layer 381. The hole-transport layer 382-2 functions as a buffer layer. The hole-transport layer 382-1 and the hole-transport layer 382-2 may contain the same material or different materials. Instead of the hole-transport layer 382-2, any of the above layers that can be used as the buffer layer may be used. The positions of the active layer 373 and the light-emitting layer 383R may be interchanged.

The light-emitting and light-receiving element illustrated in FIG. 32F is different from the light-emitting and light-receiving element illustrated in FIG. 32A in that the hole-transport layer 382 is not included. In this manner, the light-emitting and light-receiving element may exclude at least one layer of the hole-injection layer 381, the hole-transport layer 382, the electron-transport layer 384, and the electron-injection layer 385. The light-emitting and light-receiving element may include another functional layer such as a hole-blocking layer or an electron-blocking layer.

The light-emitting and light-receiving element illustrated in FIG. 32G is different from the light-emitting and light-receiving element illustrated in FIG. 32A in including a layer 389 serving as both a light-emitting layer and an active layer instead of including the active layer 373 and the light-emitting layer 383R.

As the layer serving as both a light-emitting layer and an active layer, it is possible to use, for example, a layer containing three materials which are an n-type semiconductor that can be used for the active layer 373, a p-type semiconductor that can be used for the active layer 373, and a light-emitting substance that can be used for the light-emitting layer 383R.

Note that an absorption band on the lowest energy side of an absorption spectrum of a mixed material of the n-type semiconductor and the p-type semiconductor and a maximum peak of an emission spectrum (PL spectrum) of the light-emitting substance preferably do not overlap with each other and are further preferably positioned fully apart from each other.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 5

In this embodiment, an example of a display apparatus including a light-receiving device of one embodiment of the present invention will be described.

In the display apparatus of this embodiment, a pixel can include a plurality of types of subpixels including light-emitting devices that emit light of different colors. For example, the pixel can include three types of subpixels. The three subpixels can be subpixels of three colors of red (R), green (G), and blue (B) or subpixels of three colors of yellow (Y), cyan (C), and magenta (M), for example. Alternatively, the pixel can include four types of subpixels. The four subpixels can be subpixels of four colors of R, G, B, and white (W) or subpixels of four colors of R, G, B, and Y, for example.

There is no particular limitation on the arrangement of subpixels, and a variety of methods can be employed. Examples of the arrangement of subpixels include a stripe arrangement, an S-stripe arrangement, a matrix arrangement, a delta arrangement, a Bayer arrangement, and a PenTile arrangement.

Examples of a top surface shape of the subpixel include polygons such as a triangle, a tetragon (including a rectangle and a square), and a pentagon; polygons with rounded corners; an ellipse; and a circle. Here, a top surface shape of the subpixel corresponds to a top surface shape of a light-emitting region of the light-emitting device.

In the display apparatus including light-emitting devices and a light-receiving device in each pixel, the pixel has a light-receiving function; thus, the display apparatus can detect a contact or approach of an object while displaying an image. For example, an image can be displayed by using all the subpixels included in the display apparatus; or light can be emitted by some of the subpixels as a light source and an image can be displayed by using the other subpixels.

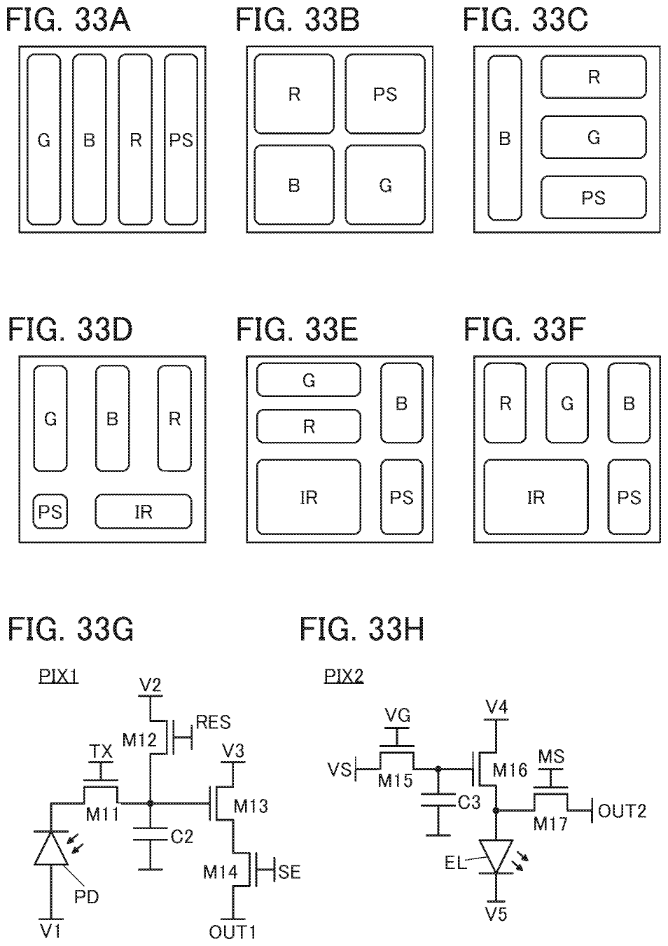

Pixels illustrated in FIG. 33A, FIG. 33B, and FIG. 33C each include a subpixel G, a subpixel B, a subpixel R, and a subpixel PS.

The pixel illustrated in FIG. 33A employs an S-stripe arrangement. The pixel illustrated in FIG. 33B employs a matrix arrangement.

In the pixel arrangement illustrated in FIG. 33C, three subpixels (the subpixel R, the subpixel G, and the subpixel PS) are vertically arranged next to one subpixel (the subpixel B).

Pixels illustrated in FIG. 33D, FIG. 33E, and FIG. 33F each include the subpixel G, the subpixel B, the subpixel R, a subpixel IR, and the subpixel PS.

FIG. 33D, FIG. 33E, and FIG. 33F illustrate examples in which one pixel is provided in two rows. Three subpixels (the subpixel G, the subpixel B, and the subpixel R) are provided in the upper row (first row), and two subpixels (one subpixel PS and one subpixel IR) are provided in the lower row (second row).

In FIG. 33D, the three vertically oriented subpixel G, subpixel B, and subpixel R are arranged laterally, and the subpixel PS and the horizontally oriented subpixel IR are arranged laterally below the three subpixels. In FIG. 33E, the two horizontally oriented subpixel G and subpixel R are arranged in the vertical direction; the vertically oriented subpixel B is arranged laterally next to the subpixels G and R; and the horizontally oriented subpixel IR and the vertically oriented subpixel PS are arranged laterally below the subpixels R, G, and B. In FIG. 33F, the three vertically oriented subpixel R, subpixel G, and subpixel B are arranged laterally, and the horizontally oriented subpixel IR and the vertically oriented subpixel PS are arranged laterally below the subpixels R, G, and B. In FIG. 33E and FIG. 33F, the area of the subpixel IR is the largest, and the area of the subpixel PS is substantially the same as that of the subpixel B and the like.

Note that the layout of the subpixels is not limited to the structures illustrated in FIG. 33A to FIG. 33F.

The subpixel R includes a light-emitting device that emits red light. The subpixel G includes a light-emitting device that emits green light. The subpixel B includes a light-emitting device that emits blue light. The subpixel IR includes a light-emitting device that emits infrared light. The subpixel PS includes a light-receiving device. Although there is no particular limitation on the wavelength of light that the subpixel PS detects, the light-receiving device included in the subpixel PS preferably has sensitivity with respect to light emitted from the light-emitting device included in the subpixel R, the subpixel G, the subpixel B, or the subpixel TR. The light-receiving device preferably detects one or more of light in blue, violet, bluish violet, green, yellow green, yellow, orange, red, and infrared wavelength ranges, for example.

The light-receiving area of the subpixel PS is smaller than the light-emitting area of each of the other subpixels. A smaller light-receiving area leads to a narrower image-capturing range, inhibits a blur in a captured image, and improves the definition. Thus, by using the subpixel PS, high-resolution or high-definition image capturing is possible. For example, image capturing for biometric authentication with the use of a fingerprint, a palm print, the iris, the shape of a blood vessel (including the shape of a vein and the shape of an artery), a face, or the like is possible by using the subpixel PS.

Moreover, the subpixel PS can be used in a touch sensor (also referred to as a direct touch sensor), a near touch sensor (also referred to as a hover sensor, a hover touch sensor, a contactless touch sensor, or a touchless sensor), or the like. For example, the subpixel PS preferably detects infrared light. Thus, touch detection is possible even in a dark place.

Here, the touch sensor or the near touch sensor can detect an approach or contact of an object (e.g., a finger, a hand, or a pen). The touch sensor can detect an object when the display apparatus and the object come in direct contact with each other. The near touch sensor can detect an object even when the object is not in contact with the display apparatus. For example, the display apparatus can preferably detect an object when the distance between the display apparatus and the object is greater than or equal to 0.1 mm and less than or equal to 300 mm, preferably greater than or equal to 3 mm and less than or equal to 50 mm. With this structure, the display apparatus can be controlled without an object directly contacting with the display apparatus. In other words, the display apparatus can be controlled in a contactless (touchless) manner. With the above structure, the display apparatus can have a reduced risk of being dirty or damaged, or can be operated without the object directly touching a dirt (e.g., dust or a virus) attached to the display apparatus.

For high-resolution image capturing, the subpixel PS is preferably provided in every pixel included in the display apparatus. Meanwhile, in the case where the subpixel PS is used in a touch sensor, a near touch sensor, or the like, high accuracy is not required as compared to the case of capturing an image of a fingerprint or the like; accordingly, the subpixel PS is provided in some of the pixels in the display apparatus. When the number of subpixels PS included in the display apparatus is smaller than the number of subpixels R, for example, higher detection speed can be achieved.

FIG. 33G illustrates an example of a pixel circuit for a subpixel including a light-receiving device. FIG. 33H illustrates an example of a pixel circuit for a subpixel including a light-emitting device.

A pixel circuit PIX1 illustrated in FIG. 33G includes a light-receiving device PD, a transistor M11, a transistor M12, a transistor M13, a transistor M14, and a capacitor C2. Here, a photodiode is used as an example of the light-receiving device PD.

An anode of the light-receiving device PD is electrically connected to a wiring V1, and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. A gate of the transistor M14 is electrically connected to a wiring SE, and the other of the source and the drain of the transistor M14 is electrically connected to a wiring OUT1.

A constant potential is supplied to the wiring V1, the wiring V2, and the wiring V3. When the light-receiving device PD is driven with a reverse bias, the wiring V2 is supplied with a potential higher than the potential of the wiring V1. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with current flowing through the light-receiving device PD. The transistor M13 functions as an amplifier transistor for performing output corresponding to the potential of the node. The transistor M14 is controlled by a signal supplied to the wiring SE and functions as a selection transistor for reading an output corresponding to the potential of the node by an external circuit connected to the wiring OUT1.

A pixel circuit PIX2 illustrated in FIG. 33H includes a light-emitting device EL, a transistor M15, a transistor M16, a transistor M17, and a capacitor C3. Here, a light-emitting diode is used as an example of the light-emitting device EL. In particular, an organic EL element is preferably used as the light-emitting device EL.

A gate of the transistor M15 is electrically connected to a wiring VG, one of a source and a drain of the transistor M15 is electrically connected to a wiring VS, and the other of the source and the drain of the transistor M15 is electrically connected to one electrode of the capacitor C3 and a gate of the transistor M16. One of a source and a drain of the transistor M16 is electrically connected to a wiring V4, and the other of the source and the drain of the transistor M16 is electrically connected to an anode of the light-emitting device EL and one of a source and a drain of the transistor M17. A gate of the transistor M17 is electrically connected to a wiring MS, and the other of the source and the drain of the transistor M17 is electrically connected to a wiring OUT2. A cathode of the light-emitting device EL is electrically connected to a wiring V5.

A constant potential is supplied to the wiring V4 and the wiring V5. The anode of the light-emitting device EL can be set to a high potential, and the cathode can be set to a lower potential than the anode. The transistor M15 is controlled by a signal supplied to the wiring VG and functions as a selection transistor for controlling a selection state of the pixel circuit PIX2. The transistor M16 functions as a driving transistor that controls current flowing through the light-emitting device EL in accordance with a potential supplied to the gate of the transistor M16. When the transistor M15 is on, a potential supplied to the wiring VS is supplied to the gate of the transistor M16, and the luminance of the light-emitting device EL can be controlled in accordance with the potential. The transistor M17 is controlled by a signal supplied to the wiring MS and has a function of outputting a potential between the transistor M16 and the light-emitting device EL to the outside through the wiring OUT2.

Here, transistors in which a metal oxide (an oxide semiconductor) is used in a semiconductor layer where a channel is formed are preferably used as the transistor M11, the transistor M12, the transistor M13, and the transistor M14 included in the pixel circuit PIX1 and the transistor M15, the transistor M16, and the transistor M17 included in the pixel circuit PIX2.

A transistor using a metal oxide having a wider band gap and a lower carrier density than silicon achieves an extremely low off-state current. Therefore, owing to the low off-state current, charge accumulated in a capacitor that is connected in series to the transistor can be retained for a long time. Hence, it is particularly preferable to use transistors containing an oxide semiconductor as the transistor M11, the transistor M12, and the transistor M15 each of which is connected in series to the capacitor C2 or the capacitor C3. Moreover, the use of transistors using an oxide semiconductor as the other transistors can reduce the manufacturing cost.

For example, the off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

Alternatively, transistors using silicon as a semiconductor where a channel is formed can be used as the transistor M11 to the transistor M17. It is particularly preferable to use silicon with high crystallinity, such as single crystal silicon or polycrystalline silicon, because high field-effect mobility can be achieved and higher-speed operation can be performed.

Alternatively, a transistor containing an oxide semiconductor may be used as one or more of the transistor M11 to the transistor M17, and transistors containing silicon may be used as the other transistors.

Although n-channel transistors are illustrated in FIG. 33G and FIG. 33H, p-channel transistors can alternatively be used.

The transistors included in the pixel circuit PIX1 and the transistors included in the pixel circuit PIX2 are preferably formed side by side over the same substrate. It is particularly preferable that the transistors included in the pixel circuit PIX1 and the transistors included in the pixel circuit PIX2 be periodically arranged in one region.

One or more layers including the transistor and/or the capacitor are preferably provided to overlap with the light-receiving device PD or the light-emitting device EL. Thus, the effective area of each pixel circuit can be reduced, and a high-resolution light-receiving portion or display portion can be achieved.

The refresh rate can be variable in the display apparatus of one embodiment of the present invention. For example, the refresh rate can be adjusted in accordance with the contents displayed on the display apparatus (e.g., adjusted in the range from 0.01 Hz to 240 Hz inclusive), whereby power consumption can be reduced. The driving with a lowered refresh rate for reducing power consumption of a display apparatus may be referred to as idling stop (IDS) driving.

The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 6

In this embodiment, a high-resolution display apparatus will be described.

Wearable electronic devices for VR, AR, and the like can provide 3D images by using parallax. In that case, it is necessary to display an image for the right eye in the right eye's field of view and display an image for the left eye in the left eye's field of view. Although the shape of a display portion in a display apparatus may be a horizontal rectangular shape, pixels provided outside the right eye's field of view and the left eye's field of view do not contribute to display, and thus black is always displayed in these pixels.

In view of the above, it is preferred that a display portion of a display panel be divided into two regions for the right eye and for the left eye, and that pixels not be provided in an outer region which does not contribute to display. Hence, power consumption needed for writing to pixels can be reduced. Moreover, loads on data lines, gate lines, and the like are reduced, so that display with a high frame rate is possible. Consequently, smooth moving images can be displayed, which improves sense of reality.

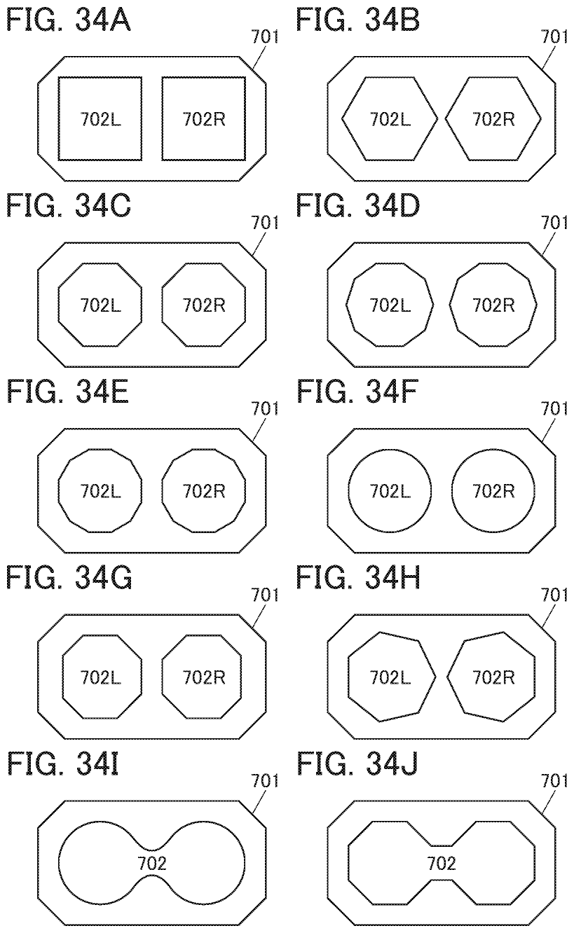

FIG. 34A illustrates a structure example of a display panel. In FIG. 34A, a display portion 702L for the left eye and a display portion 702R for the right eye are provided inward from a substrate 701. Note that in addition to the display portion 702L and the display portion 702R, a driver circuit, a wiring, an IC, an FPC, or the like may be provided over the substrate 701.

The display portion 702L and the display portion 702R illustrated in FIG. 34A each have a square top surface shape.

The top surface shapes of the display portion 702L and the display portion 702R may be other regular polygons. FIG. 34B illustrates an example of the case where the top surface shape is a regular hexagon; FIG. 34C illustrates an example of the case where the top surface shape is a regular octagon; FIG. 34D illustrates an example of the case where the top surface shape is a regular decagon; and FIG. 34E illustrates an example of the case where the top surface shape is a regular dodecagon. Note that a polygon that is not a regular polygon may be used. Moreover, a regular polygon or a polygon with rounded corners may be used.

Since the display portion consists of pixels arranged in a matrix, a linear portion of the outline of the display portion is not strictly a straight line and can be partly a stair-like portion. In particular, a linear portion that is not parallel to the direction of pixel arrangement has a stair-like top surface shape. Since the user watches images without perceiving the shape of the pixels, a tilted outline, which is stair-like to be exact, of the display portion can be regarded as a straight line. Similarly, a curved portion, which is stair-like to be exact, of the outline of the display portion can be regarded as a curve.

FIG. 34F illustrates an example of the case where the top surface shapes of the display portion 702L and the display portion 702R are circular.

The top surface shapes of the display portion 702L and the display portion 702R may be bilaterally asymmetrical. Moreover, the top surface shapes are not necessarily regular polygonal.

FIG. 34G illustrates an example of the case where the top surface shapes of the display portion 702L and the display portion 702R are bilaterally asymmetric octagonal. FIG. 34H illustrates an example of the case where the top surface shape is regular heptagonal. Even when the top surface shapes of the display portion 702L and the display portion 702R are bilaterally asymmetrical in this manner, the display portion 702L and the display portion 702R are preferably arranged bilaterally symmetrically. Consequently, an image with no unnaturalness can be provided.

Although the structures where the display portion is divided into two are described above, the display portions may have a continuous shape.

FIG. 34I illustrates an example in which the two circular display portions 702 in FIG. 34F are connected. FIG. 34J illustrates an example in which the two regular octagonal display portions 702 in FIG. 34C are connected.

The above is the description of the structure examples of the display panel.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 7

In this embodiment, a metal oxide that can be used in the OS transistor described in the above embodiment will be described.

The metal oxide used in the OS transistor preferably contains at least indium or zinc, and further preferably contains indium and zinc. The metal oxide preferably contains indium, M(M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. Specifically, M is preferably one or more kinds selected from gallium, aluminum, yttrium, and tin, and further preferably M is gallium.

In addition, the metal oxide can be formed by a sputtering method, a CVD method such as an MOCVD method, an ALD method, or the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method. The XRD spectrum obtained by GIXD measurement may be hereinafter simply referred to as an XRD spectrum.

For example, the XRD spectrum of a quartz glass substrate shows a peak with a substantially bilaterally symmetrical shape. On the other hand, the peak of the XRD spectrum of an In—Ga—Zn oxide film having a crystal structure has a bilaterally asymmetrical shape. The bilaterally asymmetrical peak of the XRD spectrum clearly shows the existence of crystals in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film deposited at room temperature. Thus, it is suggested that the In—Ga—Zn oxide deposited at room temperature is in an intermediate state, which is neither a single crystal nor polycrystal nor an amorphous state, and it cannot be concluded that the In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductors include the above-described CAAC-OS and nc-OS. Other examples of the non-single-crystal oxide semiconductors include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor having a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga, Zn) layer) are stacked. Indium and gallium can be replaced with each other. Therefore, indium may be contained in the (Ga, Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and traps carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor having small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of flexibility of the manufacturing process.

[nc-OS]

In the nc-OS, a microscopic region (e.g., a region with a size greater than or equal to 1 nm and less than or equal to 10 nm, specifically, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-like OS]

The a-like OS is an oxide semiconductor having a structure between those of the nc-OS and the amorphous oxide semiconductor. The a-like OS has a void or a low-density region. That is, the a-like OS has low crystallinity as compared with the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS will be described in detail. Note that the CAC-OS relates to the material composition.

### [CAC-OS]

The CAC-OS refers to one composition of a material in which elements included in a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. Alternatively, for example, the first region has [In] higher than [In] in the second region and [Ga] lower than [Ga] in the second region. Moreover, the second region has [Ga] higher than [Ga] in the first region and [In] lower than [In] in the first region.

Specifically, the first region includes indium oxide, indium zinc oxide, or the like as its main component. The second region includes gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof and these regions are randomly present to form a mosaic pattern. Thus, it is suggested that the CAC-OS has a structure in which metal elements are unevenly distributed.

The CAC-OS can be formed by a sputtering method under a condition where a substrate is not heated intentionally, for example. Moreover, in the case of forming the CAC-OS by a sputtering method, any one or more selected from an inert gas (typically, argon), an oxygen gas, and a nitrogen gas are used for a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

On the other hand, the second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is the most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that impurities in an oxide semiconductor refer to, for example, elements other than the main components of an oxide semiconductor. For example, an element with a concentration lower than 0.1 atomic % can be regarded as an impurity.

### <Impurities>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 8

In this embodiment, electronic devices of embodiments of the present invention will be described.

An electronic device in this embodiment includes the display apparatus of one embodiment of the present invention. The display apparatus of one embodiment of the present invention can perform image capturing with high sensitivity. In the display apparatus of one embodiment of the present invention, increases in resolution, definition, and sizes are easily achieved. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include information terminals (wearable devices) such as watch-type and bracelet-type information terminals and wearable devices capable of being worn on the head, such as a virtual reality (VR) device like a head-mounted display and a glasses-type augmented reality (AR) device. Examples of wearable devices include a substitutional reality (SR) device and a mixed reality (MR) device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320). In particular, definition of 4K2K, 8K4K, or higher is preferable. Furthermore, the pixel density (resolution) of the display apparatus of one embodiment of the present invention is preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the display apparatus with such high definition or high resolution, the electronic device can have higher realistic sensation, sense of depth, and the like in personal use such as portable use or home use.

The electronic device in this embodiment can be incorporated along a curved surface of an inside wall or an outside wall of a house or a building or the interior or the exterior of a car.

The electronic device in this embodiment may include an antenna. When a signal is received by the antenna, the electronic device can display a video, data, and the like on a display portion. When the electronic device includes the antenna and a secondary battery, the antenna may be used for contactless power transmission.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of kinds of information (a still image, a moving image, a text image, and the like) on the display portion, a function of a touch sensor, a function of displaying a calendar, date, time, and the like, a function of executing a variety of software (programs), a wireless communication function, and a function of reading out a program or data stored in a recording medium.

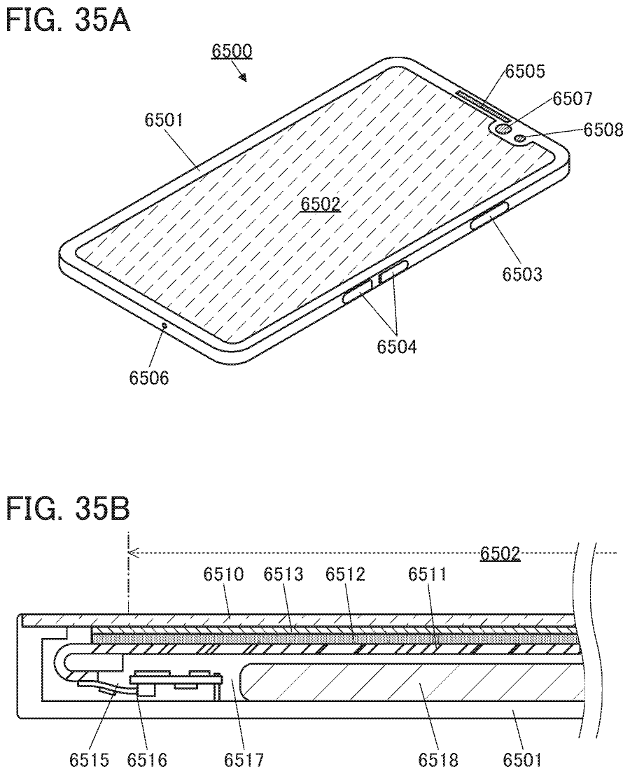

An electronic device 6500 illustrated in FIG. 35A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a function of a touch sensor.

The display apparatus of one embodiment of the present invention can be used in the display portion 6502. Accordingly, the electronic device 6500 can have a function of a touch sensor and have a function of performing biometric authentication, for example.

FIG. 35B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display (a display apparatus having flexibility) of one embodiment of the present invention can be used for the display panel 6511. Thus, an extremely lightweight electronic device can be provided. Since the display panel 6511 is extremely thin, the battery 6518 with high capacity can be mounted while the thickness of the electronic device is reduced. An electronic device with a narrow frame can be obtained when part of the display panel 6511 is folded back so that the portion connected to the FPC 6515 is positioned on the rear side of a pixel portion.

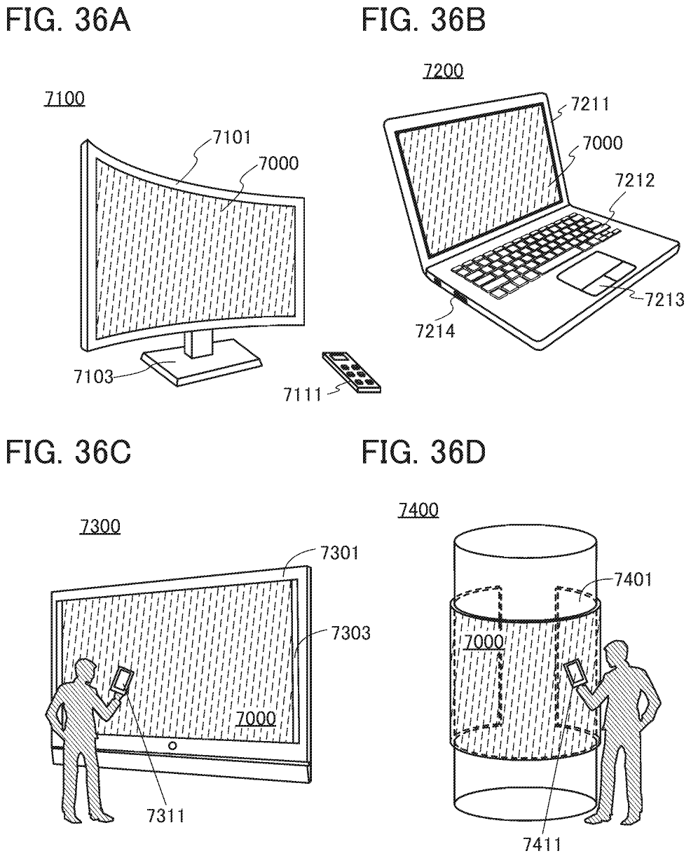

FIG. 36A illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used in the display portion 7000. Accordingly, the television device 7100 can have a function of a touch sensor and have a function of performing biometric authentication, for example.

Operation of the television device 7100 illustrated in FIG. 36A can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying data output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 36B illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000. Accordingly, the notebook personal computer 7200 can have a function of a touch sensor and have a function of performing biometric authentication, for example.

FIG. 36C and FIG. 36D illustrate examples of digital signage.

Digital signage 7300 illustrated in FIG. 36C includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 36D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 36C and FIG. 36D. Accordingly, the digital signage 7300 and the digital signage 7400 can have a function of a touch sensor and have a function of performing biometric authentication, for example.

A larger area of the display portion 7000 can increase the amount of data that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 36C and FIG. 36D, it is preferable that the digital signage 7300 or the digital signage 7400 can work with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

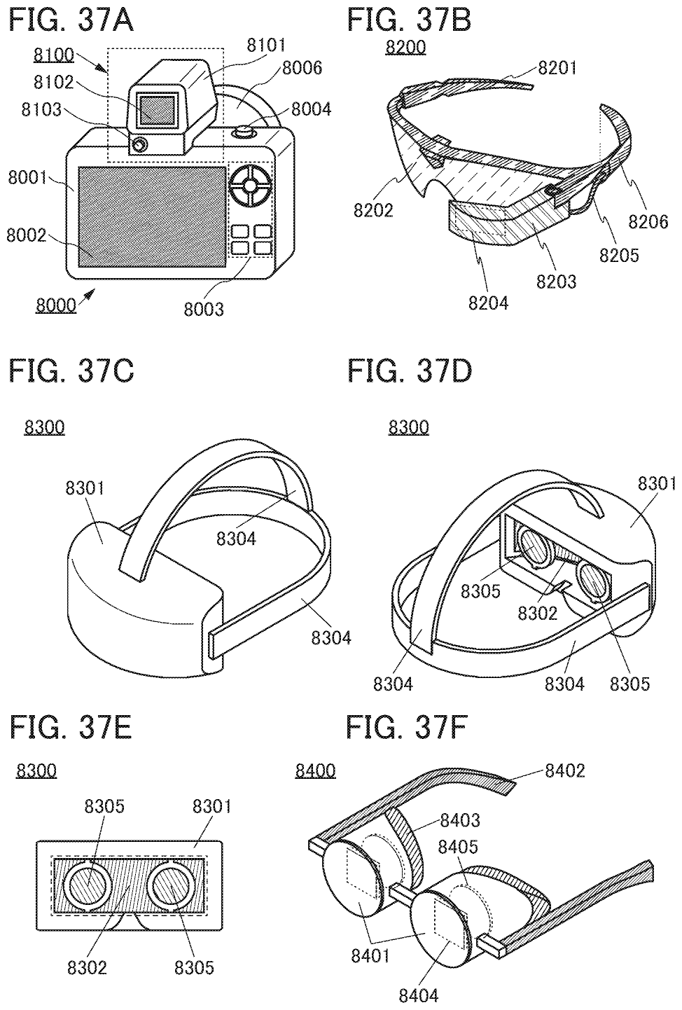

FIG. 37A is a diagram illustrating the appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing may be integrated with each other in the camera 8000.

The camera 8000 can capture images by the press of the shutter button 8004 or touch on the display portion 8002 serving as a touch panel.

The housing 8001 includes a mount including an electrode, so that, in addition to the finder 8100, a stroboscope can be connected to the housing, for example.

The finder 8100 includes a housing 8101, a display portion 8102, a button 8103, and the like.

The housing 8101 is attached to the camera 8000 with the mount engaging with a mount of the camera 8000. In the finder 8100, a video received from the camera 8000 can be displayed on the display portion 8102, for example.

The button 8103 has a function of a power button, for example.

The display apparatus of one embodiment of the present invention can be used for the display portion 8002 of the camera 8000 and the display portion 8102 of the finder 8100. Accordingly, the camera 8000 can have a function of a touch sensor and have a function of performing biometric authentication, for example. Note that a finder may be incorporated in the camera 8000.

FIG. 37B is a diagram illustrating the appearance of a head-mounted display 8200.

The head-mounted display 8200 includes a wearing portion 8201, a lens 8202, a main body 8203, a display portion 8204, a cable 8205, and the like. A battery 8206 is incorporated in the wearing portion 8201.

The cable 8205 supplies electric power from the battery 8206 to the main body 8203. The main body 8203 includes a wireless receiver, for example, and can display received video information on the display portion 8204. In addition, the main body 8203 is provided with a camera, and information on the movement of the user's eyeball or eyelid can be used as an input means.

The mounting portion 8201 may be provided with a plurality of electrodes capable of sensing current flowing in response to the movement of the user's eyeball in a position in contact with the user. Thus, the head-mounted display 8200 can have a function of recognizing the user's sight line. Furthermore, the head-mounted display 8200 may have a function of monitoring the user's pulse with the use of current flowing through the electrodes. Moreover, the mounting portion 8201 may be provided with a variety of sensors such as a temperature sensor, a pressure sensor, and an acceleration sensor. The head-mounted display 8200 may have a function of displaying the user's biological information on the display portion 8204, a function of changing a video displayed on the display portion 8204 in accordance with the movement of the user's head, or the like.

The display apparatus of one embodiment of the present invention can be used in the display portion 8204. Accordingly, the head-mounted display 8200 can capture an image of the user's face and detect the user's state, for example. The head-mounted display 8200 can detect the user's fatigue state, for example.

FIG. 37C to FIG. 37E are diagrams illustrating the appearance of a head-mounted display 8300. The head-mounted display 8300 includes a housing 8301, a display portion 8302, a fixing band 8304, and a pair of lenses 8305.

A user can perceive display on the display portion 8302 through the lenses 8305. Note that the display portion 8302 is preferably curved and placed because the user can feel a high realistic sensation. In addition, when another image displayed on a different region of the display portion 8302 is perceived through the lenses 8305, three-dimensional display using parallax can also be performed, for example. Note that the number of display portions 8302 provided is not limited to one; two display portions 8302 may be provided so that one display portion is provided for one eye of the user.

The display apparatus of one embodiment of the present invention can be used in the display portion 8302. Accordingly, the head-mounted display 8300 can capture an image of the user's face and detect the user's state, for example. The head-mounted display 8300 can detect the user's fatigue state, for example.

The display apparatus of one embodiment of the present invention can achieve extremely high resolution. For example, a pixel is not easily perceived by the user even when the user perceives display that is magnified by the use of the lenses 8305 as illustrated in FIG. 37E. In other words, a video with a strong sense of reality can be perceived by the user with the use of the display portion 8302.

FIG. 37F is an external view of a goggle-type head-mounted display 8400. The head-mounted display 8400 includes a pair of housings 8401, a mounting portion 8402, and a cushion 8403. A display portion 8404 and a lens 8405 are provided in each of the pair of housings 8401. The pair of display portions 8404 may display different images, whereby three-dimensional display using parallax can be performed.

A user can perceive display on the display portion 8404 through the lenses 8405. The lens 8405 has a focus adjustment mechanism and can adjust the position according to the user's eyesight. The display portion 8404 is preferably a square or a horizontal rectangle. Accordingly, realistic sensation can be increased.

The mounting portion 8402 preferably has plasticity and elasticity to be adjusted to fit the size of the user's face and not to slide down. In addition, part of the mounting portion 8402 preferably has a vibration mechanism functioning as a bone conduction earphone. Thus, without additionally requiring an audio device such as earphones or a speaker, the user can enjoy video and sound only by wearing the head-mounted display. Note that the housing 8401 may have a function of outputting sound data by wireless communication.

The mounting portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge whose surface is covered by cloth, leather (natural leather or synthetic leather), or the like is used, for example, a gap is unlikely to be generated between the user's face and the cushion 8403, whereby light leakage can be suitably prevented. Furthermore, using such a material is preferable because it has a soft texture and the user does not feel cold when wearing the head-mounted display in a cold season, for example. The member in contact with user's skin, such as the cushion 8403 or the mounting portion 8402, is preferably detachable because cleaning or replacement can be easily performed.

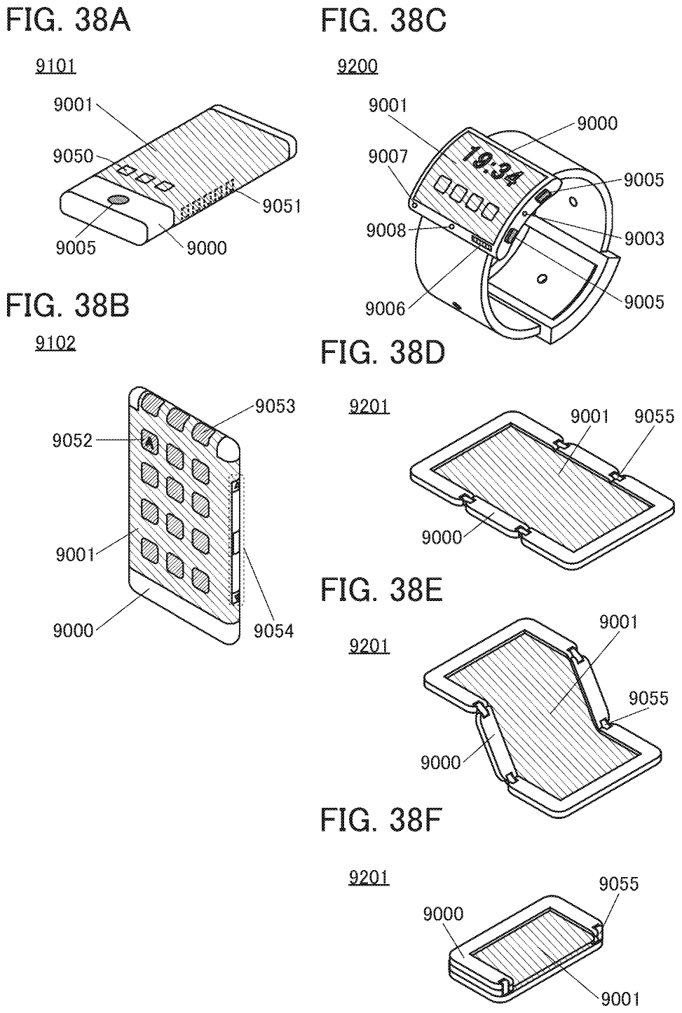

Electronic devices illustrated in FIG. 38A to FIG. 38F each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 38A to FIG. 38F have a variety of functions. For example, the electronic devices can have a function of displaying a variety of kinds of information (a still image, a moving image, a text image, and the like) on the display portion, a function of a touch sensor, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. In addition, the electronic devices may each include a camera, for example, and have a function of capturing a still image or a moving image and storing the captured image in a recording medium (an external recording medium or a recording medium incorporated in the camera), a function of displaying the captured image on the display portion, or the like.

The display apparatus of one embodiment of the present invention can be used in the display portion 9001. Accordingly, the electronic devices illustrated in FIG. 38A to FIG. 38F can have a function of a touch sensor and have a function of performing biometric authentication, for example.

The details of the electronic devices illustrated in FIG. 38A to FIG. 38F are described below.

FIG. 38A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display letters and image information on its plurality of surfaces. FIG. 38A illustrates an example in which three icons 9050 are displayed. Information 9051 indicated by dashed rectangles can be displayed on another surface of the display portion 9001. Examples of the information 9051 include notification of reception of an e-mail, SNS, or an incoming call, the title and sender of an e-mail, SNS, or the like, the date, the time, remaining battery, and the radio field intensity. Alternatively, the icon 9050 or the like may be displayed in the position where the information 9051 is displayed.

FIG. 38B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer a call, for example.

FIG. 38C is a perspective view illustrating a watch-type portable information terminal 9200. The portable information terminal 9200 can be used as a smartwatch (registered trademark), for example. The display surface of the display portion 9001 is curved, and display can be performed on the curved display surface. Mutual communication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 38D to FIG. 38F are perspective views illustrating a foldable portable information terminal 9201. FIG. 38D is a perspective view of an opened state of the portable information terminal 9201, FIG. 38F is a perspective view of a folded state thereof, and FIG. 38E is a perspective view of a state in the middle of change from one of FIG. 38D and FIG. 38F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature greater than or equal to 0.1 mm and less than or equal to 150 mm.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### REFERENCE NUMERALS

100: display apparatus, 101: layer, 102: substrate, 105: substrate, 107: display portion, 111B: pixel electrode, 111G: pixel electrode, 111R: pixel electrode, 111S: pixel electrode, 111: pixel electrode, 112B: EL layer, 112Bf: EL film, 112f: EL film, 112G: EL layer, 112Gf: EL film, 112R: EL layer, 112Rf: EL film, 112: EL layer, 113: connection electrode, 114: common layer, 115: common electrode, 116B: tapered portion, 116G: tapered portion, 116R: tapered portion, 116S: tapered portion, 116: tapered portion, 118: light-blocking layer, 120: substrate, 121: protective layer, 122: adhesive layer, 123: conductive layer, 125f: insulating film, 125: insulating layer, 126a: insulating layer, 126b: insulating layer, 126f: insulating film, 126: insulating layer, 127a: insulating layer, 127b: insulating layer, 128: layer, 129: conductive layer, 130B: light-emitting element, 130G: light-emitting element, 130R: light-emitting element, 130: light-emitting element, 133: region, 138: region, 139a: light, 139b: light, 140: connection portion, 142: adhesive layer, 143a: resist mask, 143b: resist mask, 143c: resist mask, 143d: resist mask, 143: resist mask, 144Ba: mask film, 144Bb: mask film, 144Ga: mask film, 144Gb: mask film, 144Ra: mask film, 144Rb: mask film, 144Sa: mask film, 144Sb: mask film, 144: mask film, 145a: mask layer, 145b: mask layer, 145Ba: mask layer, 145Bb: mask layer, 145Ga: mask layer, 145Gb: mask layer, 145Ra: mask layer, 145Rb: mask layer, 145Sa: mask layer, 145Sb: mask layer, 145: mask layer, 146: protective layer, 150: light-receiving element, 155f: PD film, 155: PD layer, 164: circuit, 165: wiring, 166: conductive layer, 172: FPC, 173: IC, 200A: display apparatus, 200B: display apparatus, 200C: display apparatus, 200D: display apparatus, 200E: display apparatus, 200F: display apparatus, 201: transistor, 202: substrate, 203: functional layer, 204: connection portion, 205: transistor, 207: substrate, 209: transistor, 210: transistor, 211: insulating layer, 212: light-receiving element, 213R: light-emitting and light-receiving element, 213: insulating layer, 215: insulating layer, 216B: light-emitting element, 216G: light-emitting element, 216IR: light-emitting element, 216R: light-emitting element, 216W: light-emitting element, 216X: light-emitting element, 216: light-emitting element, 218: insulating layer, 220: finger, 221: conductive layer, 222a: conductive layer, 222b: conductive layer, 222: fingerprint, 223: conductive layer, 225: insulating layer, 226: path, 227: contact portion, 228: image-capturing range, 229: stylus, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 300A: display panel, 300B: display panel, 300: display panel, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 370B: light-emitting element, 370G: light-emitting element, 370PD: light-receiving element, 370R: light-emitting element, 370SR: light-emitting and light-receiving element, 371: pixel electrode, 373: active layer, 375: common electrode, 377: first electrode, 378: second electrode, 380A: display apparatus, 380B: display apparatus, 380C: display apparatus, 381: hole-injection layer, 382: hole-transport layer, 383B: light-emitting layer, 383G: light-emitting layer, 383R: light-emitting layer, 383: light-emitting layer, 384: electron-transport layer, 385: electron-injection layer, 389: layer, 400: display apparatus, 701: substrate, 702L: display portion, 702R: display portion, 702: display portion, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: wearing portion, 8202: lens, 8203: main body, 8204: display portion, 8205: cable, 8206: battery, 8300: head-mounted display, 8301: housing, 8302: display portion, 8304: fixing band, 8305: lens, 8400: head-mounted display, 8401: housing, 8402: mounting portion, 8403: cushion, 8404: display portion, 8405: lens, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. A display apparatus comprising:
a first light-emitting element;
a second light-emitting element adjacent to the first light-emitting, element;
a light-receiving element adjacent to the second light-emitting element;
a first insulating layer between the second light-emitting element and the light-receiving element; and
a second insulating layer between the first light-emitting element and the second light-emitting element,
the first light-emitting element comprising:
a first pixel electrode;
a first EL layer over the first pixel electrode; and
a common electrode over the first EL layer,
the second light-emitting element comprising:
a second pixel electrode;
a second EL layer over the second pixel electrode; and
the common electrode over the second EL layer,
the light-receiving element comprising:
a third pixel electrode;
a PD layer over the third pixel electrode; and
the common electrode over the PD layer,
wherein the common electrode is provided over the first insulating layer and the second insulating layer, and
wherein the second insulating layer and the first insulating layer comprise the same material.

2. (canceled)

3. The display apparatus according to claim 1,
wherein the first insulating layer and the second insulating layer each comprise an organic material.

4. The display apparatus according to claim 1,
wherein end portions of the first pixel electrode, the second pixel electrode, and the third pixel electrode have tapered shapes,
wherein the first EL layer covers the end portion of the first pixel electrode,
wherein the second EL layer covers the end portion of the second pixel electrode, and
wherein the PD layer covers the end portion of the third pixel electrode.

5. The display apparatus according to claim 4,
wherein the first EL layer comprises a first tapered portion between the end portion of the first pixel electrode and the second insulating layer,
wherein the second EL layer comprises a second tapered portion between the end portion of the second pixel electrode and the second insulating layer, and
wherein the PD layer comprises a third tapered portion between the end portion of the third pixel electrode and the first insulating layer.

6. The display apparatus according to claim 1,
the first EL layer further comprising:
a first light-emitting laver; and
a first carrier-transport layer over the first light-emitting layer,
the second EL layer further comprising:
a second light-emitting layer; and
a second carrier-transport layer over the second light-emitting layer, and
the PD layer further comprising:
a photoelectric conversion layer; and
a third carrier-transport layer over the photoelectric conversion layer.

7. The display apparatus according to claim 6, further comprising a common layer over the first carrier-transport layer, the second carrier-transport layer, the third carrier-transport layer, the first insulating layer, and the second insulating layer and the common electrode over the common layer.

8. The display apparatus according to claim 7,
wherein the common layer comprises a carrier-injection layer.

9. A display module comprising:
the display apparatus according to claim 1; and
at least one of a connector and an integrated circuit.

10. An electronic device comprising:
the display module according to claim 9; and
at least one of a battery, a camera, a speaker, and a microphone.

11. A method for manufacturing a display apparatus, comprising:
forming a first pixel electrode, a second pixel electrode, and a third pixel electrode;
forming a first EL film over the first pixel electrode, the second pixel electrode, and the third pixel electrode;
forming a first mask film over the first EL film;
processing the first EL film and the first mask film to form a first EL layer and a first mask layer over the first EL layer;
forming a second EL film over the second pixel electrode, the third pixel electrode, and the first mask layer;
forming a second mask film over the second EL film;
processing the second EL film and the second mask film to form a second EL layer adjacent to the first EL layer and a second mask layer over the second EL layer;
forming a PD film over the third pixel electrode, the first mask layer, and the second mask layer;
forming a third mask film over the PD film;
processing the PD film and the third mask film to form a PD layer adjacent to the second EL layer and a third mask layer over the PD layer;
forming a first insulating film comprising a positive photosensitive material to cover a side surface of the first EL layer, a side surface of the second EL layer, and a side surface of the PD layer;
performing irradiation of first light on the first insulating film and then performing development to form a first insulating layer between the second EL layer and the PD layer and a second insulating layer between the first EL layer and the second EL layer;
performing irradiation of second light on the second insulating layer;
removing at least part of the first mask layer, the second mask layer, and the third mask layer; and
forming a common electrode over the first EL layer, the second EL layer, the PD layer, the first insulating layer, and the second insulating layer.

12. (canceled)

13. The method for manufacturing a display apparatus, according to claim 11,
wherein by performing heat treatment after the first insulating layer and the second insulating layer are formed but before the first mask layer, the second mask layer, and the third mask layer are removed, the first insulating layer and the second insulating layer are changed in shape to have tapered shapes in side surfaces.

14. The method for manufacturing a display apparatus, according to claim 13,
wherein a temperature of the heat treatment is lower than or equal to 130° C.

15. The method for manufacturing a display apparatus, according to claim 11,
wherein the second light comprises light having the same wavelength as the first light.

16. The method for manufacturing a display apparatus, according to claim 11,
wherein a spectrum of the first light and a spectrum of the second light each have a peak in an ultraviolet light region.

17.-18. (canceled)

19. The method for manufacturing a display apparatus, according to claim 11,
wherein the first EL film comprises a first light-emitting film and a film configured to be a first carrier-transport layer over the first light-emitting film,
wherein the second EL film comprises a second light-emitting film and a film configured to be a second carrier-transport layer over the second light-emitting film,
wherein the PD film comprises a photoelectric conversion film and a film configured to be a third carrier-transport layer over the photoelectric conversion film,
wherein the first light-emitting film, the film configured to be the first carrier-transport layer, and the first mask film are processed to form a first light-emitting layer, the first carrier-transport layer over the first light-emitting layer, and the first mask layer over the first carrier-transport layer,
wherein the second light-emitting film, the film configured to be the second carrier-transport layer, and the second mask film are processed to form a second light-emitting layer, the second carrier-transport layer over the second light-emitting layer, and the second mask layer over the second carrier-transport layer, and
wherein the photoelectric conversion film, the film configured to be the third carrier-transport layer, and the third mask film are processed to form a photoelectric conversion layer, the third carrier-transport layer over the photoelectric conversion layer, and the third mask layer over the third carrier-transport layer.

20. The method for manufacturing a display apparatus, according to claim 11,
wherein the first to third pixel electrodes are formed to have tapered shapes in end portions,
wherein by processing the first EL film, the first EL layer is formed to cover the end portion of the first pixel electrode,
wherein by processing the second EL film, the second EL layer is formed to cover the end portion of the second pixel electrode, and
wherein by processing the PD film, the PD layer is formed to cover the end portion of the third pixel electrode.

21. (canceled)

22. The display apparatus according to claim 1,
wherein a transmittance of light having a specific wavelength that is at least part of a visible light wavelength in the first insulating layer is lower than the transmittance of the light having the specific wavelength in the second insulating layer.

23. The display apparatus according to claim 1,
wherein a transmittance of light of at least one color among red, green, and blue in the first insulating layer is lower than the transmittance in the second insulating layer.

24. The method for manufacturing a display apparatus, according to claim 11,
wherein the irradiation of the second light is performed on the second insulating layer to increase a transmittance of light having a wavelength that is at least part of a visible light wavelength in the second insulating layer.

25. The method for manufacturing a display apparatus, according to claim 11,
wherein the irradiation of the second light is performed on the second insulating layer to increase a transmittance of light of at least one color among red, green, and blue in the second insulating layer, and
wherein at least the part of the first mask layer, the second mask layer, and the third mask layer are removed to expose at least part of the first EL layer, the second EL layer, and the PD layer.
